(19) United States
(12) Patent Application Publication
(10) Pub. No.: US 2022/0155683 A1
(43) Pub. Date: May 19, 2022

(54) PHOTO-PATTERNABLE CROSS-BRED ORGANIC SEMICONDUCTOR POLYMERS FOR ORGANIC THIN-FILM TRANSISTORS

(71) Applicant: Corning Incorporated, Corning, NY (US)

(72) Inventors: Huayun Deng, Painted Post, NY (US); Mingqian He, Horseheads, NY (US); Yang Li, Shanghai (CN); Weijun Niu, Painted Post, NY (US); Hongxiang Wang, Shanghai (CN)

(21) Appl. No.: 17/440,387

(22) PCT Filed: Mar. 5, 2020
(86) PCT No.: PCT/US2020/021146

§ 371 Date: Sep. 17, 2021

(30) Foreign Application Priority Data
Mar. 27, 2019 (CN) 201910237759.4

(51) Int. Cl. G03F 7/038; G03F 7/11; G03F 7/38; G03F 7/40; G03F 7/32; G03F 7/004

(52) U.S. Cl. CPC G03F 7/0382; G03F 7/11; G03F 7/0045; G03F 7/40; G03F 7/325; G03F 7/38

(57) ABSTRACT

A polymer blend, including at least one organic semiconductor (OSC) polymer, such that: the at least one OSC polymer is a diketopyrrolopyrrole-fused thiophene polymeric material, the fused thiophene is beta-substituted, the at least one OSC polymer has a first portion and a second portion, and at least one of the first portion or the second portion includes at least one UV-curable side chain.

This application claims the benefit of priority under 35 U.S.C. § 119 of Chinese Patent Application Serial No. 201910237759.4, filed on Mar. 27, 2019, the content of which is relied upon and incorporated herein by reference in its entirety.

### BACKGROUND

### 1. Field

The disclosure relates to photo-patternable cross-bred organic semiconductor polymers as semiconducting layers for organic thin-film transistors (OTFTs).

### 2. Technical Background

Organic thin-film transistors (OTFTs) have garnered extensive attention as alternatives to conventional silicon-based technologies, which require high temperature and high vacuum deposition processes, as well as complex photolithographic patterning methods. Semiconducting (i.e., organic semiconductor, OSC) layers are one important component of OTFTs which can effectively influence the performance of devices.

Traditional technologies in the manufacture of inorganic TFT device arrays often rely on photolithography as the patterning process. However, photolithography usually involves harsh oxygen (O₂) plasma during pattern transfer or photoresist removal and aggressive developing solvents which may severely damage the OSC layer and lead to significant deterioration of device performance.

This disclosure presents improved photo-patternable cross-bred organic semiconductor polymers and use thereof for OSC layers of organic thin-film transistors.

### SUMMARY

In some embodiments, a polymer blend, comprises: at least one organic semiconductor (OSC) polymer, wherein the at least one OSC polymer is a diketopyrrolopyrrole-fused thiophene polymeric material, wherein the fused thiophene is beta-substituted, and wherein the at least one OSC polymer comprises a first portion and a second portion, wherein at least one of the first portion or the second portion comprises at least one UV-curable side chain.

In one aspect, which is combinable with any of the other aspects or embodiments, the at least one UV-curable side chain comprises at least one of acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, only the first portion comprises at least one UV-curable side chain.

In one aspect, which is combinable with any of the other aspects or embodiments, both the first portion and the second portion comprise the at least one UV-curable side chain.

In one aspect, which is combinable with any of the other aspects or embodiments, the polymer blend further comprises: at least one crosslinker, wherein the at least one crosslinker comprises at least one of acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, the polymer blend further comprises: at least one photoinitiator, wherein the at least one photoinitiator is present in a range of 0.1 wt. % to 10 wt. %.

In one aspect, which is combinable with any of the other aspects or embodiments, the at least one photoinitiator is present in a range of 0.1 wt. % to 5.0 wt. %.

In one aspect, which is combinable with any of the other aspects or embodiments, the polymer blend further comprises: at least one of antioxidants, lubricants, compatibilizers, leveling agents, or nucleating agents present in a range of 0.05 wt. % to 5 wt. %.

In one aspect, which is combinable with any of the other aspects or embodiments, the at least one OSC polymer comprises the repeat unit of Formula 1 or Formula 2, or a salt, isomer, or analog thereof:

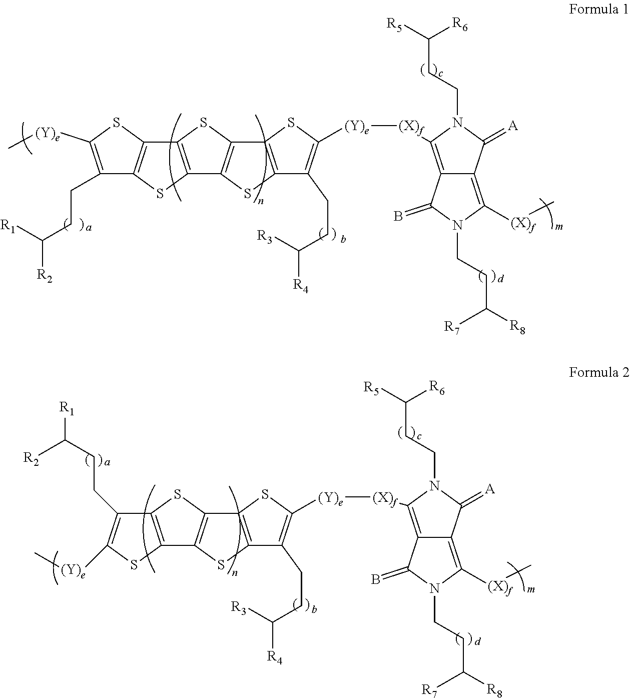

wherein in Formula 1 and Formula 2: m is an integer greater than or equal to one; n is 0, 1, or 2; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl; a, b, c, and d are independently, integers greater than or equal to 3; e and f are integers greater than or equal to zero; X and Y are, independently a covalent bond, an optionally substituted aryl group, an optionally substituted heteroaryl, an optionally substituted fused aryl or fused heteroaryl group, an alkyne or an alkene; and A and B may be, independently, either S or O, with the provisos that: (i) at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl; (ii) if any of R₁, R₂, R₃, or R₄ is hydrogen, then none of R₅, R₆, R₇, or R₈ are hydrogen; (iii) if any of R₅, R₆, R₇, or R₈ is hydrogen, then none of R₁, R₂, R₃, or R₄ are hydrogen; (iv) e and f cannot both be 0; (v) if either e or f is 0, then c and d, independently, are integers greater than or equal to 5; and (vi) the polymer having a molecular weight, wherein the molecular weight of the polymer is greater than 10,000.

In one aspect, which is combinable with any of the other aspects or embodiments, for the first portion, R₅ and R₇ are hydrogen and R₆ and R₈ are substituted or unsubstituted C₄ or greater alkenyl.

In one aspect, which is combinable with any of the other aspects or embodiments, for the first portion and the second portion, R₅ and R₇ are hydrogen and R₆ and R₈ are substituted or unsubstituted C₄ or greater alkenyl.

In one aspect, which is combinable with any of the other aspects or embodiments, at least one of R₅, R₆, R₇, and R₈ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, at least one of R₁, R₂, R₃, and R₄ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, the at least one UV-curable side chain comprises at least one of: (A) a polymer selected from:

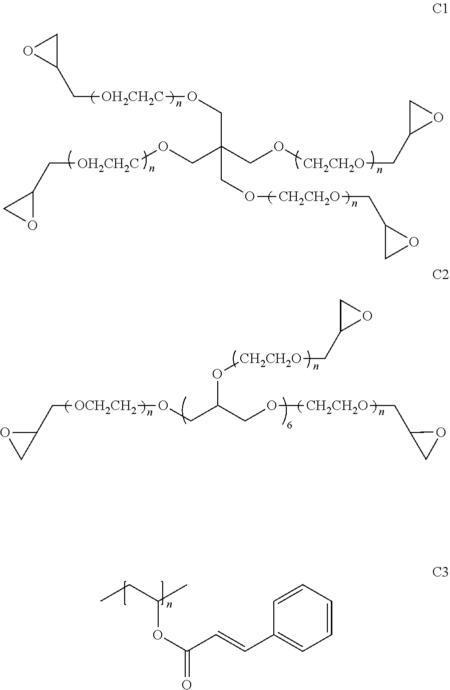

wherein n is an integer greater than or equal to two, or (B) a small-molecule selected from:

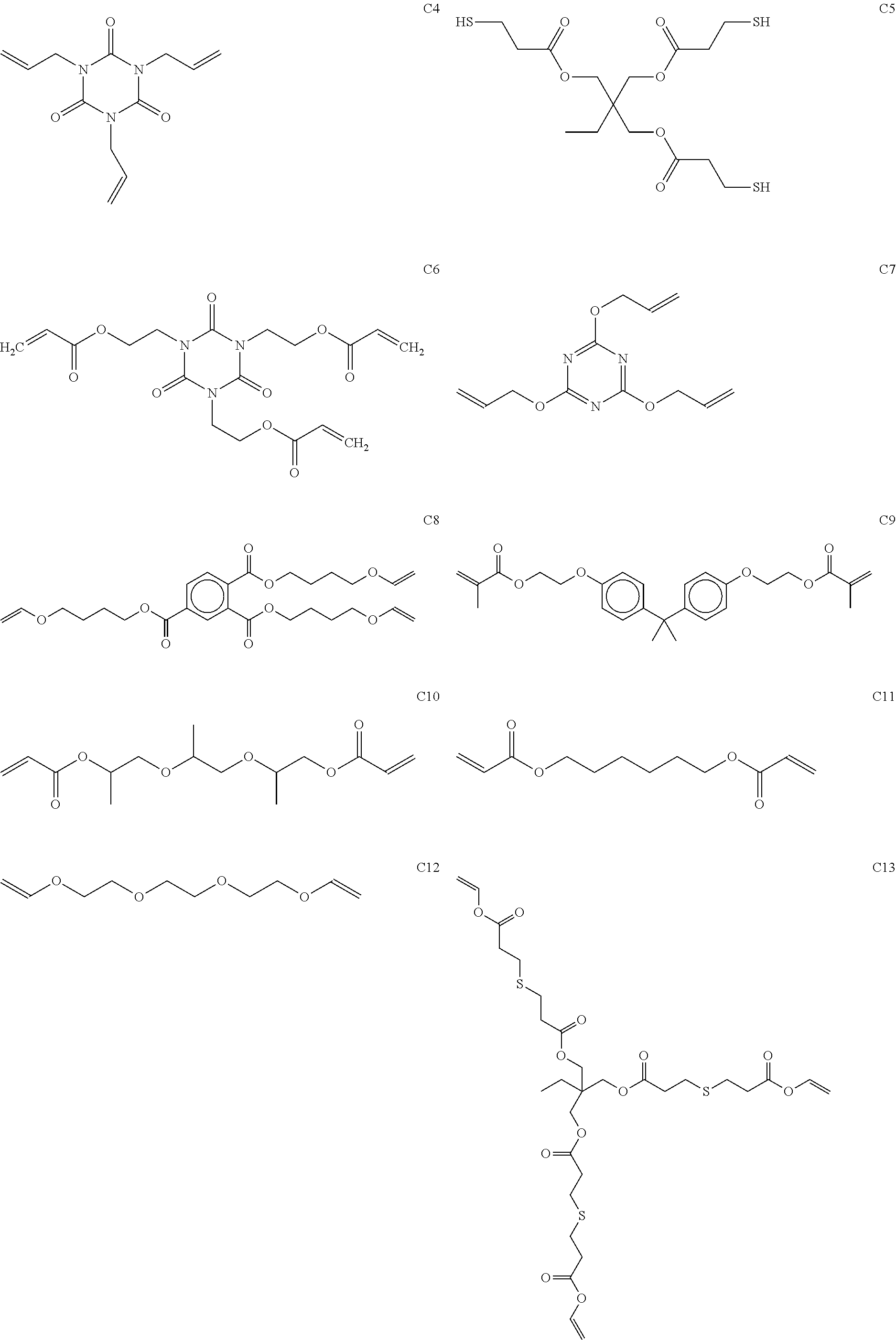

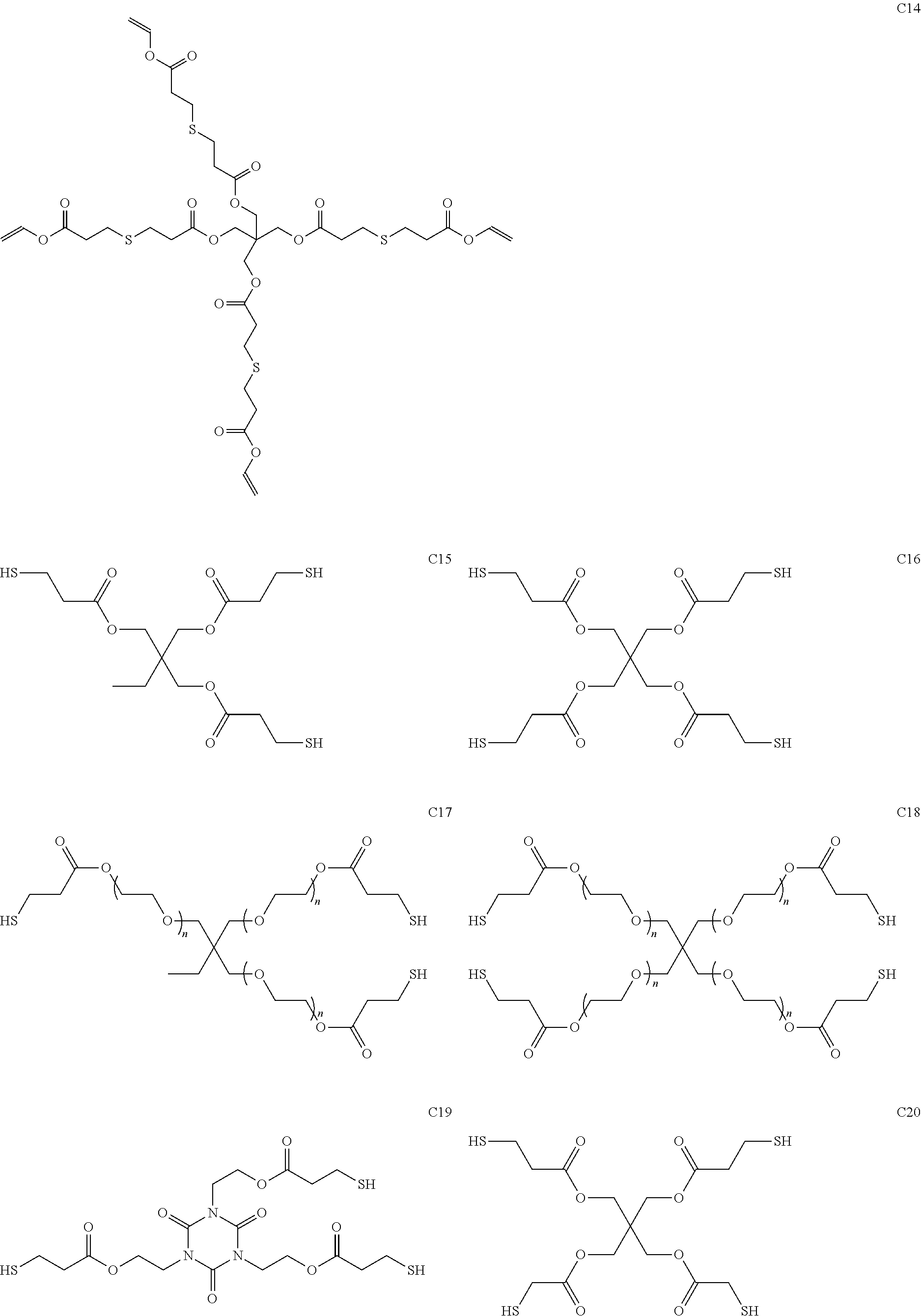

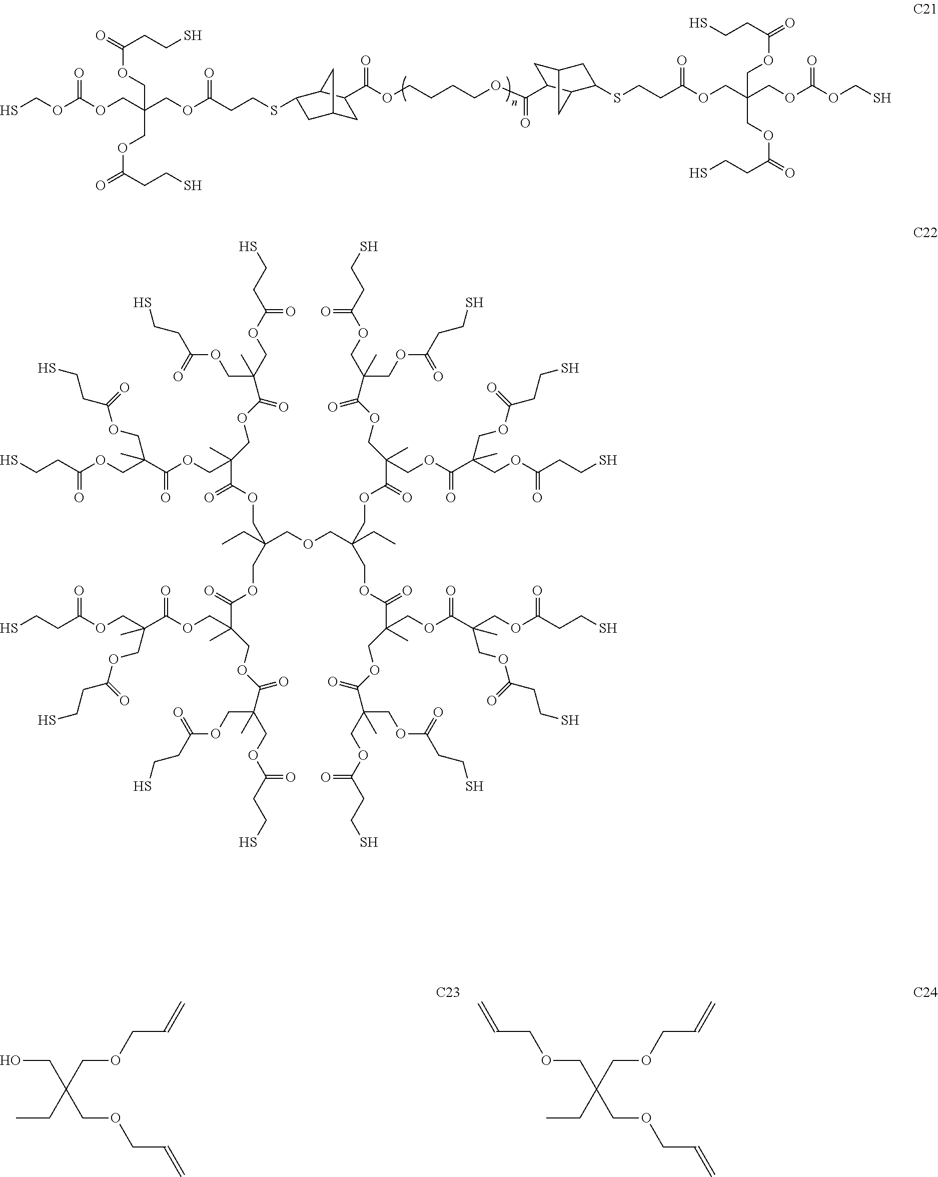

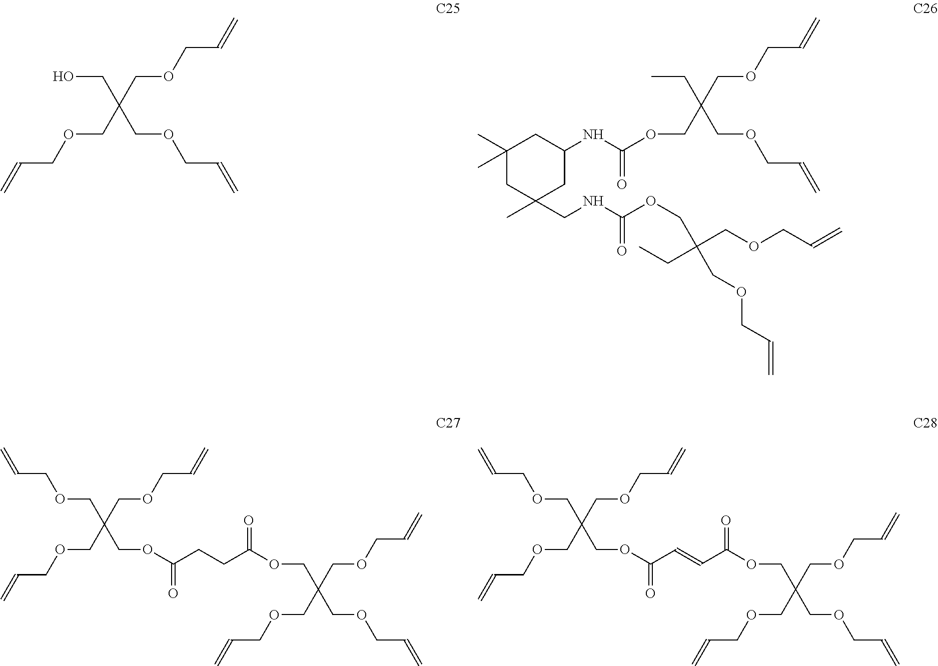 [SMILES: C=CCOCC(CO)(COCC=C)COCC=C ; C=CCOCC(CC)(COCC=C)COC(=O)NCC1(C)CC(NC(=O)OCC(CC)(COCC=C)COCC=C)CC(C)(C)C1 ; C=CCOCC(COCC=C)(COCC=C)COC(=O)CCC(=O)OCC(COCC=C)(COCC=C)COCC=C ; C=CCOCC(COCC=C)(COCC=C)COC(=O)/C=C/C(=O)OCC(COCC=C)(COCC=C)COCC=C]

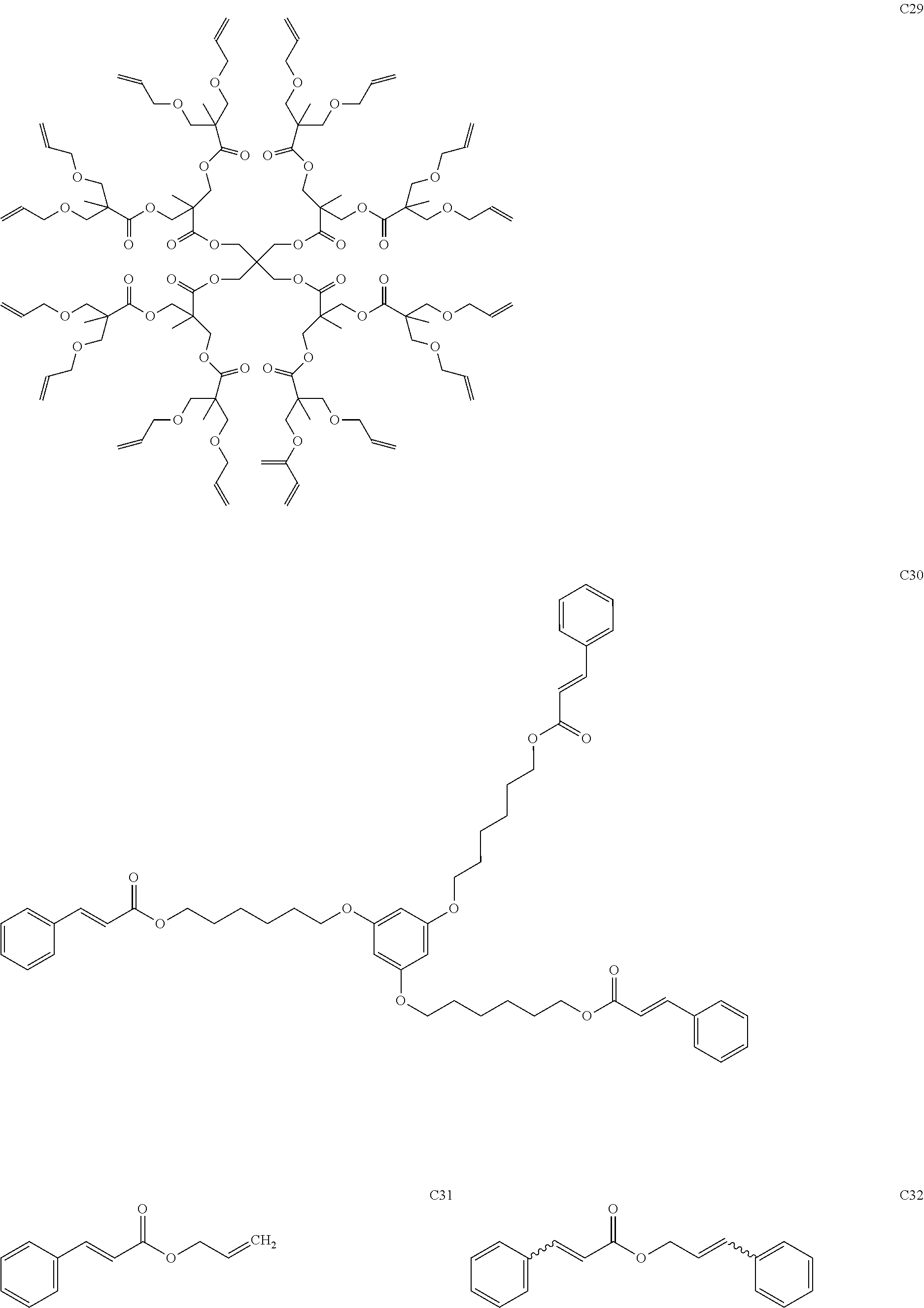 [SMILES: C=CCOCC(C)(COCC=C)C(=O)OCC(C)(COC(=O)C(C)(COCC=C)COCC=C)C(=O)OCC(COC(=O)C(C)(COC(=O)C(C)(COCC=C)COCC=C)COC(=O)C(C)(COCC=C)COCC=C)(COC(=O)C(C)(COC(=O)C(C)(COCC=C)COCC=C)COC(=O)C(C)(COCC=C)COCC=C)COC(=O)C(C)(COC(=O)C(C)(COCC=C)COCC=C)COC(=O)C(C)(COCC=C)COC(=C)C=C ; O=C(/C=C/c1ccccc1)OCCCCCCOc1cc(OCCCCCCOC(=O)/C=C/c2ccccc2)cc(OCCCCCCOC(=O)/C=C/c2ccccc2)c1 ; C=CCOC(=O)/C=C/c1ccccc1 ; O=C(C=Cc1ccccc1)OCC=Cc1ccccc1]

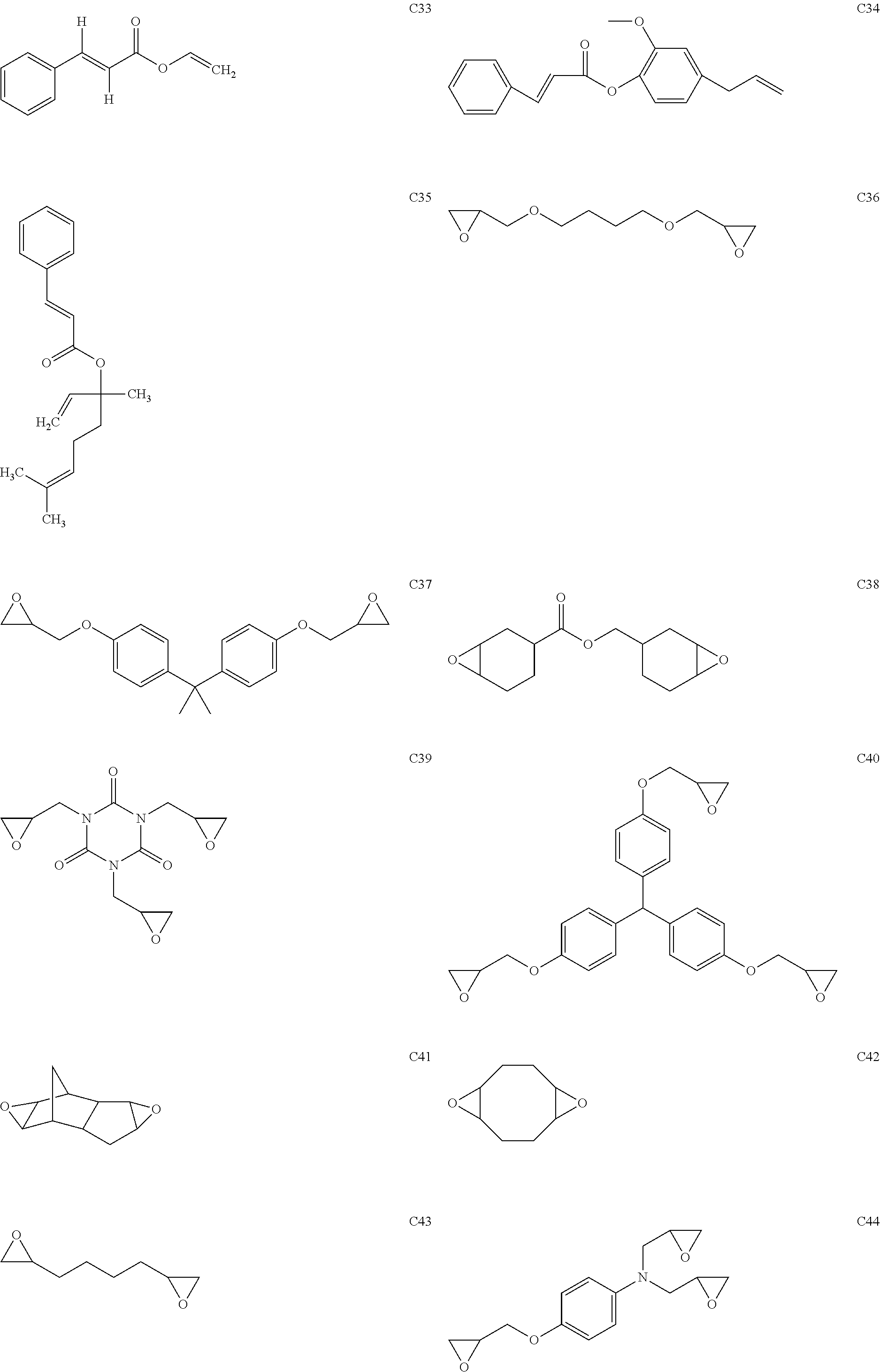

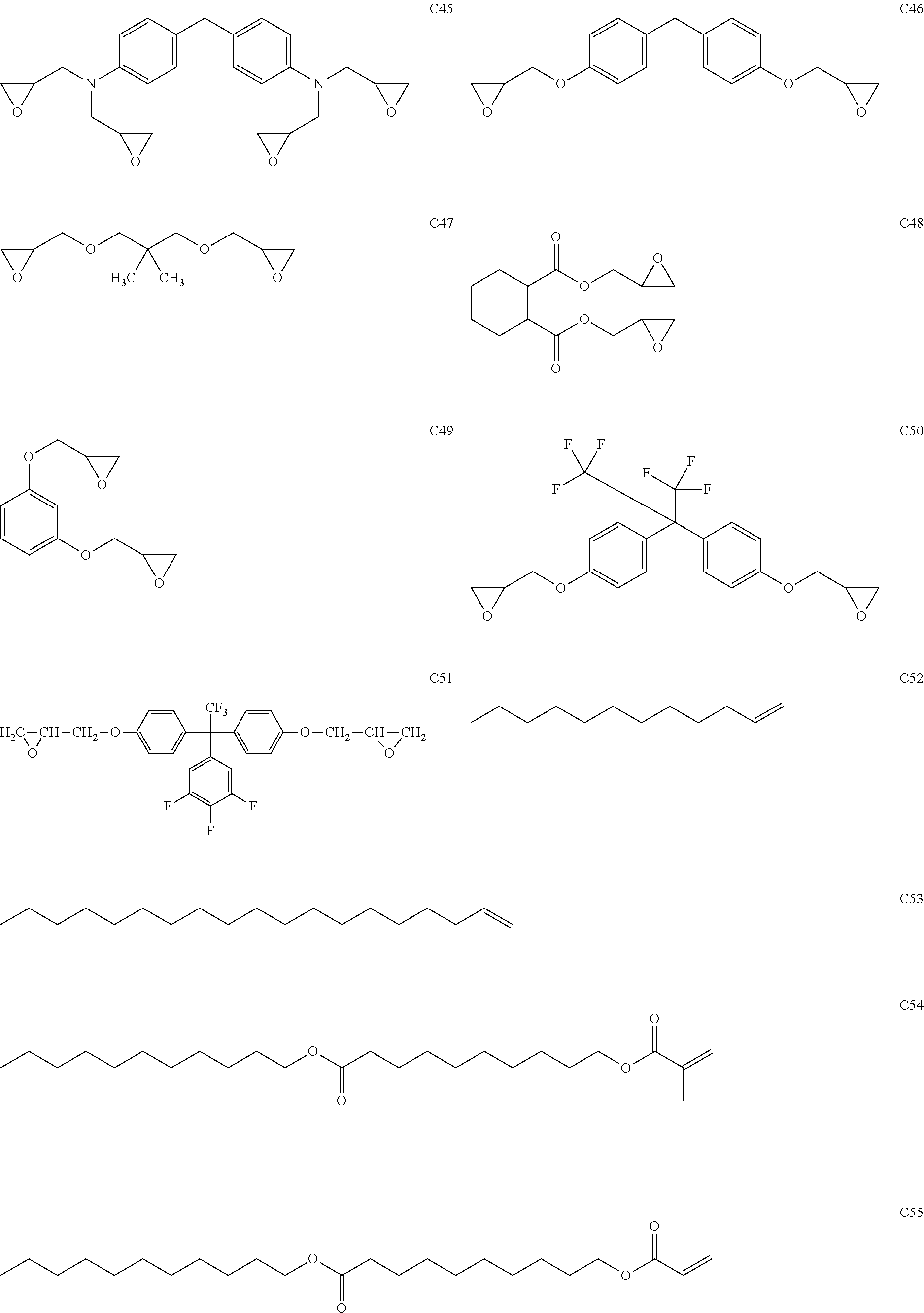

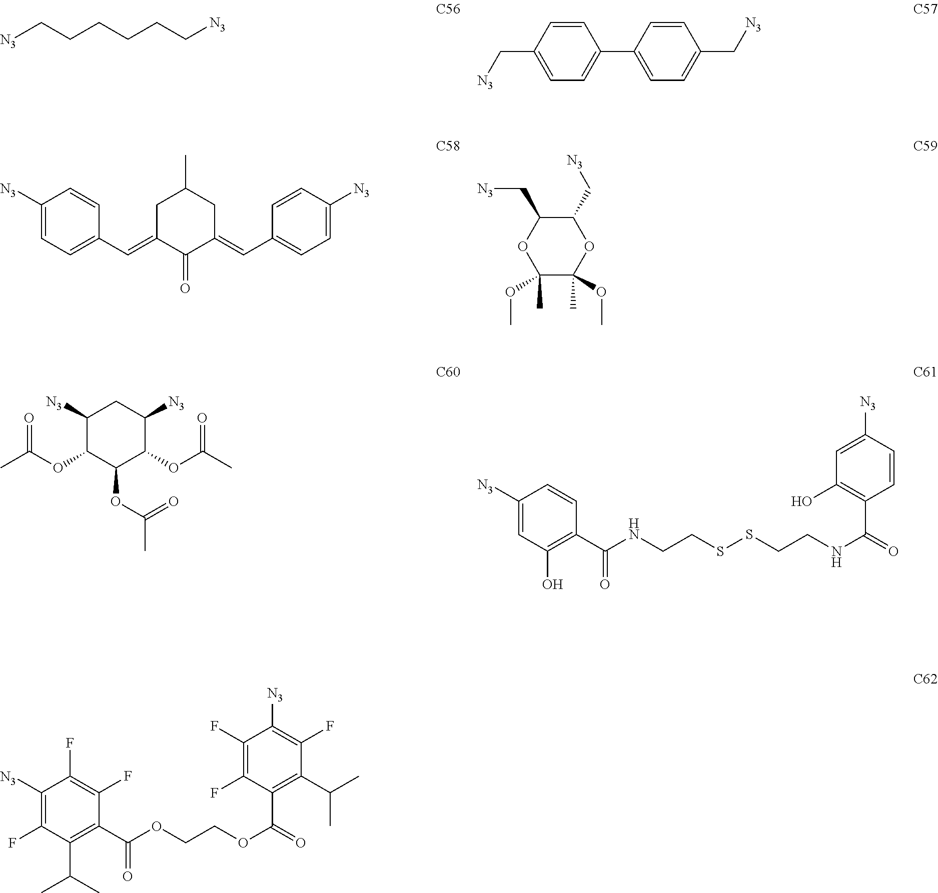

or, (C) a combination thereof.

In one aspect, which is combinable with any of the other aspects or embodiments, the at least one photoinitiator comprises at least one free radical photoinitiator.

In one aspect, which is combinable with any of the other aspects or embodiments, the at least one photoinitiator comprises at least one cationic photoinitiator.

In one aspect, which is combinable with any of the other aspects or embodiments, the at least one photoinitiator comprises: 1-hydroxy-cyclohexyl-phenyl-ketone (184); 2-benzyl-2-dimethylamino-1-(4-morpholinophenyl)-butanone-1 (369); diphenyl(2,4,6-trimethylbenzoyl)phosphine oxide (TPO); 2-isopropyl thioxanthone (ITX); 1-[4-(phenylthio) phenyl]-1,2-octanedione 2-(O-benzoyloxime) (HRCURE-OXE01); 2,2-dimethoxy-1,2-diphenylethan-1-one (BDK); benzoyl peroxide (BPO); hydroxyacetophenone (HAP); 2-hydroxy-2-methylprophenone (1173); 2-methyl-4′-(methylthio)-2-morpholinopropiophenone (907); 2-benzyl-2-(dimethylamino)-4′-morpholinobutyrophenone (IHT-PI 910); Ethyl-4-(dimethylamino)benzoate (EDB); methyl o-benzoyl benzoate (OMBB); bis-(2,6 dimethoxy-benzoyl)-phenyl phosphine oxide (BAPO); 4-benzoyl-4′ methyldiphenylsulfide (BMS); benzophenone (BP); 1-chloro-4-propoxy thiozanthone (CPTX); chlorothioxanthone (CTX); 2,2-diethoxyacetophenone (DEAP); diethyl thioxanthone (DETX); 2-dimethyl aminoethyl benzonate (DMB); 2,2-dimethoxy-2-phenyl acetophenone (DMPA); 2-ethyl anthraquinone (2-EA); ethyl-para-N,N-dimethyl-dimethylamino lenzoate (EDAB); 2-ethyl hexyl-dimethylaminolenzoate (EHA); 4,4-bis-(diethylamino)-benzophenone (EMK); methyl benzophenone (MBF); 4-methyl benzophenone (MBP); Michler's ketone (MK); 2-methyl-1-[4(methylthiol)phenyl]-2-morpholino propanone (1) (MMMP); 4-phenylbenzophenone (PBZ); 2,4,6-trimethyl-benzoly-ethoxyl phenyl phosphine oxide (TEPO); bis(4-tert-butylphenyl) iodonium perfluoro-1-butanesulfonate; bis(4-tert-butylphenyl) iodonium p-toluenesulfonate; bis(4-tert-butylphenyl) iodonium triflate; boc-methoxyphenyldiphenylsulfonium triflate; (4-tert-Butylphenyl) diphenylsulfonium triflate; diphenyliodonium hexafluorophosphate; diphenyliodonium nitrate; diphenyliodonium p-toluenesulfonate; diphenyliodonium triflate; (4-fluorophenyl) diphenylsulfonium triflate; N-hydroxynaphthalimide triflate; N-hydroxy-5-norbornene-2,3-dicarboximide perfluoro-1-butanesulfonate; (4-iodophenyl) diphenylsulfonium triflate; (4-methoxyphenyl) diphenylsulfonium triflate; 2-(4-Methoxystyryl)-4,6-bis (trichloromethyl)-1,3,5-triazine; (4-methylthiophenyl) methyl phenyl sulfonium triflate; 1-naphthyl diphenylsulfonium triflate; (4-phenoxyphenyl) diphenylsulfonium triflate; (4-phenylthiophenyl) diphenylsulfonium triflate; triarylsulfonium hexafluoroantimonate salts, mixed 50 wt. % in propylene carbonate; triarylsulfonium hexafluorophosphate salts, mixed 50 wt. % in propylene carbonate; triphenylsulfonium perfluoro-1-butanesufonate; triphenylsulfonium triflate; tris(4-tert-butylphenyl) sulfonium perfluoro-1-butanesulfonate; tris(4-tert-butylphenyl)sulfonium triflate; aryl diazo salts; diaryliodonium salts; triaryl sulfonium salts; aryl ferrocenium salts; or combinations thereof.

In some embodiments, a polymer blend comprises: at least one organic semiconductor (OSC) polymer, wherein the at least one OSC polymer comprises a structure of Formula 7:

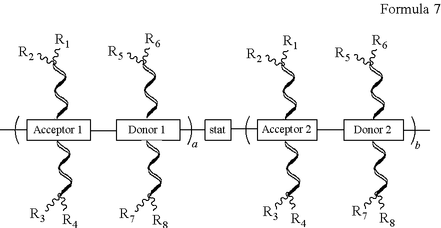

wherein in Formula 7: Acceptor 1 and Acceptor 2 are each electron withdrawing groups; Donor 1 and Donor 2 are electron-donating groups; a and b are, independently, integers greater than or equal to one; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl, wherein: (i) at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl; (ii) if any of R₁, R₂, R₃, or R₄ is hydrogen, then none of R₅, R₆, R₇, or R₈ are hydrogen; (iii) if any of R₅, R₆, R₇, or R₈ is hydrogen, then none of R₁, R₂, R₃, or R₄ are hydrogen; (iv) one of R₁ or R₂ and one of R₃ or R₄ are, independently, connected with Acceptor 1 and Acceptor 2; (v) one of R₅ or R₆ and one of R₇ or R₈ are, independently, connected with Donor 1 and Donor 2; and (vi) the at least one OSC polymer has a molecular weight of greater than 10,000.

In one aspect, which is combinable with any of the other aspects or embodiments, Acceptor 1 and Acceptor 2 are independently selected from the group comprising:

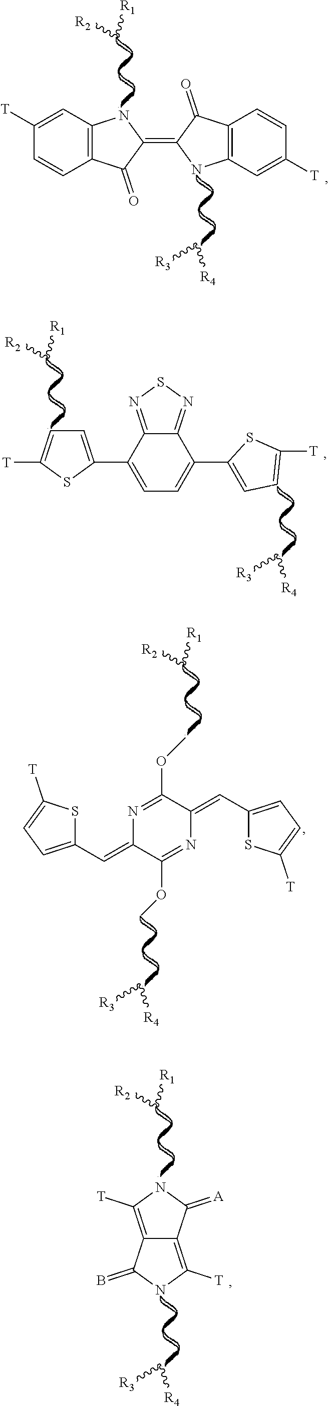

wherein A and B may be, independently, either S or O, and T is a connection terminus to at least one of Donor 1 or Donor 2.

In one aspect, which is combinable with any of the other aspects or embodiments, Donor 1 and Donor 2 are independently selected from the group comprising: thiophene, benzene, fused thiophene, or combinations thereof.

In one aspect, which is combinable with any of the other aspects or embodiments, at least one of Acceptor 1, Acceptor 2, Donor 1, or Donor 2 comprises at least one UV-curable side chain.

In one aspect, which is combinable with any of the other aspects or embodiments, the at least one UV-curable side chain comprises at least one of acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, at least one of R₅, R₆, R₇, and R₈ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, at least one of R₁, R₂, R₃, and R₄ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, the at least one UV-curable side chain comprises at least one of: (A) a polymer selected from:

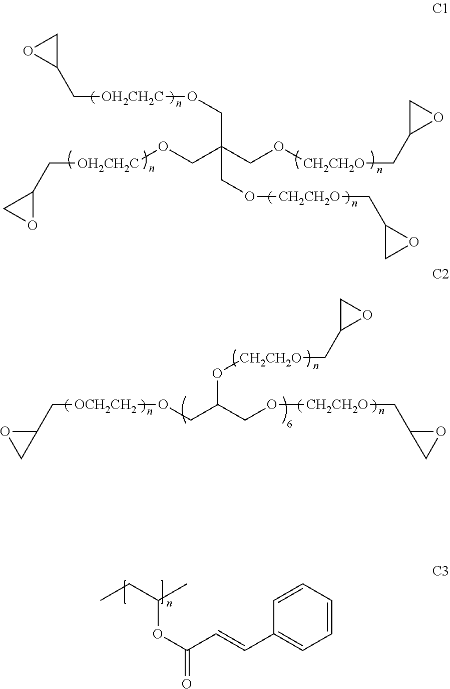

wherein n is an integer greater than or equal to two, or (B) a small-molecule selected from:

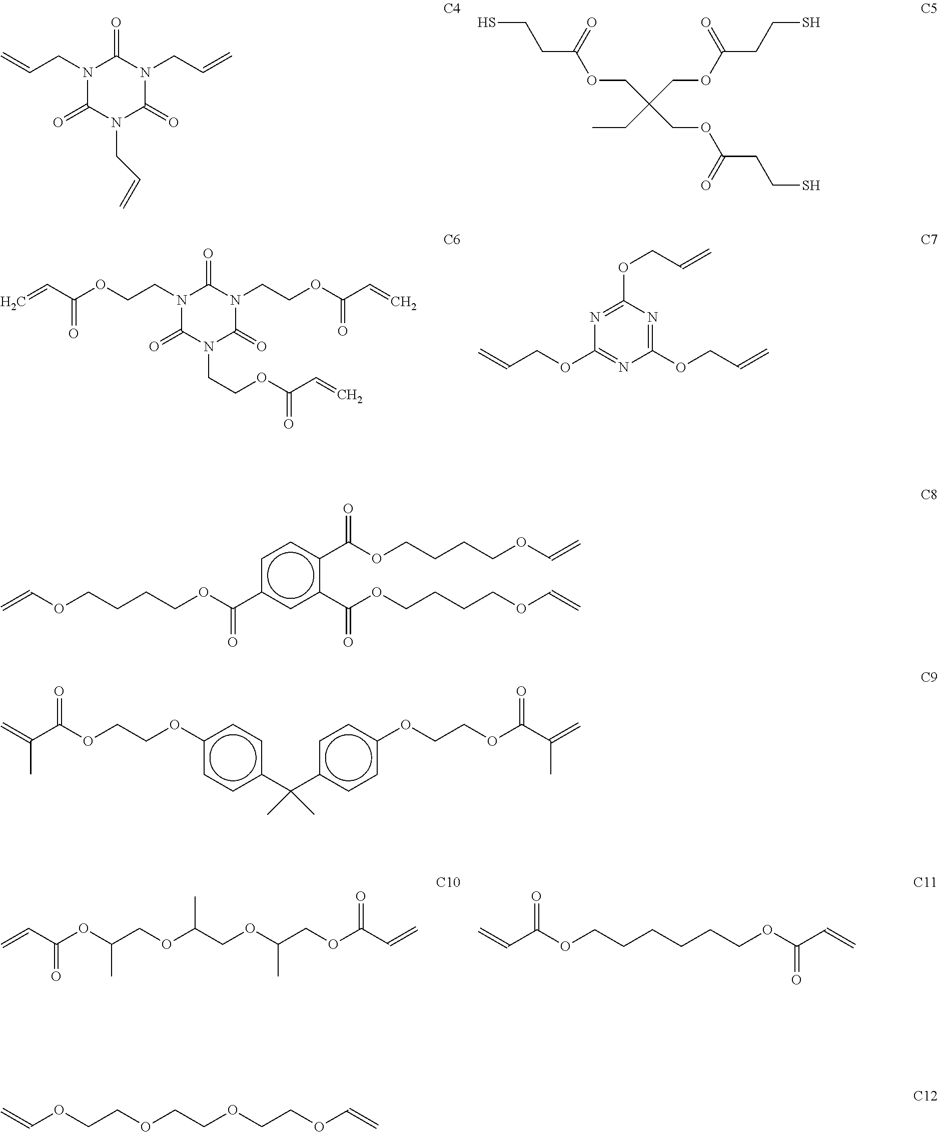

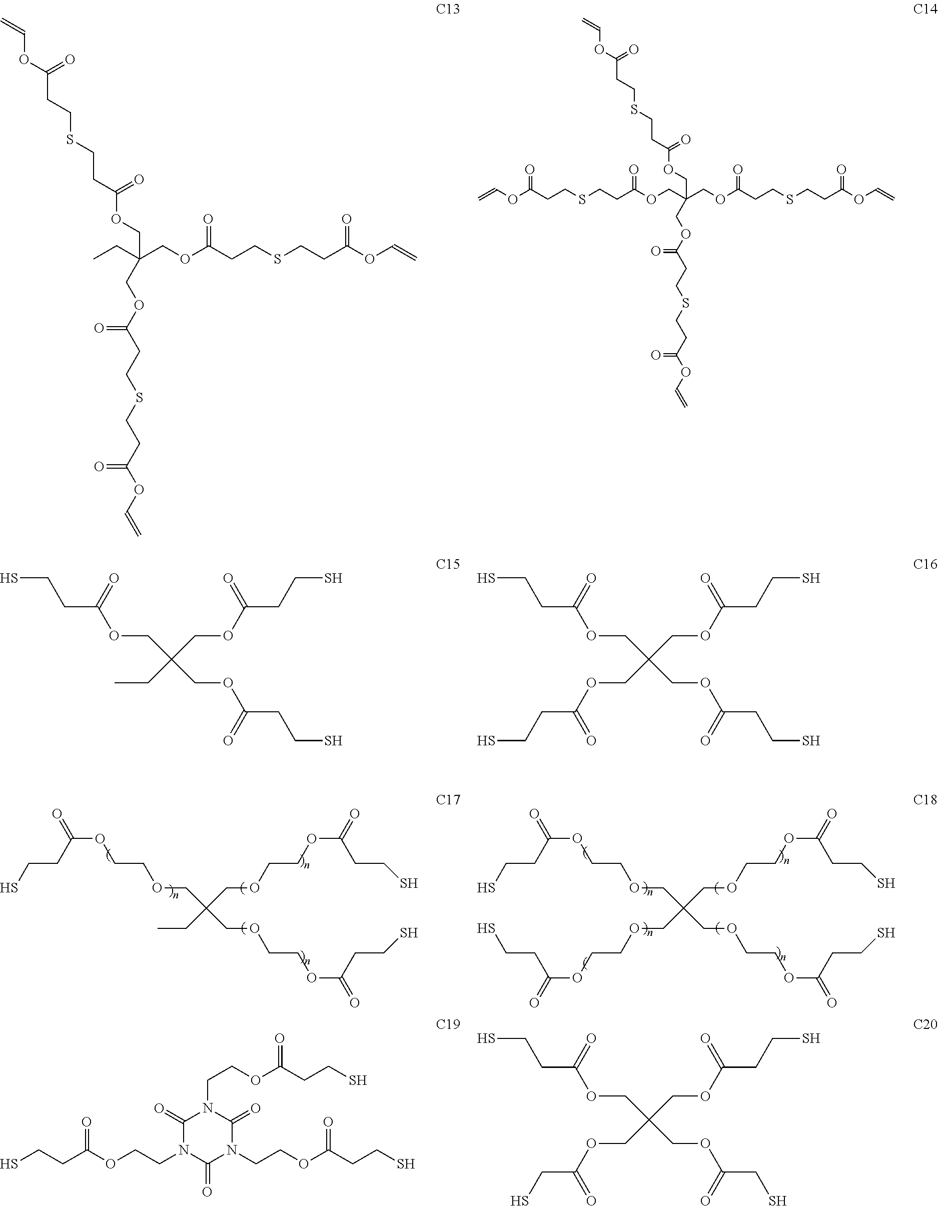

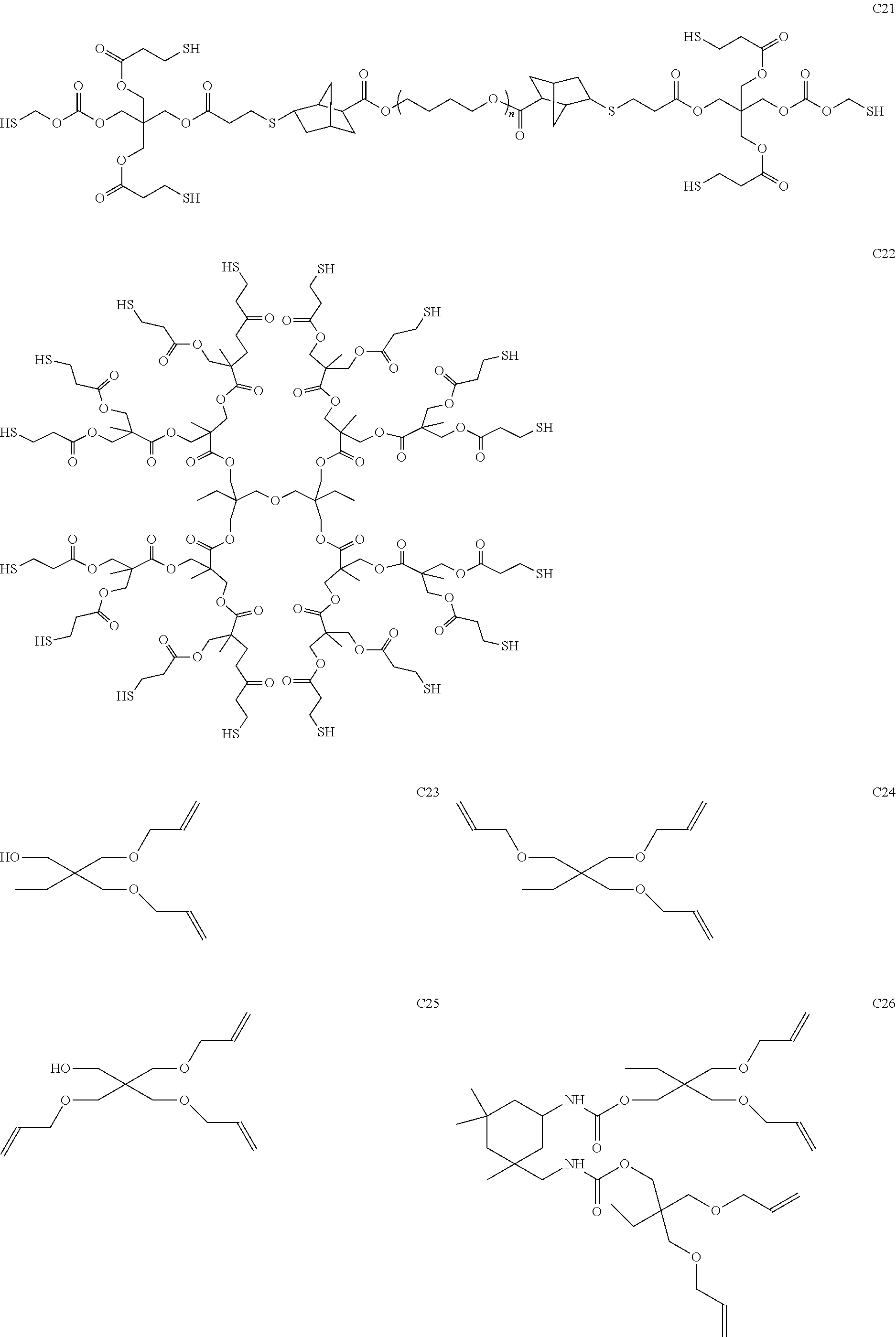

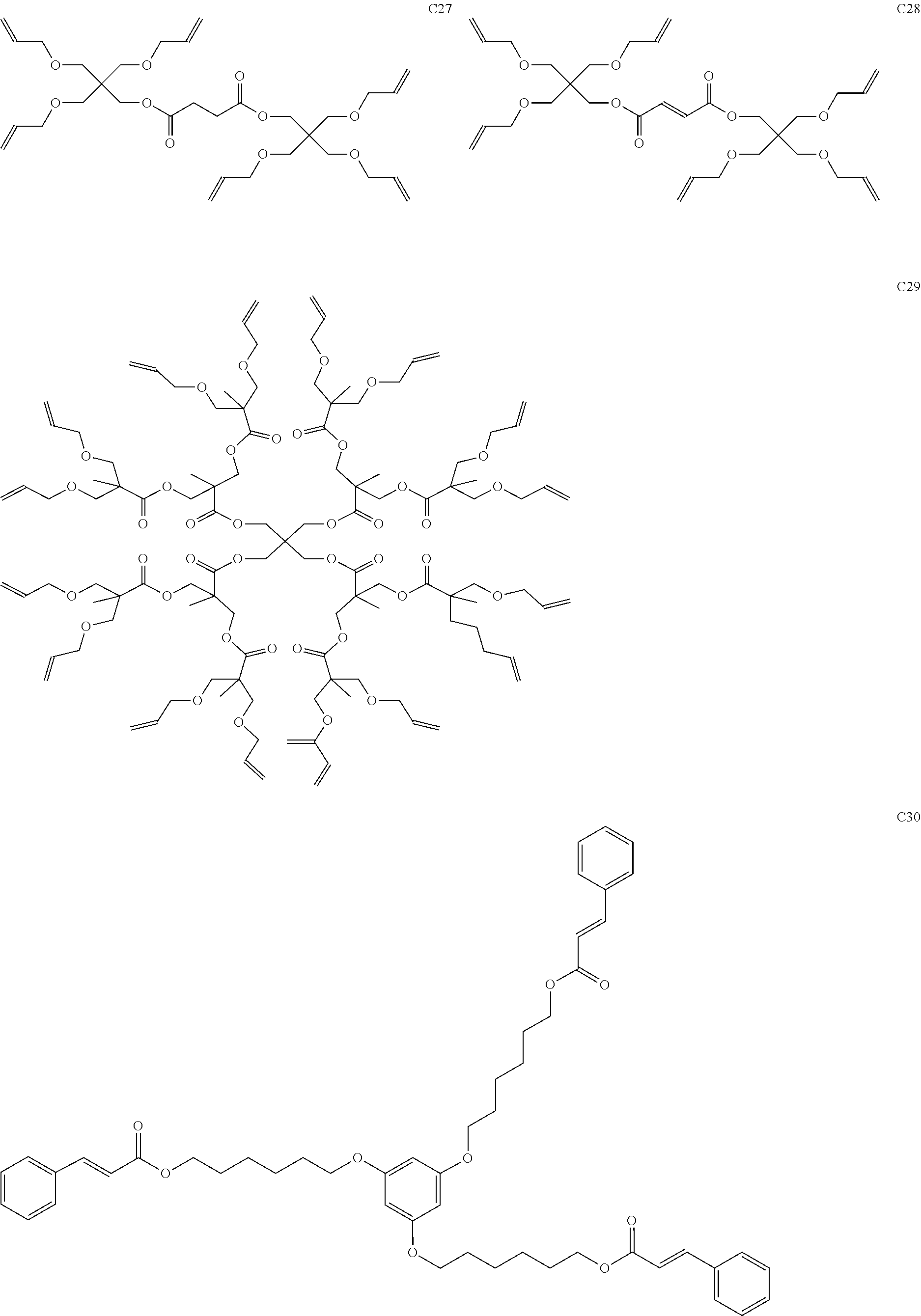 [SMILES: C=CCOCC(COCC=C)(COCC=C)COC(=O)CCC(=O)OCC(COCC=C)(COCC=C)COCC=C ; C=CCOCC(COCC=C)(COCC=C)COC(=O)/C=C/C(=O)OCC(COCC=C)(COCC=C)COCC=C ; C=CCCCC(C)(COCC=C)C(=O)OCC(C)(COC(=O)C(C)(COCC=C)COC(=C)C=C)C(=O)OCC(COC(=O)C(C)(COC(=O)C(C)(COCC=C)COCC=C)COC(=O)C(C)(COCC=C)COCC=C)(COC(=O)C(C)(COC(=O)C(C)(COCC=C)COCC=C)COC(=O)C(C)(COCC=C)COCC=C)COC(=O)C(C)(COC(=O)C(C)(COCC=C)COCC=C)COC(=O)C(C)(COCC=C)COCC=C ; O=C(/C=C/c1ccccc1)OCCCCCCOc1cc(OCCCCCCOC(=O)/C=C/c2ccccc2)cc(OCCCCCCOC(=O)/C=C/c2ccccc2)c1]

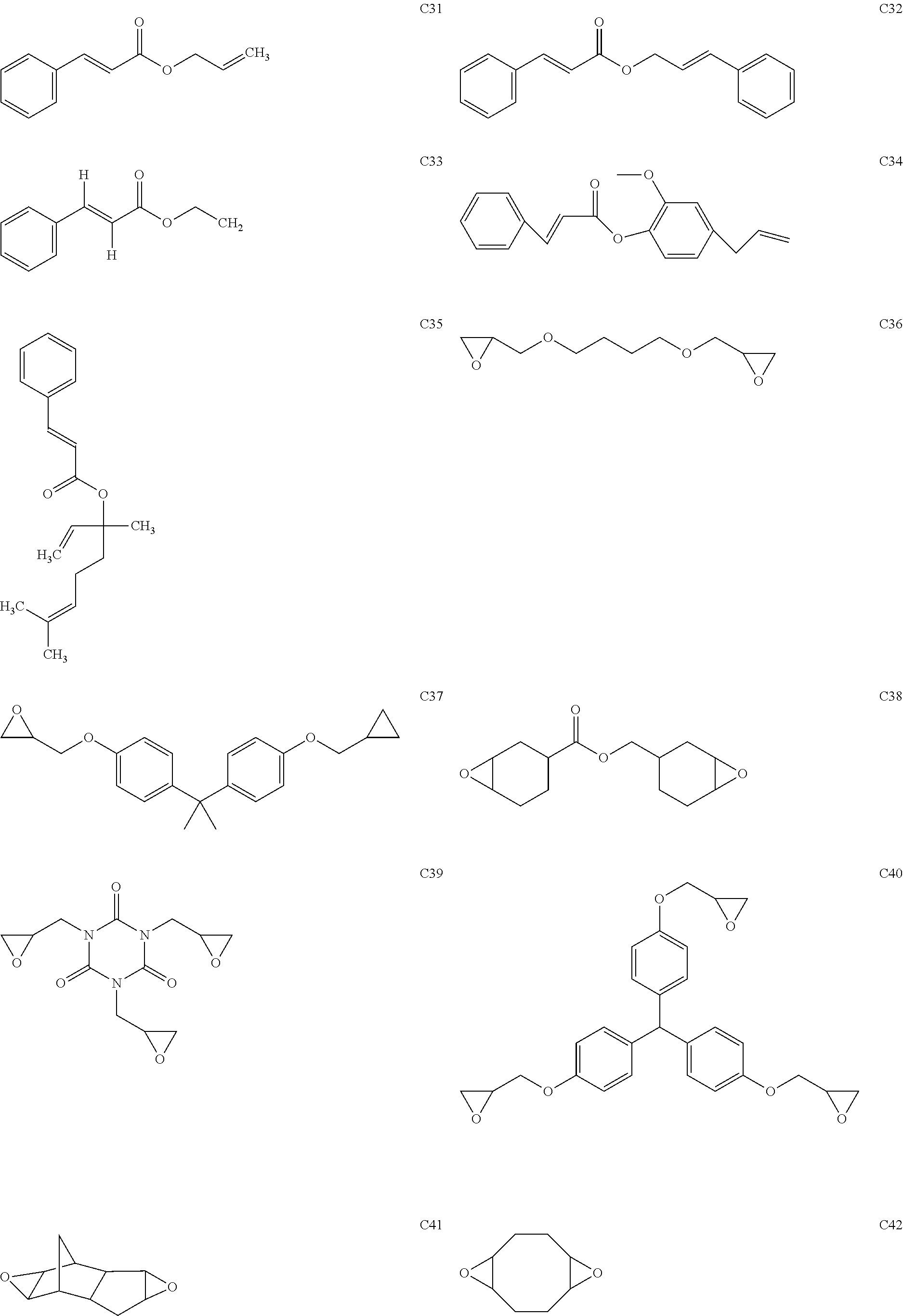

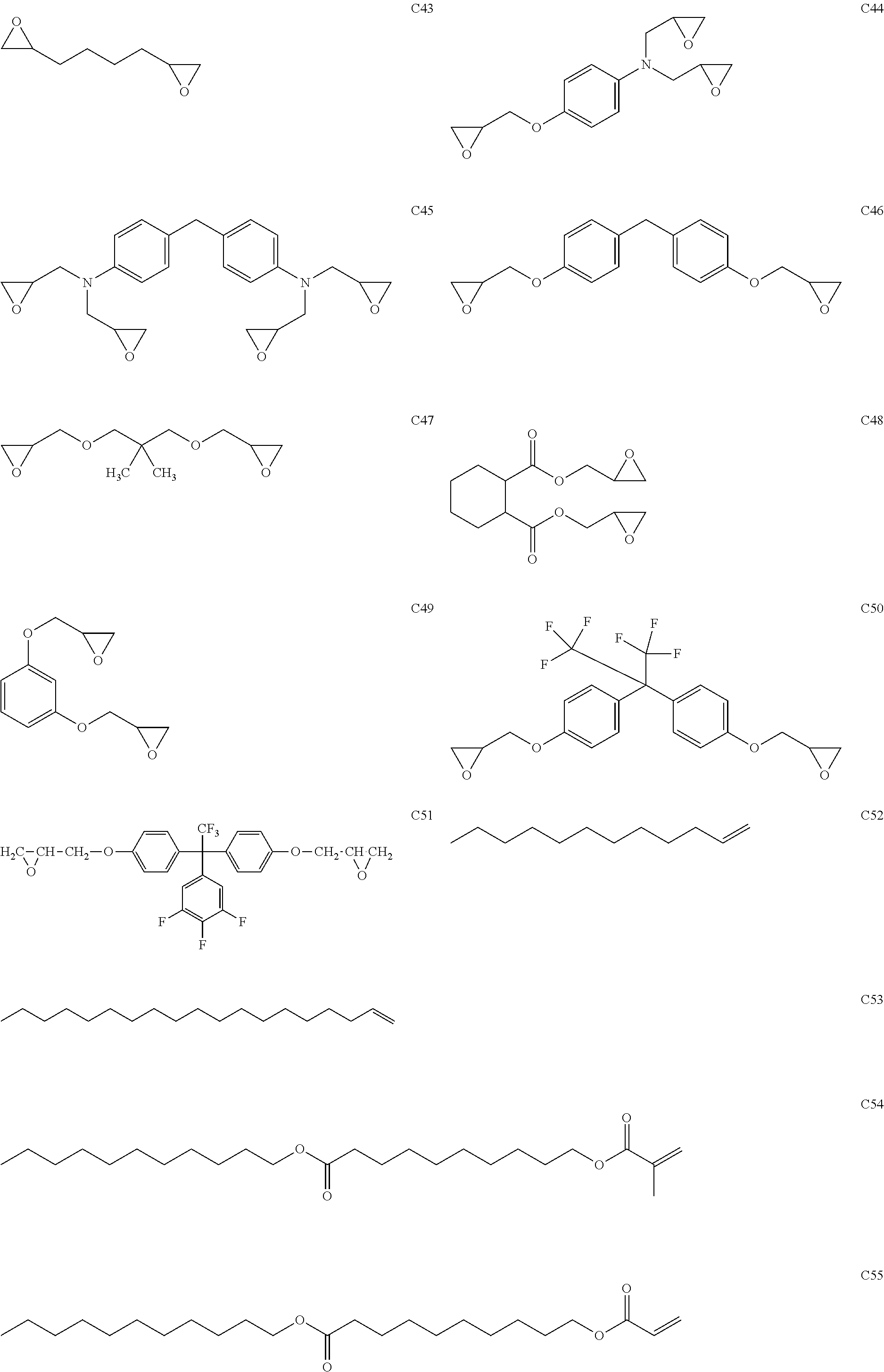

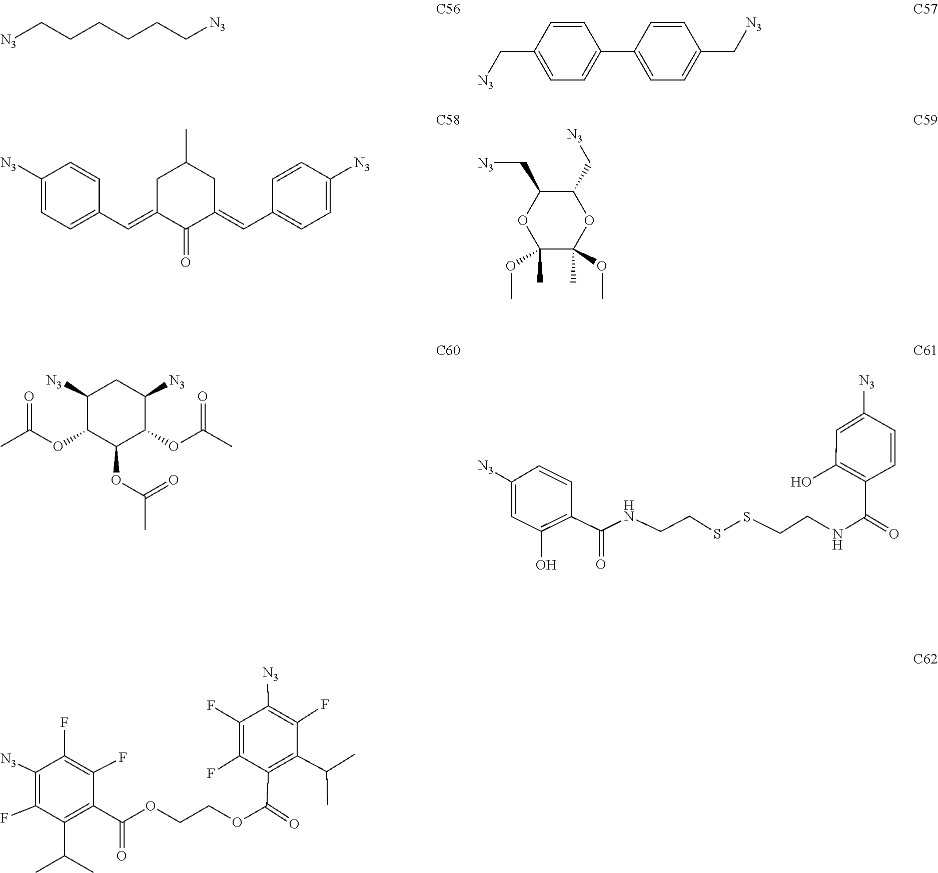

or, (C) a combination thereof.

### BRIEF DESCRIPTION OF THE DRAWINGS

The disclosure will become more fully understood from the following detailed description, taken in conjunction with the accompanying figures, in which:

FIGS. 1A to 1E illustrate traditional patterning techniques of organic semiconductor blends utilizing photoresists.

FIGS. 2A to 2C illustrate patterning techniques of organic semiconductor blends, according to some embodiments.

FIG. 3 illustrates an exemplary OTFT device, according to some embodiments.

FIG. 4 illustrates an exemplary OTFT device, according to some embodiments.

FIGS. 5A and 5B illustrate a photo patterning of the cross-bred OSC polymer using chlorobenzene for dissolving and rinsing, according to some embodiments.

### DETAILED DESCRIPTION

Reference will now be made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments. It should be understood that the present application is not limited to the details or methodology set forth in the description or illustrated in the figures. It should also be understood that the terminology is for the purpose of description only and should not be regarded as limiting.

Additionally, any examples set forth in this specification are illustrative, but not limiting, and merely set forth some of the many possible embodiments of the claimed invention. Other suitable modifications and adaptations of the variety of conditions and parameters normally encountered in the field, and which would be apparent to those skilled in the art, are within the spirit and scope of the disclosure.

### Definitions

The term “alkyl group” refers to a monoradical branched or unbranched saturated hydrocarbon chain having 1 to 40 carbon atoms. This term is exemplified by groups such as methyl, ethyl, n-propyl, isopropyl, n-butyl, isobutyl, t-butyl, pentyl, n-hexyl, n-heptyl, n-octyl, n-decyl, or tetradecyl, and the like. The alkyl group can be substituted or unsubstituted.

The term “substituted alkyl group” refers to: (1) an alkyl group as defined above, having 1, 2, 3, 4 or 5 substituents, typically 1 to 3 substituents, selected from the group consisting of alkenyl, alkynyl, alkoxy, aralkyl, aldehyde, cycloalkyl, cycloalkenyl, acyl, acylamino, acyl halide, acyloxy, amino, aminocarbonyl, alkoxycarbonylamino, azido, cyano, halogen, hydroxy, keto, thiocarbonyl, carboxy, carboxyalkyl, arylthiol, ester, heteroarylthio, heterocyclylthio, hydroxyl, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO-alkyl, —SO-aryl, —SO-heteroaryl, —SO₂-alkyl, —SO₂-aryl and —SO₂-heteroaryl, thioalkyl, vinyl ether. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2; or (2) an alkyl group as defined above that is interrupted by 1-10 atoms independently chosen from oxygen, sulfur and NRₐ, where Rₐ is chosen from hydrogen, alkyl, cycloalkyl, alkenyl, cycloalkenyl, alkynyl, aryl, heteroaryl and heterocyclyl. All substituents may be optionally further substituted by alkyl, alkoxy, halogen, CF₃, amino, substituted amino, cyano, or —S(O)ₙR_{SO}, in which R_{SO} is alkyl, aryl, or heteroaryl and n is 0, 1 or 2; or (3) an alkyl group as defined above that has both 1, 2, 3, 4 or 5 substituents as defined above and is also interrupted by 1-10 atoms as defined above. For example, the alkyl groups can be an alkyl hydroxy group, where any of the hydrogen atoms of the alkyl group are substituted with a hydroxyl group.

The term “alkyl group” as defined herein also includes cycloalkyl groups. The term “cycloalkyl group” as used herein is a non-aromatic carbon-based ring (i.e., carbocyclic) composed of at least three carbon atoms, and in some embodiments from three to 20 carbon atoms, having a single cyclic ring or multiple condensed rings. Examples of single ring cycloalkyl groups include, but are not limited to, cyclopropyl, cyclobutyl, cyclopentyl, cyclohexyl, cyclooctyl, and the like. Examples of multiple ring cycloalkyl groups include, but are not limited to, adamantanyl, bicyclo[2.2.1]heptane, 1,3,3-trimethylbicyclo[2.2.1]hept-2-yl, (2,3,3-trimethylbicyclo[2.2.1]hept-2-yl), or carbocyclic groups to which is fused an aryl group, for example indane, and the like. The term cycloalkyl group also includes a heterocycloalkyl group, where at least one of the carbon atoms of the ring is substituted with a heteroatom such as, but not limited to, nitrogen, oxygen, sulfur, or phosphorus.

The term “unsubstituted alkyl group” is defined herein as an alkyl group composed of just carbon and hydrogen.

The term “acyl” denotes a group —C(O)R_{CO}, in which R_{CO} is hydrogen, optionally substituted alkyl, optionally substituted cycloalkyl, optionally substituted heterocyclyl, optionally substituted aryl, and optionally substituted heteroaryl.

The term “aryl group” as used herein is any carbon-based aromatic group (i.e., aromatic carbocyclic) such as having a single ring (e.g., phenyl) or multiple rings (e.g., biphenyl), or multiple condensed (fused) rings (e.g., naphthyl or anthryl). These may include, but are not limited to, benzene, naphthalene, phenyl, etc.

The term “aryl group” also includes “heteroaryl group,” meaning a radical derived from an aromatic cyclic group (i.e., fully unsaturated) having 1, 2, 3, 4, 5, 6, 7, 8, 9, 10, 11, 12, 13, 14, or 15 carbon atoms and 1, 2, 3 or 4 heteroatoms selected from oxygen, nitrogen, sulfur, and phosphorus within at least one ring. In other words, heteroaryl groups are aromatic rings composed of at least three carbon atoms that has at least one heteroatom incorporated within the ring of the aromatic group. Such heteroaryl groups can have a single ring (e.g., pyridyl or furyl) or multiple condensed rings (e.g., indolizinyl, benzothiazolyl, or benzothienyl). Examples of heteroaryls include, but are not limited to, [1,2,4]oxadiazole, [1,3,4]oxadiazole, [1,2,4]thiadiazole, [1,3,4]thiadiazole, pyrrole, imidazole, pyrazole, pyridine, pyrazine, pyrimidine, pyridazine, indolizine, isoindole, indole, indazole, purine, quinolizine, isoquinoline, quinoline, phthalazine, naphthylpyridine, quinoxaline, quinazoline, cinnoline, pteridine, carbazole, carboline, phenanthridine, acridine, phenanthroline, isothiazole, phenazine, isoxazole, phenoxazine, phenothiazine, imidazolidine, imidazoline, triazole, oxazole, thiazole, naphthyridine, and the like as well as N-oxide and N-alkoxy derivatives of nitrogen containing heteroaryl compounds, for example pyridine-N-oxide derivatives.

Unless otherwise constrained by the definition for the heteroaryl substituent, such heteroaryl groups can be optionally substituted with 1 to 5 substituents, typically 1 to 3 substituents selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclylthio, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO— alkyl, —SO-aryl, —SO— heteroaryl, —SO₂-alkyl, SO₂-aryl and —SO₂-heteroaryl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The aryl group can be substituted or unsubstituted. Unless otherwise constrained by the definition for the aryl substituent, such aryl groups can optionally be substituted with from 1 to 5 substituents, typically 1 to 3 substituents, selected from the group consisting of alkyl, alkenyl, alkynyl, alkoxy, aldehyde, cycloalkyl, cycloalkenyl, acyl, acylamino, acyloxy, amino, aminocarbonyl, alkoxycarbonylamino, azido, cyano, ester, halogen, hydroxy, keto, thiocarbonyl, carboxy, carboxyalkyl, arylthio, heteroarylthio, heterocyclylthio, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO-alkyl, —SO-aryl, —SO-heteroaryl, —SO₂-alkyl, SO₂-aryl and —SO₂-heteroaryl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2. In some embodiments, the term “aryl group” is limited to substituted or unsubstituted aryl and heteroaryl rings having from three to 30 carbon atoms.

The term “aralkyl group” as used herein is an aryl group having an alkyl group or an alkylene group as defined herein covalently attached to the aryl group. An example of an aralkyl group is a benzyl group. “Optionally substituted aralkyl” refers to an optionally substituted aryl group covalently linked to an optionally substituted alkyl group or alkylene group. Such aralkyl groups are exemplified by benzyl, phenylethyl, 3-(4-methoxyphenyl)propyl, and the like.

The term “heteroaralkyl” refers to a heteroaryl group covalently linked to an alkylene group, where heteroaryl and alkylene are defined herein. “Optionally substituted heteroaralkyl” refers to an optionally substituted heteroaryl group covalently linked to an optionally substituted alkylene group. Such heteroaralkyl groups are exemplified by 3-pyridylmethyl, quinolin-8-ylethyl, 4-methoxythiazol-2-ylpropyl, and the like.

The term “alkenyl group” refers to a monoradical of a branched or unbranched unsaturated hydrocarbon group typically having from 2 to 40 carbon atoms, more typically 2 to 10 carbon atoms and even more typically 2 to 6 carbon atoms and having 1-6, typically 1, double bond (vinyl). Typical alkenyl groups include ethenyl or vinyl (—CH═CH₂), 1-propylene or allyl (—CH₂CH═CH₂), isopropylene (—C(CH₃)═CH₂), bicyclo[2.2.1]heptene, and the like. When alkenyl is attached to nitrogen, the double bond cannot be alpha to the nitrogen.

The term “substituted alkenyl group” refers to an alkenyl group as defined above having 1, 2, 3, 4 or 5 substituents, and typically 1, 2, or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclylthio, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO— alkyl, —SO-aryl, —SO— heteroaryl, —SO₂-alkyl, SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “cycloalkenyl group” refers to carbocyclic groups of from 3 to 20 carbon atoms having a single cyclic ring or multiple condensed rings with at least one double bond in the ring structure.

The term “alkynyl group” refers to a monoradical of an unsaturated hydrocarbon, typically having from 2 to 40 carbon atoms, more typically 2 to 10 carbon atoms and even more typically 2 to 6 carbon atoms and having at least 1 and typically from 1-6 sites of acetylene (triple bond) unsaturation. Typical alkynyl groups include ethynyl, (—C≡CH), propargyl (or prop-1-yn-3-yl, —CH₂C≡CH), and the like. When alkynyl is attached to nitrogen, the triple bond cannot be alpha to the nitrogen.

The term “substituted alkynyl group” refers to an alkynyl group as defined above having 1, 2, 3, 4 or 5 substituents, and typically 1, 2, or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclylthio, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO-alkyl, —SO-aryl, —SO-heteroaryl, —SO₂-alkyl, SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “alkylene group” is defined as a diradical of a branched or unbranched saturated hydrocarbon chain, having 1, 2, 3, 4, 5, 6, 7, 8, 9, 10, 11, 12, 13, 14, 15, 16, 17, 18, 19 or 20 carbon atoms, typically 1-10 carbon atoms, more typically 1, 2, 3, 4, 5 or 6 carbon atoms. This term is exemplified by groups such as methylene (—CH₂—), ethylene (—CH₂CH₂—), the propylene isomers (e.g., —CH₂CH₂CH₂— and —CH(CH₃)CH₂—) and the like.

The term “substituted alkylene group” refers to: (1) an alkylene group as defined above having 1, 2, 3, 4, or 5 substituents selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclylthio, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO-alkyl, —SO-aryl, —SO-heteroaryl, —SO₂-alkyl, —SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2; or (2) an alkylene group as defined above that is interrupted by 1-20 atoms independently chosen from oxygen, sulfur and NRₐ—, where Rₐ is chosen from hydrogen, optionally substituted alkyl, cycloalkyl, cycloalkenyl, aryl, heteroaryl and heterocyclyl, or groups selected from carbonyl, carboxyester, carboxyamide and sulfonyl; or (3) an alkylene group as defined above that has both 1, 2, 3, 4 or 5 substituents as defined above and is also interrupted by 1-20 atoms as defined above. Examples of substituted alkylenes are chloromethylene (—CH(Cl)—), aminoethylene (—CH(NH₂)CH₂—), methylaminoethylene (—CH(NHMe)CH₂—), 2-carboxypropylene isomers (—CH₂CH(CO₂H)CH₂—), ethoxyethyl (—CH₂CH₂O—CH₂CH₂—), ethylmethylaminoethyl (—CH₂CH₂N(CH₃)CH₂CH₂—), and the like.

The term “alkoxy group” refers to the group R—O—, where R is an optionally substituted alkyl or optionally substituted cycloalkyl, or R is a group —Y—Z, in which Y is optionally substituted alkylene and Z is optionally substituted alkenyl, optionally substituted alkynyl; or optionally substituted cycloalkenyl, where alkyl, alkenyl, alkynyl, cycloalkyl and cycloalkenyl are as defined herein. Typical alkoxy groups are optionally substituted alkyl-O— and include, by way of example, methoxy, ethoxy, n-propoxy, iso-propoxy, n-butoxy, tert-butoxy, sec-butoxy, n-pentoxy, n-hexoxy, 1,2-dimethylbutoxy, trifluoromethoxy, and the like.

The term “alkylthio group” refers to the group R_{S}—S—, where R_{S} is as defined for alkoxy.

The term “aminocarbonyl” refers to the group —C(O)NR_{N}R_{N} where each R_{N} is independently hydrogen, alkyl, aryl, heteroaryl, heterocyclyl or where both R_{N} groups are joined to form a heterocyclic group (e.g., morpholino). Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “acylamino” refers to the group —NR_{NCO}C(O)R where each R_{NCO} is independently hydrogen, alkyl, aryl, heteroaryl, or heterocyclyl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “acyloxy” refers to the groups —O(O)C-alkyl, —O(O)C-cycloalkyl, —O(O)C-aryl, —O(O)C-heteroaryl, and —O(O)C-heterocyclyl. Unless otherwise constrained by the definition, all substituents may be optionally further substituted by alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “aryloxy group” refers to the group aryl-O— wherein the aryl group is as defined above, and includes optionally substituted aryl groups as also defined above.

The term “heteroaryloxy” refers to the group heteroaryl-O—.

The term “amino” refers to the group —NH₂.

The term “substituted amino” refers to the group —NR_{w}R_{w} where each R_{w} is independently selected from the group consisting of hydrogen, alkyl, cycloalkyl, carboxyalkyl (for example, benzyloxycarbonyl), aryl, heteroaryl and heterocyclyl provided that both R_{w} groups are not hydrogen, or a group —Y—Z, in which Y is optionally substituted alkylene and Z is alkenyl, cycloalkenyl, or alkynyl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “carboxy” refers to a group —C(O)OH. The term “carboxyalkyl group” refers to the groups —C(O)O-alkyl or —C(O)O-cycloalkyl, where alkyl and cycloalkyl, are as defined herein, and may be optionally further substituted by alkyl, alkenyl, alkynyl, alkoxy, halogen, CF₃, amino, substituted amino, cyano, and —S(O)ₙR_{SO}, in which R_{SO} is alkyl, aryl, or heteroaryl and n is 0, 1 or 2.

The terms “substituted cycloalkyl group” or “substituted cycloalkenyl group” refer to cycloalkyl or cycloalkenyl groups having 1, 2, 3, 4 or 5 substituents, and typically 1, 2, or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclylthio, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO-alkyl, —SO-aryl, —SO-heteroaryl, —SO₂-alkyl, SO₂-aryl and —SO₂-heteroaryl. Unless otherwise constrained by the definition, all substituents may optionally be further substituted by 1, 2, or 3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “conjugated group” is defined as a linear, branched or cyclic group, or combination thereof, in which p-orbitals of the atoms within the group are connected via delocalization of electrons and wherein the structure can be described as containing alternating single and double or triple bonds and may further contain lone pairs, radicals, or carbenium ions.

Conjugated cyclic groups may comprise both aromatic and non-aromatic groups, and may comprise polycyclic or heterocyclic groups, such as diketopyrrolopyrrole. Ideally, conjugated groups are bound in such a way as to continue the conjugation between the thiophene moieties they connect. In some embodiments, “conjugated groups” is limited to conjugated groups having three to 30 carbon atoms.

The term “halogen,” “halo,” or “halide” may be referred to interchangeably and refer to fluoro, bromo, chloro, and iodo.

The term “heterocyclyl” refers to a monoradical saturated or partially unsaturated group having a single ring or multiple condensed rings, having from 1 to 40 carbon atoms and from 1 to 10 hetero atoms, typically 1, 2, 3 or 4 heteroatoms, selected from nitrogen, sulfur, phosphorus, and/or oxygen within the ring. Heterocyclic groups can have a single ring or multiple condensed rings, and include tetrahydrofuranyl, morpholino, piperidinyl, piperazino, dihydropyridino, and the like.

Unless otherwise constrained by the definition for the heterocyclyl substituent, such heterocyclyl groups can be optionally substituted with 1, 2, 3, 4 or 5, and typically 1, 2 or 3 substituents, selected from the group consisting of alkyl, alkenyl, alkynyl, alkoxy, cycloalkyl, cycloalkenyl, acyl, acylamino, acyloxy, amino, aminocarbonyl, alkoxycarbonylamino, azido, cyano, halogen, hydroxy, keto, thiocarbonyl, carboxy, carboxyalkyl, arylthio, heteroarylthio, heterocyclylthio, thiol, alkylthio, aryl, aryloxy, heteroaryl, aminosulfonyl, aminocarbonylamino, heteroaryloxy, heterocyclyl, heterocyclooxy, hydroxyamino, alkoxyamino, nitro, —SO-alkyl, —SO-aryl, —SO-heteroaryl, —SO₂-alkyl, —SO₂-aryl and —SO₂-heteroaryl. Unless otherwise constrained by the definition, all substituents may optionally be further substituted by 1-3 substituents chosen from alkyl, carboxy, carboxyalkyl, aminocarbonyl, hydroxy, alkoxy, halogen, CF₃, amino, substituted amino, cyano, and —S(O)ₙR_{SO}, where R_{SO} is alkyl, aryl, or heteroaryl and n is 0, 1 or 2.

The term “thiol” refers to the group —SH. The term “substituted alkylthio” refers to the group —S-substituted alkyl. The term “arylthiol group” refers to the group aryl-S—, where aryl is as defined as above. The term “heteroarylthiol” refers to the group —S-heteroaryl wherein the heteroaryl group is as defined above including optionally substituted heteroaryl groups as also defined above.

The term “sulfoxide” refers to a group —S(O)R_{SO}, in which R_{SO} is alkyl, aryl, or heteroaryl. The term “substituted sulfoxide” refers to a group —S(O)R_{SO}, in which R_{SO} is substituted alkyl, substituted aryl, or substituted heteroaryl, as defined herein. The term “sulfone” refers to a group —S(O)₂R_{SO}, in which R_{SO} is alkyl, aryl, or heteroaryl. The term “substituted sulfone” refers to a group —S(O)₂R_{SO}, in which R_{SO} is substituted alkyl, substituted aryl, or substituted heteroaryl, as defined herein.

The term “keto” refers to a group —C(O)—. The term “thiocarbonyl” refers to a group —C(S)—.

As used herein, the term “room temperature” is 20° C. to 25° C.

Disclosed are compounds, compositions, and components that can be used for, can be used in conjunction with, can be used in preparation of, or are products of the disclosed methods and compositions. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. Thus, if a class of molecules A, B, and C are disclosed as well as a class of molecules D, E, and F and an example of a combination molecule, A-D is disclosed, then even if each is not individually recited, each is individually and collectively contemplated. Thus, in this example, each of the combinations A-E, A-F, B-D, B-E, B-F, C-D, C-E, and C-F are specifically contemplated and should be considered disclosed from disclosure of A, B, and C; D, E, and F; and the example combination A-D. Likewise, any subset or combination of these is also specifically contemplated and disclosed. Thus, for example, the sub-group of A-E, B-F, and C-E are specifically contemplated and should be considered disclosed from disclosure of A, B, and C; D, E, and F; and the example combination A-D. This concept applies to all aspects of this disclosure including, but not limited to, steps in methods of making and using the disclosed compositions. Thus, if there are a variety of additional steps that can be performed it is understood that each of these additional steps can be performed with any specific embodiment or combination of embodiments of the disclosed methods, and that each such combination is specifically contemplated and should be considered disclosed.

A weight percent of a component, unless specifically stated to the contrary, is based on the total weight of the formulation or composition in which the component is included.

Organic semiconductors as functional materials may be used in a variety of applications including, for example, printed electronics, organic transistors, including organic thin-film transistors (OTFTs) and organic field-effect transistors (OFETs), organic light-emitting diodes (OLEDs), organic integrated circuits, organic solar cells, and disposable sensors. Organic transistors may be used in many applications, including smart cards, security tags, and the backplanes of flat panel displays. Organic semiconductors may substantially reduce cost compared to inorganic counterparts, such as silicon. Depositing OSCs from solution may enable fast, large-area fabrication routes such as various printing methods and roll-to-roll processes.

Organic thin-film transistors are particularly interesting because their fabrication processes are less complex as compared with conventional silicon-based technologies. For example, OTFTs generally rely on low temperature deposition and solution processing, which, when used with semiconducting conjugated polymers, can achieve valuable technological attributes, such as compatibility with simple-write printing techniques, general low-cost manufacturing approaches, and flexible plastic substrates. Other potential applications for OTFTs include flexible electronic papers, sensors, memory devices (e.g., radio frequency identification cards (RFIDs)), remote controllable smart tags for supply chain management, large-area flexible displays, and smart cards.

Organic Semiconductor (OSC) Polymer

An OSC polymer may be used to produce organic semiconductor devices. In some examples, a polymer blend comprises an organic semiconductor polymer. In some examples, the OSC polymer has a main backbone that is fully conjugated. In some examples, the OSC is a diketopyrrolopyrrole (DPP) fused thiophene polymeric material. In some examples, the fused thiophene is beta-substituted. This OSC may contain both fused thiophene and diketopyrrolopyrrole units. In some examples, the OSC is used in OTFT applications. For example, the OSC polymer may comprise the repeat unit of Formula 1 or Formula 2, or a salt, isomer, or analog thereof:

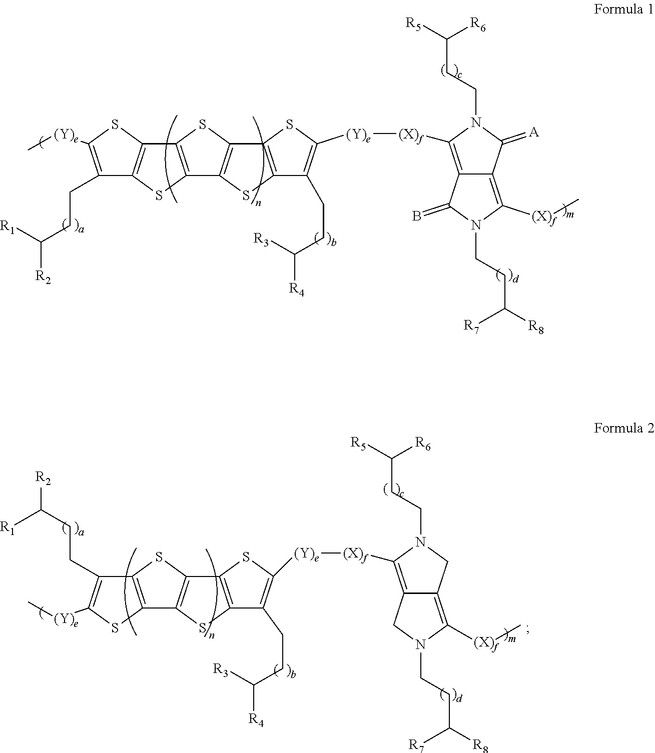

wherein in Formula 1 and Formula 2: m is an integer greater than or equal to one; n is 0, 1, or 2; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl; a, b, c, and d are independently, integers greater than or equal to 3; e and f are integers greater than or equal to zero; X and Y are, independently a covalent bond, an optionally substituted aryl group, an optionally substituted heteroaryl, an optionally substituted fused aryl or fused heteroaryl group, an alkyne or an alkene; and A and B may be, independently, either S or O, with the provisos that: (i) at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl; (ii) if any of R₁, R₂, R₃, or R₄ is hydrogen, then none of R₅, R₆, R₇, or R₈ are hydrogen; (iii) if any of R₅, R₆, R₇, or R₈ is hydrogen, then none of R₁, R₂, R₃, or R₄ are hydrogen; (iv) e and f cannot both be 0; (v) if either e or f is 0, then c and d, independently, are integers greater than or equal to 5; and (iv) the polymer having a molecular weight, wherein the molecular weight of the polymer is greater than 10,000.

In some embodiments, the OSC polymers defined in Formula 1 or Formula 2 enable simple transistor fabrication at relatively low temperatures, which is particularly important for the realization of large-area, mechanically flexible electronics. A beta-substituted OSC polymer can also help to improve solubility.

In some examples, the OSC polymer may comprise a first portion and a second portion, such that at least one of the first portion or the second portion comprises at least one UV-curable side chain. In some examples, the at least one UV-curable side chain comprises at least one of acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof. In some examples, only the first portion comprises the at least one UV-curable side chain. In some examples, only the second portion comprises the at least one UV-curable side chain. In some examples, both the first portion and the second portion comprise the at least one UV-curable side chain.

In some examples, such as when the first portion comprises the at least one UV-curable side chain, the second portion comprises a repeat unit of Formulas 3-6, or a salt, isomer, or analog thereof. In some examples, such as when the second portion comprises the at least one UV-curable side chain, the first portion comprises a repeat unit of Formulas 3-6, or a salt, isomer, or analog thereof. In some examples, R₅ and R₇ are hydrogen and R₆ and R₈ are substituted or unsubstituted C₄ or greater alkenyl in the first portion and the second portion comprises a repeat unit of Formulas 3-6, or a salt, isomer, or analog thereof. In some examples, R₅ and R₇ are hydrogen and R₆ and R₈ are substituted or unsubstituted C₄ or greater alkenyl in the first portion and the second portion. In some examples, at least one of R₅, R₆, R₇, and R₈ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof. In some examples, at least one of R₁, R₂, R₃, and R₄ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

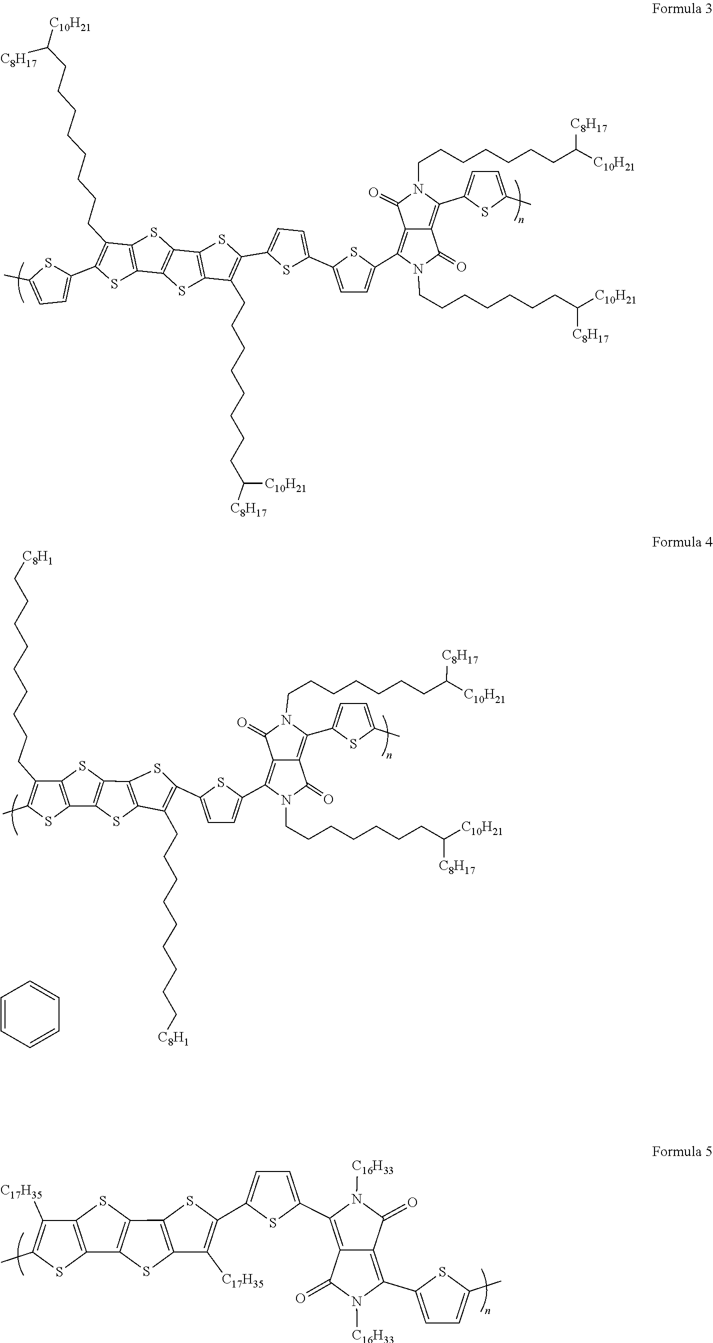

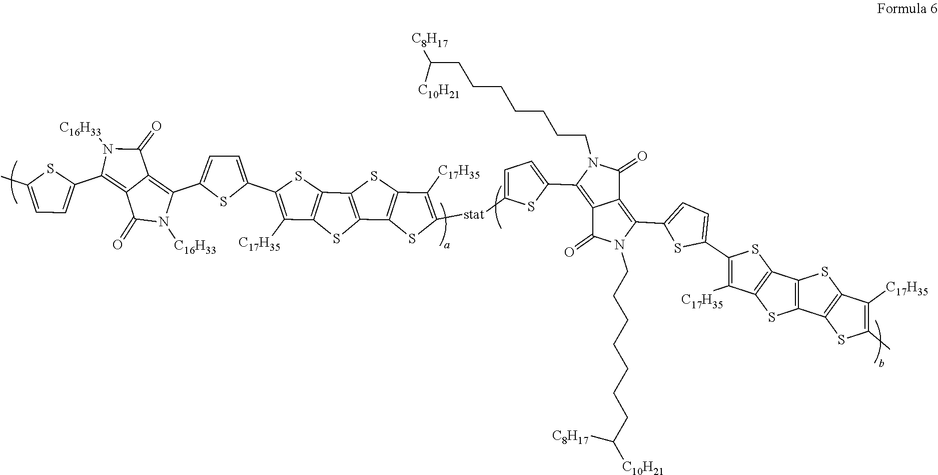

In some examples, the at least one UV-curable side chain comprises at least one of: (A) a polymer selected from:

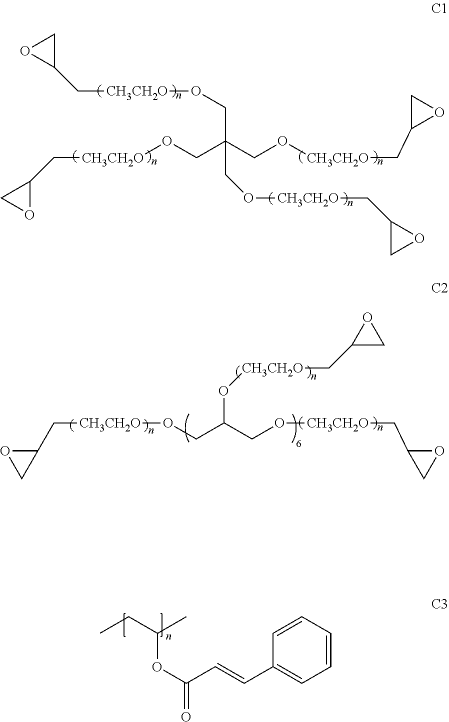

wherein n is an integer greater than or equal to two, or (B) a small-molecule selected from:

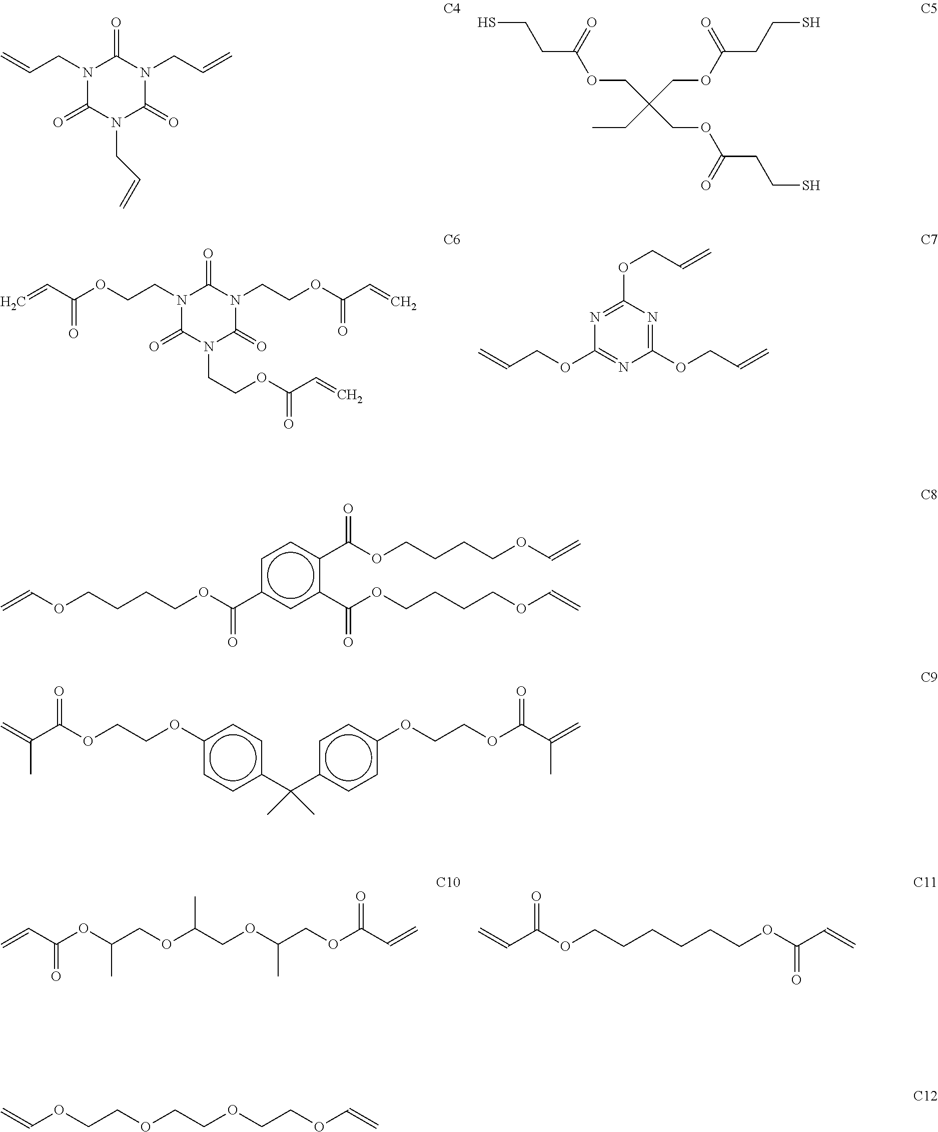

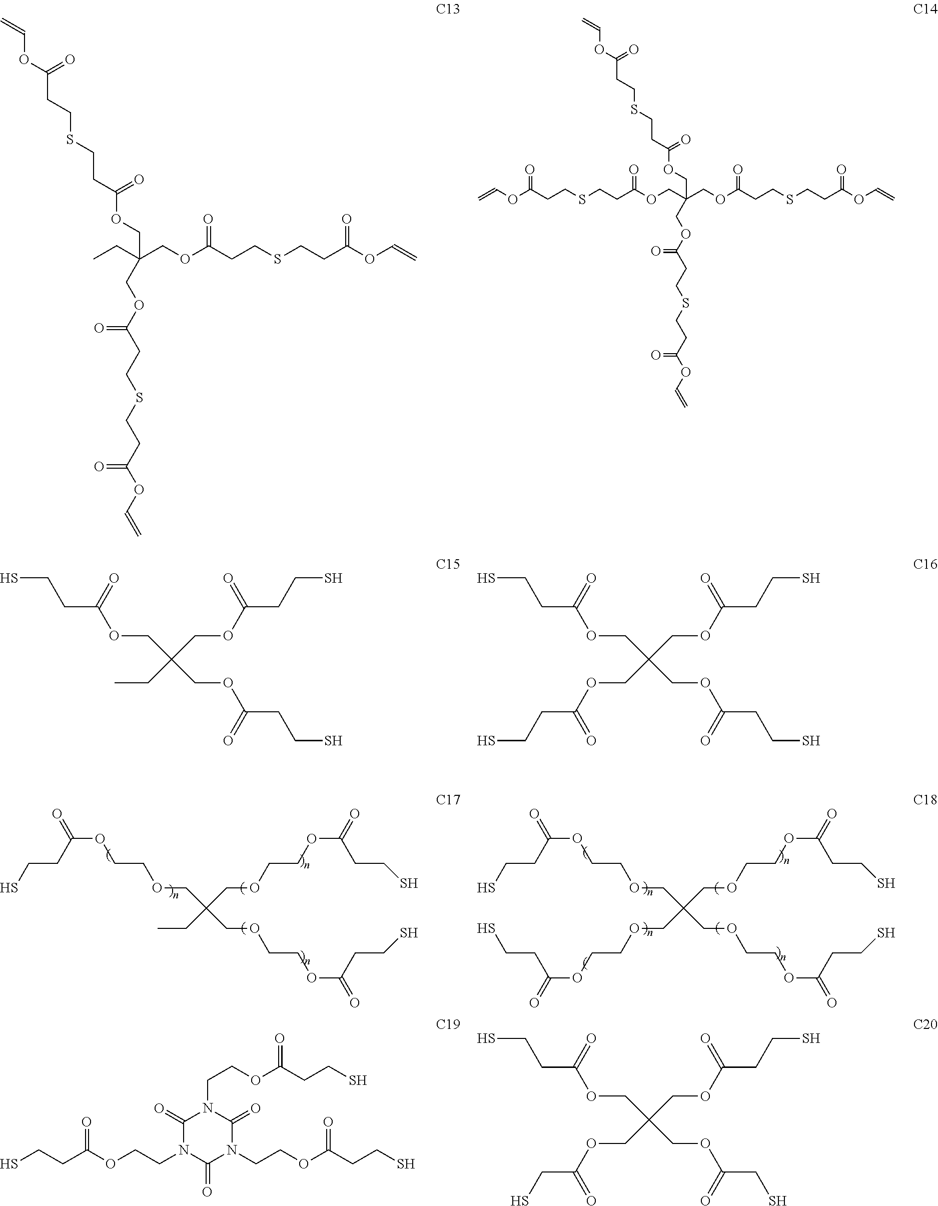

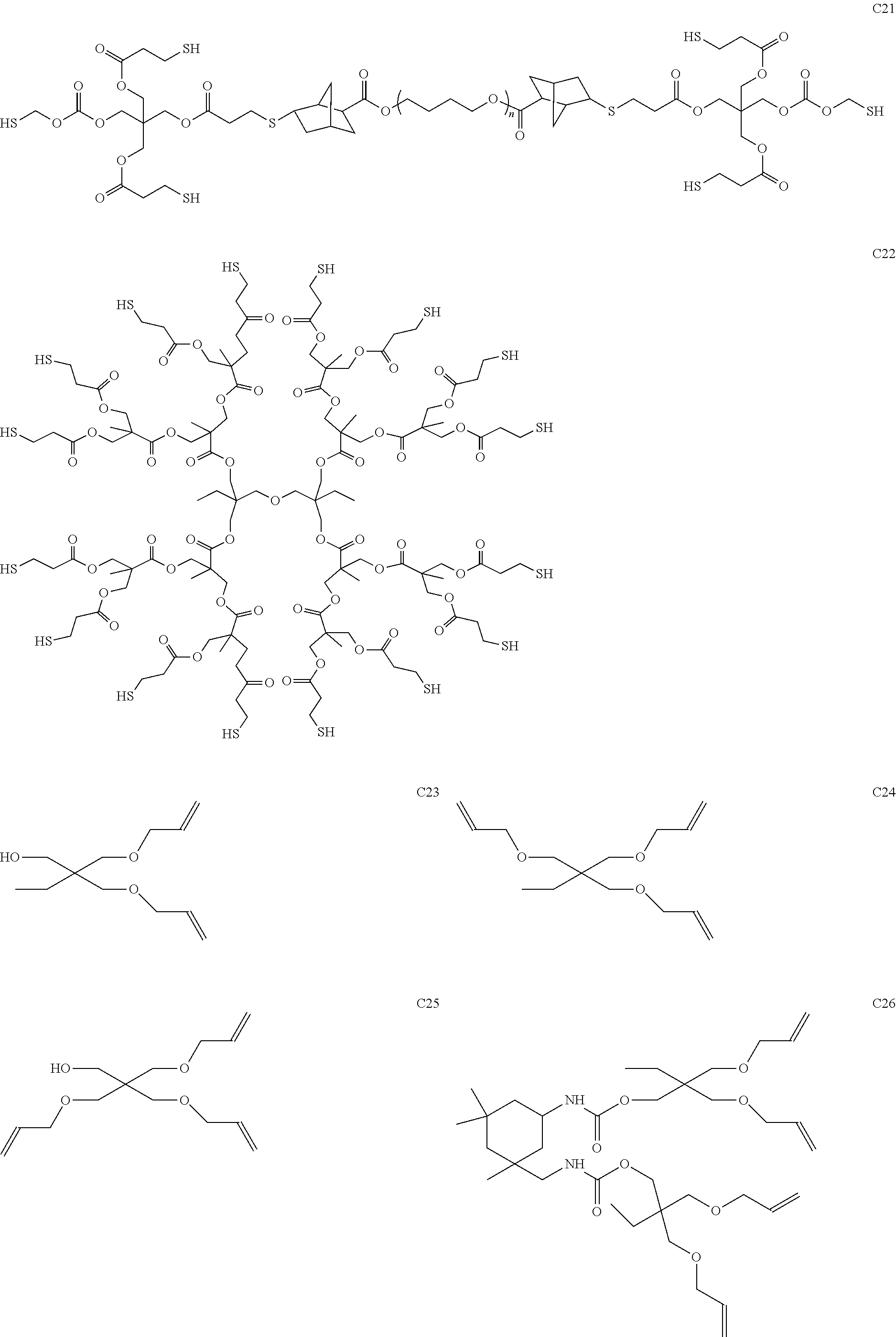

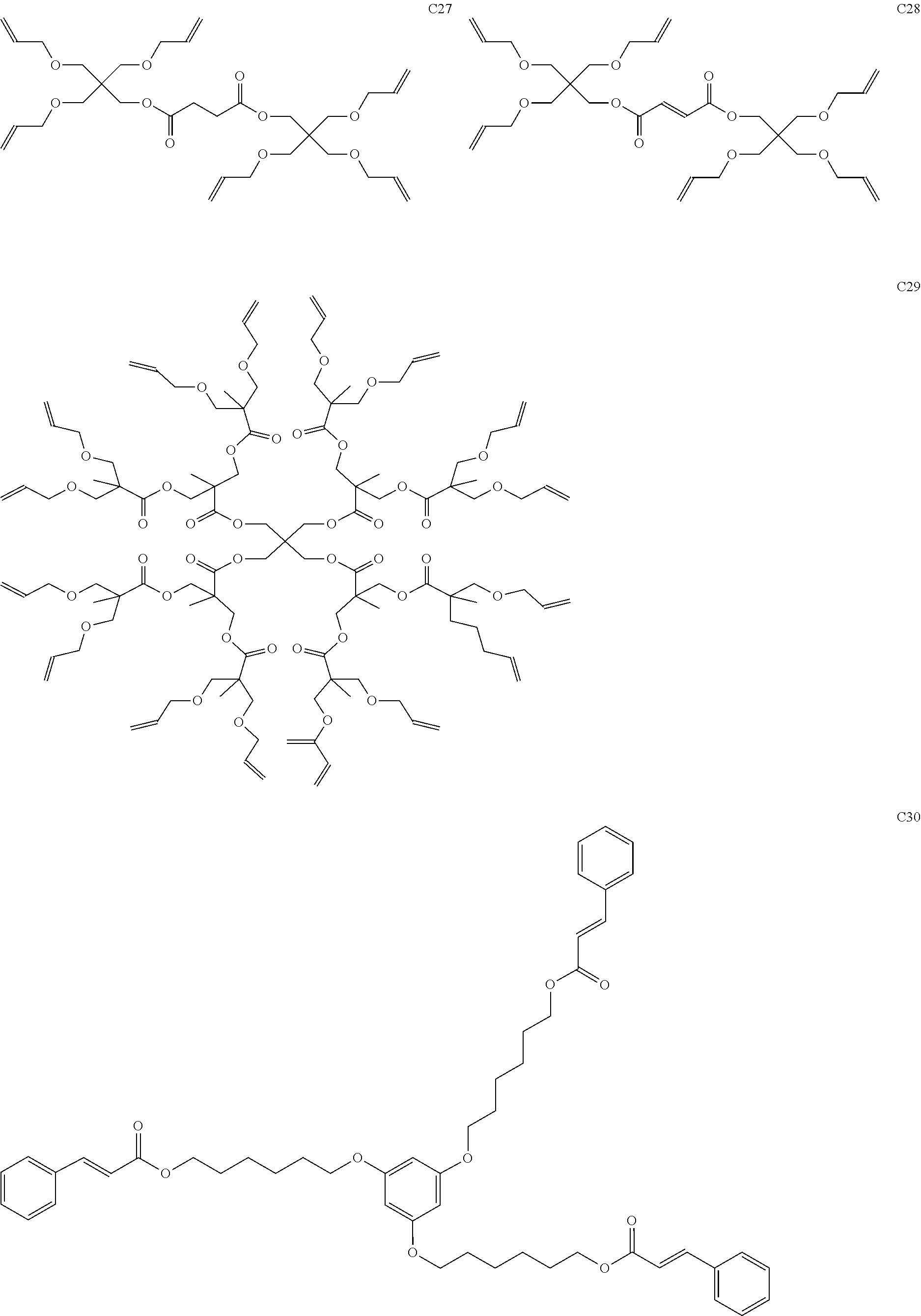 [SMILES: C=CCOCC(COCC=C)(COCC=C)COC(=O)CCC(=O)OCC(COCC=C)(COCC=C)COCC=C ; C=CCOCC(COCC=C)(COCC=C)COC(=O)/C=C/C(=O)OCC(COCC=C)(COCC=C)COCC=C ; C=CCCCC(C)(COCC=C)C(=O)OCC(C)(COC(=O)C(C)(COCC=C)COC(=C)C=C)C(=O)OCC(COC(=O)C(C)(COC(=O)C(C)(COCC=C)COCC=C)COC(=O)C(C)(COCC=C)COCC=C)(COC(=O)C(C)(COC(=O)C(C)(COCC=C)COCC=C)COC(=O)C(C)(COCC=C)COCC=C)COC(=O)C(C)(COC(=O)C(C)(COCC=C)COCC=C)COC(=O)C(C)(COCC=C)COCC=C ; O=C(/C=C/c1ccccc1)OCCCCCCOc1cc(OCCCCCCOC(=O)/C=C/c2ccccc2)cc(OCCCCCCOC(=O)/C=C/c2ccccc2)c1]

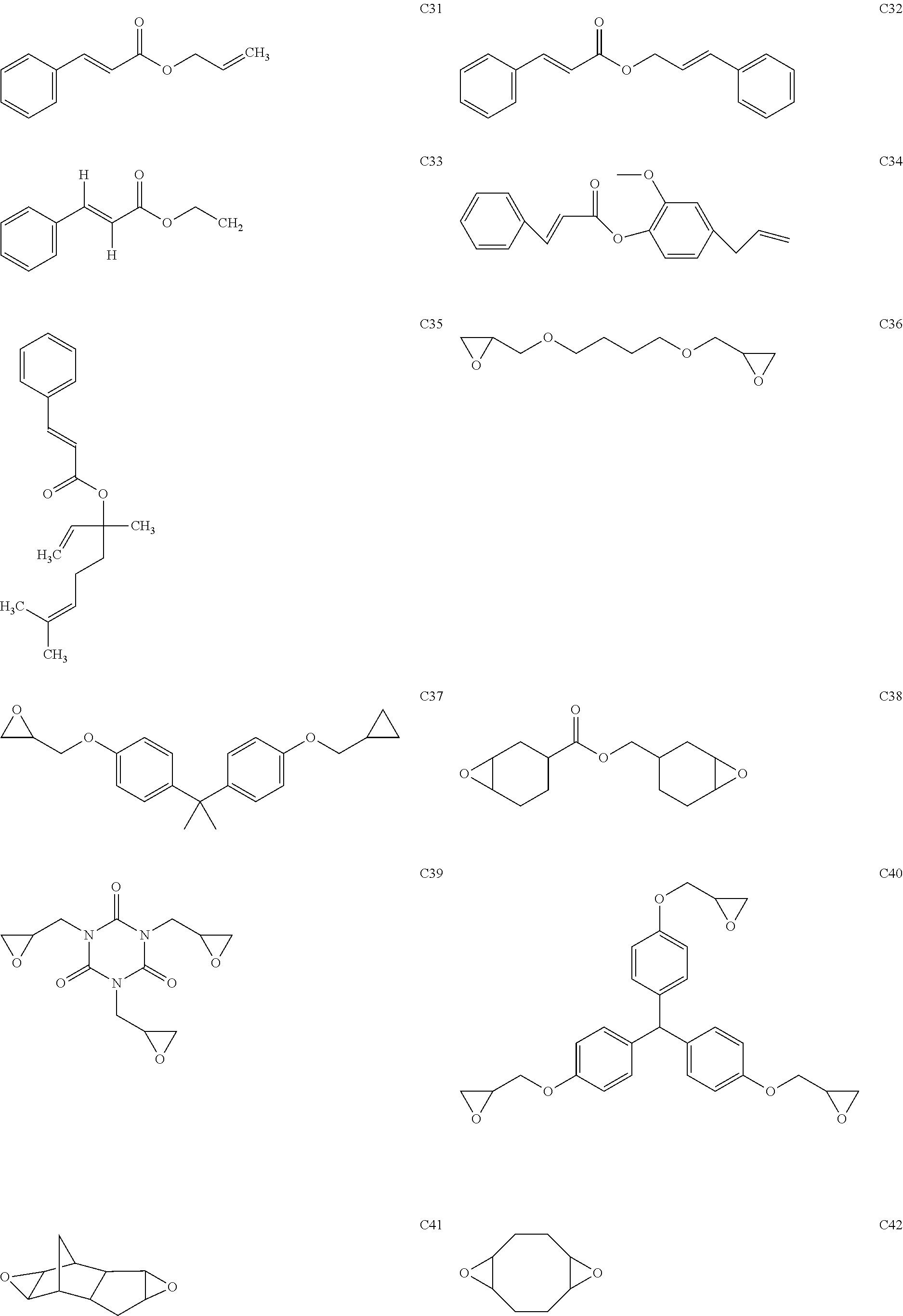

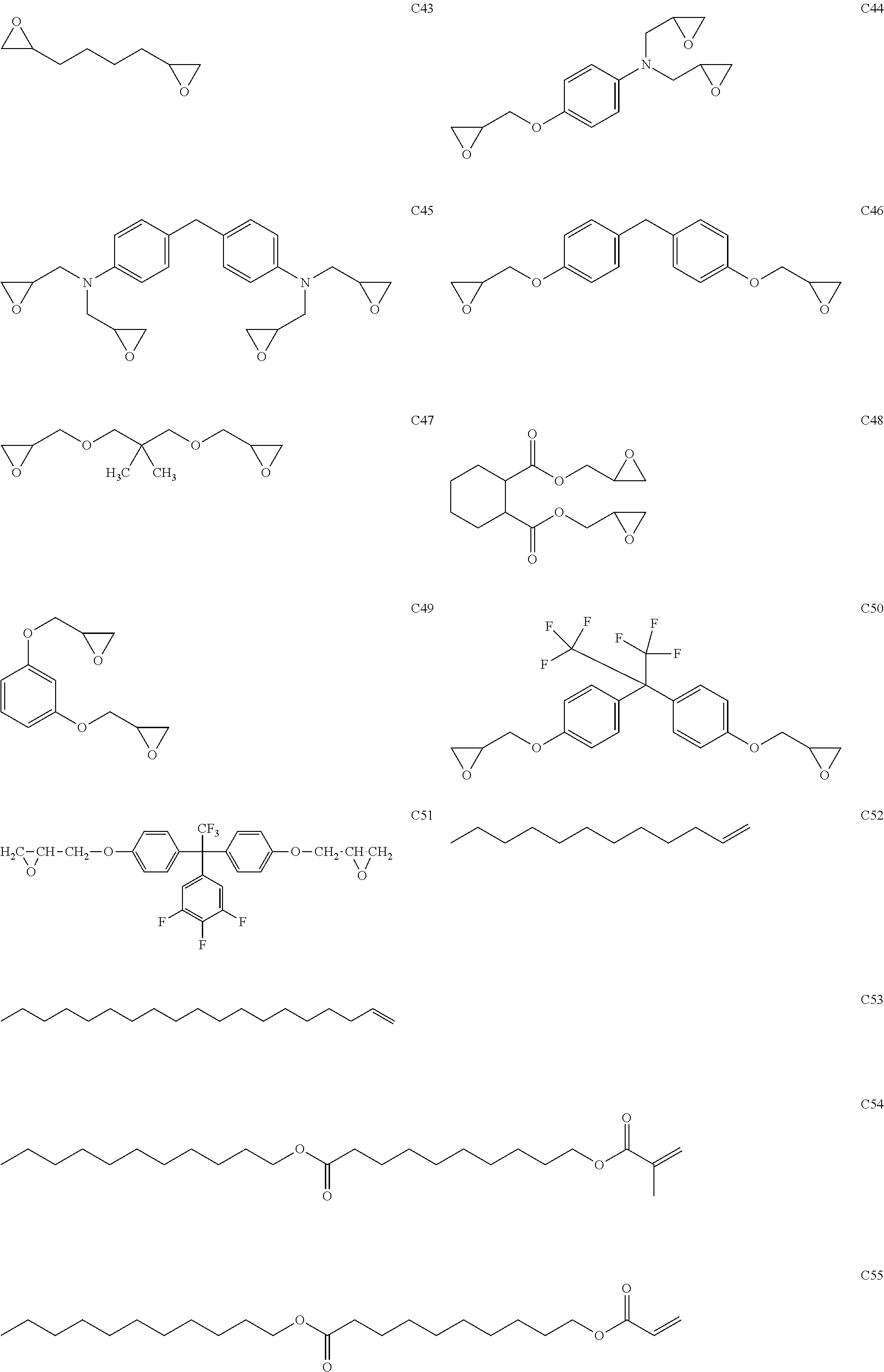

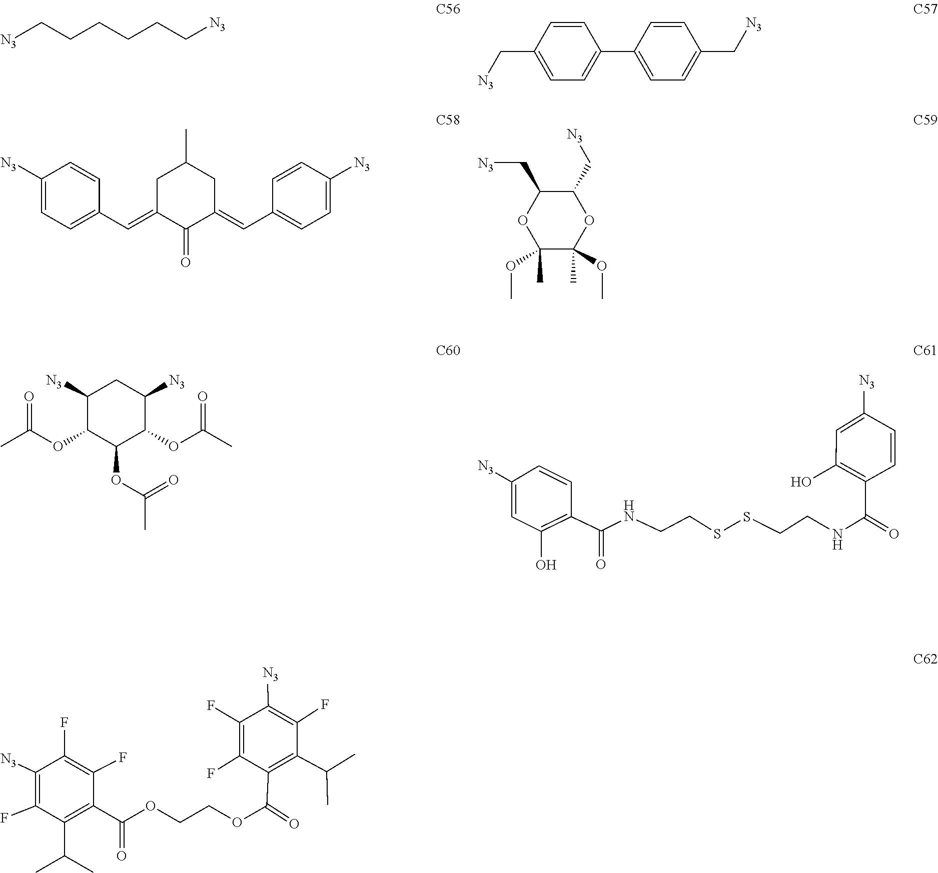

or (C) a combination thereof.

In some examples, the OSC polymer may comprise a structure of Formula 7:

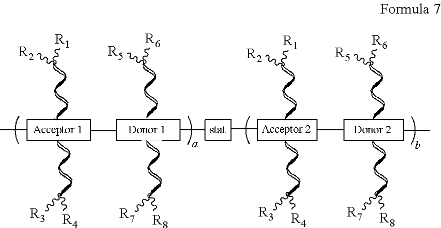

wherein in Formula 7 Acceptor 1 and Acceptor 2 are each electron withdrawing groups; Donor 1 and Donor 2 are electron donating groups; a and b are, independently, integers greater than or equal to one; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl, and wherein: (i) at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl; (ii) if any of R₁, R₂, R₃, or R₄ is hydrogen, then none of R₅, R₆, R₇, or R₈ are hydrogen; (iii) if any of R₅, R₆, R₇, or R₈ is hydrogen, then none of R₁, R₂, R₃, or R₄ are hydrogen; (iv) one of R₁ or R₂ and one of R₃ or R₄ are, independently, connected with Acceptor 1 and Acceptor 2; (v) one of R₅ or R₆ and one of R₇ or R₈ are, independently, connected with Donor 1 and Donor 2; and (vi) the at least one OSC polymer has a molecular weight of greater than 10,000. Electron donating groups are functional groups that donate a portion of their electron density into a conjugated n-system via resonance or inductive effects, thereby making the n-system more nucleophilic. Electron withdrawing groups have an opposite effect on nucleophilicity as an electron donating group, as it removes electron density from a n-system, making the n-system less nucleophilic.

In some examples, R₁ and R₃ are connected with Acceptor 1 and/or Acceptor 2. In some examples, R₁ and R₄ are connected with Acceptor 1 and/or Acceptor 2. In some examples, R₂ and R₃ are connected with Acceptor 1 and/or Acceptor 2. In some examples, R₂ and R₄ are connected with Acceptor 1 and/or Acceptor 2. In some examples, R₅ and R₇ are connected with Donor 1 and/or Donor 2. In some examples, R₅ and R₈ are connected with Donor 1 and/or Donor 2. In some examples, R₆ and R₇ are connected with Donor 1 and/or Donor 2. In some examples, R₆ and R₈ are connected with Donor 1 and/or Donor 2. In some examples, the connection between R₁, R₂, R₃, and/or R₄ to Acceptor 1 and/or Acceptor 2 are, independently, direct connections or connections via an intermediary functionality. In some examples, the connection between R₅, R₆, R₇, and/or R₈ to Donor 1 and/or Donor 2 are, independently, direct connections or connections via an intermediary functionality.

In some examples, Acceptor 1 and Acceptor 2 are independently selected from the group comprising:

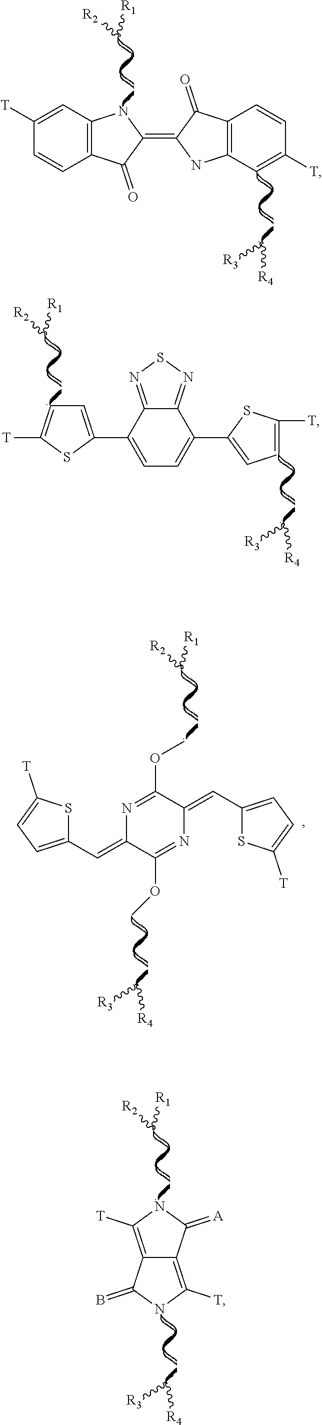

wherein A and B may be, independently, either S or O, and T is a connection terminus to at least one of Donor 1 or Donor 2.

In some examples, Donor 1 and Donor 2 are independently selected from the group comprising: thiophene, benzene, fused thiophene, or combinations thereof. In some examples, at least one of Acceptor 1, Acceptor 2, Donor 1, or Donor 2 comprises at least one UV-curable side chain. In some examples, at least one of R₅, R₆, R₇, and R₈ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof. In some examples, at least one of R₁, R₂, R₃, and R₄ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In some examples, the OSC has a solubility of 0.5 mg/mL, 1 mg/mL, 2 mg/mL, 3 mg/mL, 4 mg/mL, 5 mg/mL, 10 mg/mL, 15 mg/mL, 20 mg/mL, 25 mg/mL, 30 mg/mL, 35 mg/mL, 40 mg/mL, or any value therein, or any range defined by any two of those endpoints. In some examples, the OSC has a solubility of 1 mg/mL or more at room temperature.

In some examples, the OSC has hole mobilities of 1 cm²V⁻¹ s⁻¹, 2 cm²V⁻¹s⁻¹, 3 cm²V⁻¹s⁻¹, 4 cm²V⁻¹ s⁻¹, 5 cm²V⁻¹s⁻¹, 10 cm²V⁻¹s⁻¹, 15 cm²V⁻¹ s⁻¹, 20 cm²V⁻¹s⁻¹, 25 cm²V⁻¹s⁻¹, 30 cm²V⁻¹s⁻¹, 35 cm²V⁻¹s⁻¹, 40 cm²V⁻¹s⁻¹, or any value therein, or any range defined by any two of those endpoints. The hole mobilities may be equal to or greater than any of these values. In some examples, the OSC has hole mobilities of 1 to 4 cm²V⁻¹s⁻¹. In some examples, the OSC has hole mobilities of 2 cm²V⁻¹s⁻¹. In some examples, the OSC has hole mobilities of 2 cm²V⁻¹s⁻¹ or more.

In some examples, the OSC polymers have On/Off ratios of greater than 10⁵. In some examples, the OSC polymers have On/Off ratios of greater than 10⁶.

In some examples, the OSC polymers have a threshold voltage in thin film transistor devices of −20V, −15V, −10V, −5V, −4V, −3V, −2V, −1V, 0V, 1V, 2V, 3V, 4V, 5V, 10V, 15V, 20V, or any value therein or any range defined by any two of those endpoints. In some examples, the OSC polymers have a threshold voltage in a range of 1 V to 3 V in thin film transistor devices. In some examples, the OSC polymers have a threshold voltage of 2 V in thin film transistor devices.

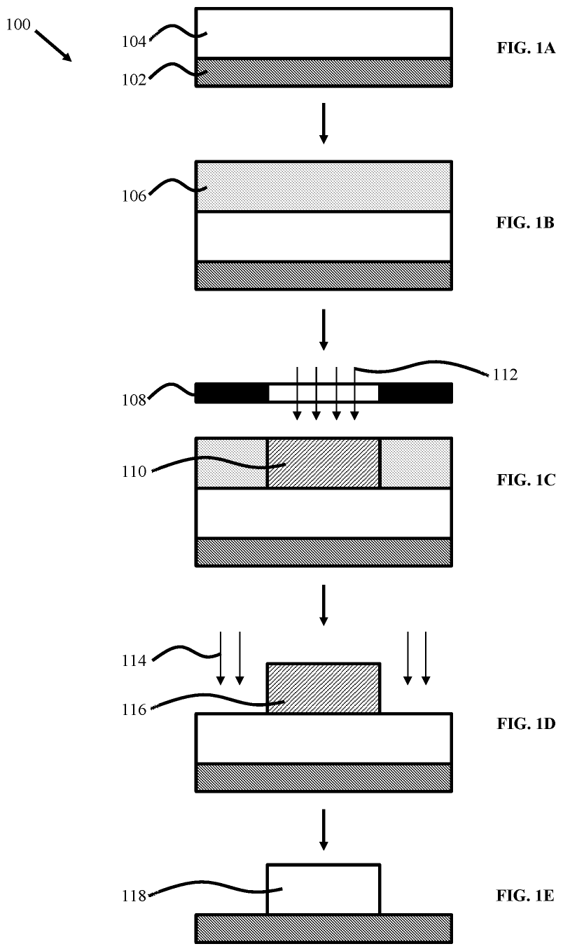

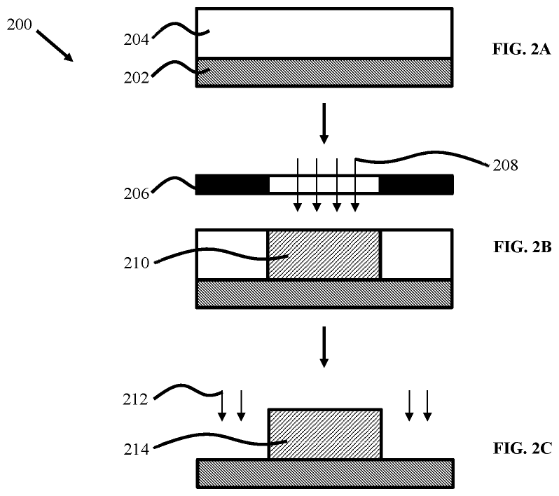

The OSC polymer disclosed herein (e.g., with at least one UV-curable side chain), enables direct UV crosslinking and patterning, thereby leading to improved patterning effects and OFET devices performance. For example, compared with conventional photolithography (described in FIGS. 1A to 1E), directly UV curable cross-bred OSC polymers reduce the number of pattern processing steps to only two steps (e.g., FIGS. 2A to 2C). Traditional processing steps, such as coating with compatible photoresists, etching the active material, and resist stripping become unnecessary due to the intrinsic UV patternability of the cross-bred OSC polymers disclosed herein. This reduction of manufacturing steps has a direct benefit in avoiding device performance degradation, since contact with potentially harmful solvents during resist coating and aggressive plasma etching atmospheres are avoided. Moreover, the reduction of steps may also significantly reduce manufacturing cost, equipment investment, as well as shorten the manufacturing cycle in OTFT manufacturing.

The disclosed cross-bred OSC polymers having the at least one UV-curable side chain have no phase separation issues and have stronger solvent resistance due to covalent-bond crosslinking. Thus, they are easier to process, leading to better reproducibility for solution processable OSC thin films. The chemical and physical properties of the cross-bred OSC polymers disclosed herein are also highly tunable by manipulating ratios among different monomers. The crosslinked OSC polymer networks formed using the disclosed cross-bred OSC polymers having the at least one UV-curable side chain help polymer chain alignment at elevated temperatures, offering higher temperature resistance of OTFT devices made thereof, as well as longer device life time and higher weatherability.

Crosslinker

In some examples, a polymer blend comprises at least one organic semiconductor (OSC) polymer and at least one crosslinker, such that the crosslinker includes at least one of: acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or a combination thereof. In some examples, the at least one crosslinker comprises C═C bonds, thiols, oxetanes, halides, azides, or combinations thereof.

In some examples, the crosslinker may be a small molecule or a polymer that reacts with the OSC polymer by one or a combination of reaction mechanisms, depending on functional moieties present in the crosslinker molecule. For example, crosslinkers comprising thiol groups may react with double bonds in the OSC polymer via thiol-ene click chemistry. In some examples, crosslinkers comprising vinyl groups may react with double bonds in the OSC polymer via addition reaction. In some examples, crosslinkers (comprising thiols, vinyl groups, etc., or combinations thereof) may react with crosslinkable functionalities incorporated in the side chains of OSC polymers. These include, for example, acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

In one aspect, which is combinable with any of the other aspects or embodiments, the at least one crosslinker comprises at least one of: (A) a polymer selected from:

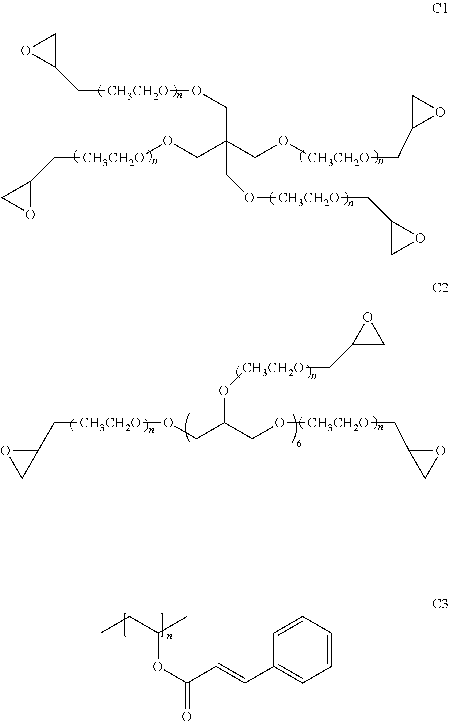

wherein n is an integer greater than or equal two, or (B) a small-molecule selected from:

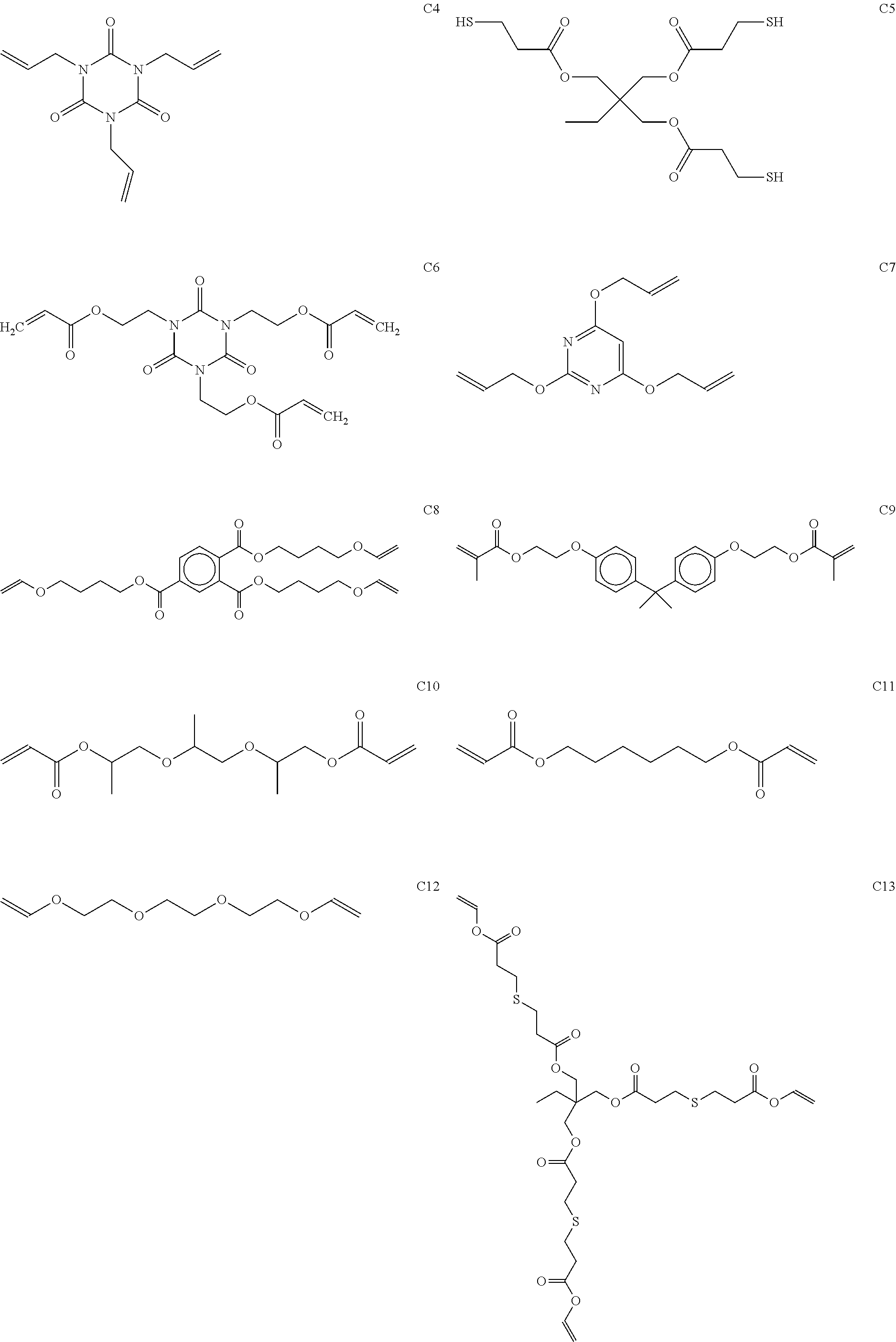

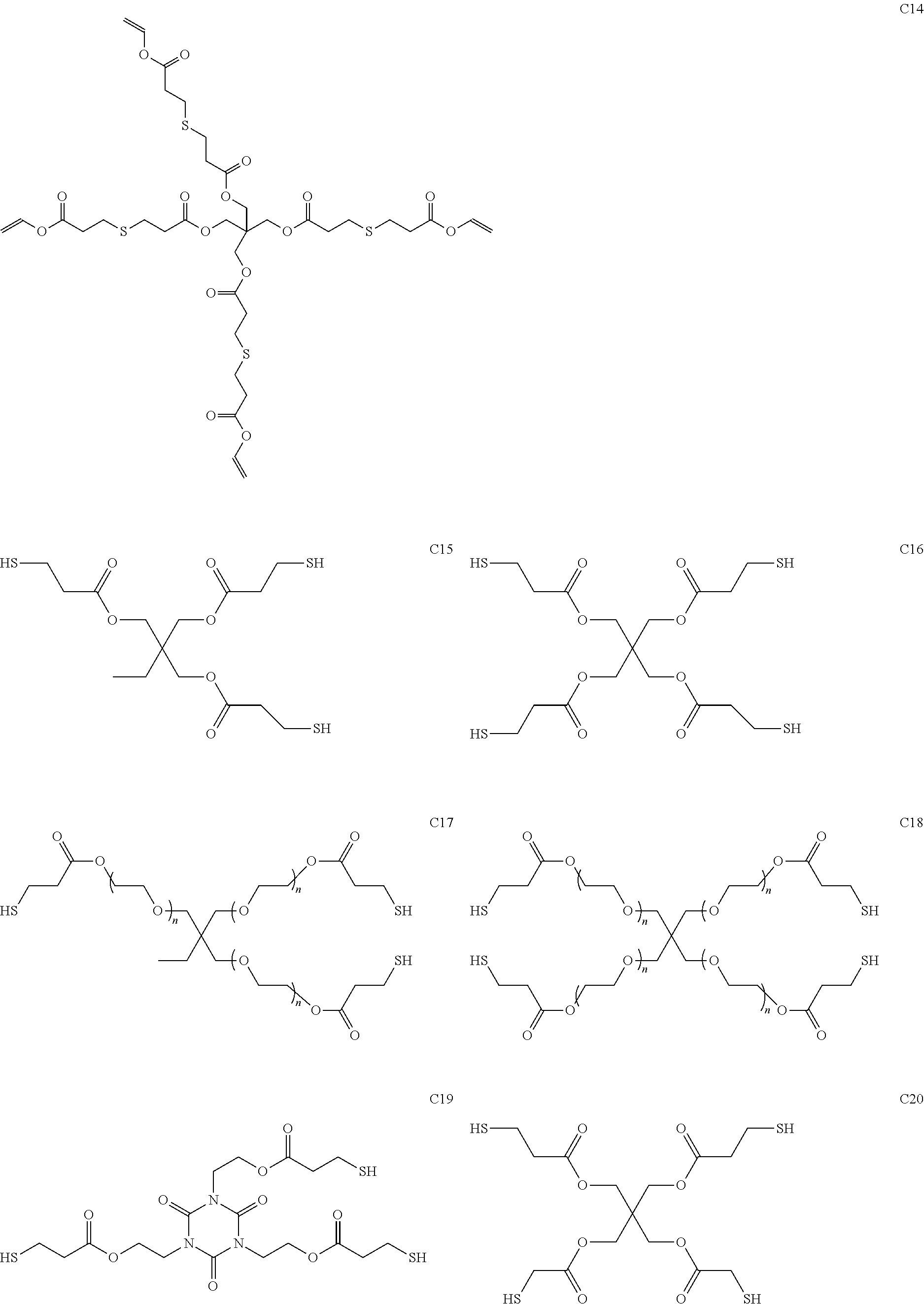

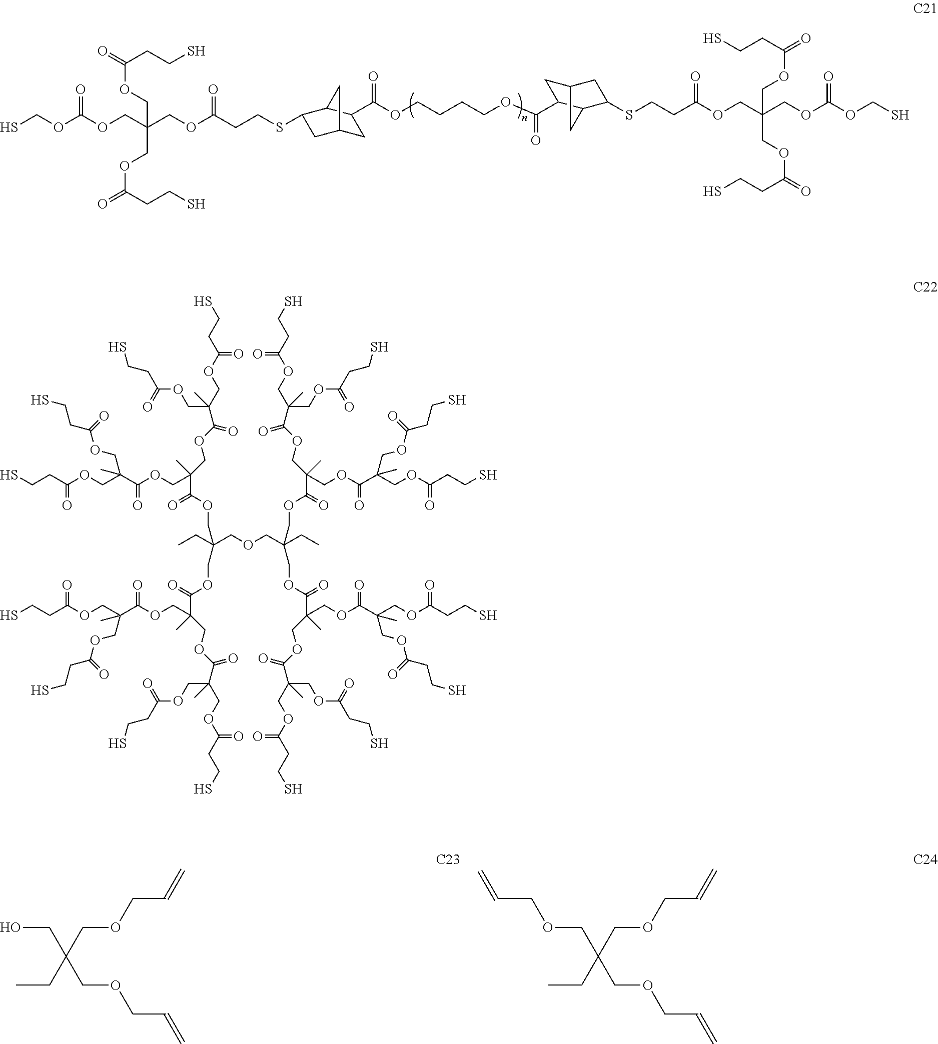

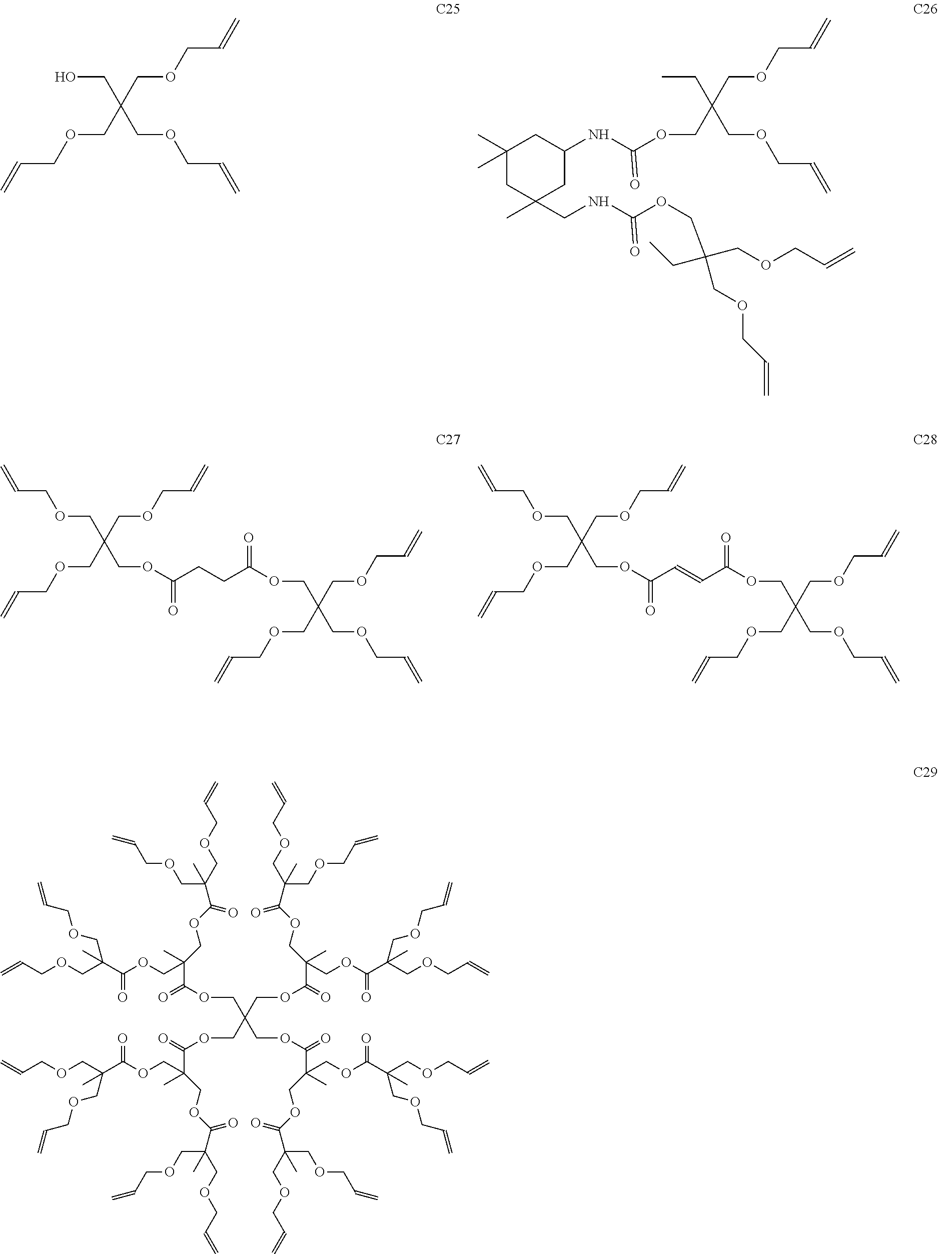 [SMILES: C=CCOCC(CO)(COCC=C)COCC=C ; C=CCOCC(CC)(COCC=C)COC(=O)NCC1(C)CC(NC(=O)OCC(CC)(COCC=C)COCC=C)CC(C)(C)C1 ; C=CCOCC(COCC=C)(COCC=C)COC(=O)CCC(=O)OCC(COCC=C)(COCC=C)COCC=C ; C=CCOCC(COCC=C)(COCC=C)COC(=O)/C=C/C(=O)OCC(COCC=C)(COCC=C)COCC=C ; C=CCOCC(C)(COCC=C)C(=O)OCC(C)(COC(=O)C(C)(COCC=C)COCC=C)C(=O)OCC(COC(=O)C(C)(COC(=O)C(C)(COCC=C)COCC=C)COC(=O)C(C)(COCC=C)COCC=C)(COC(=O)C(C)(COC(=O)C(C)(COCC=C)COCC=C)COC(=O)C(C)(COCC=C)COCC=C)COC(=O)C(C)(COC(=O)C(C)(COCC=C)COCC=C)COC(=O)C(C)(COCC=C)COCC=C]

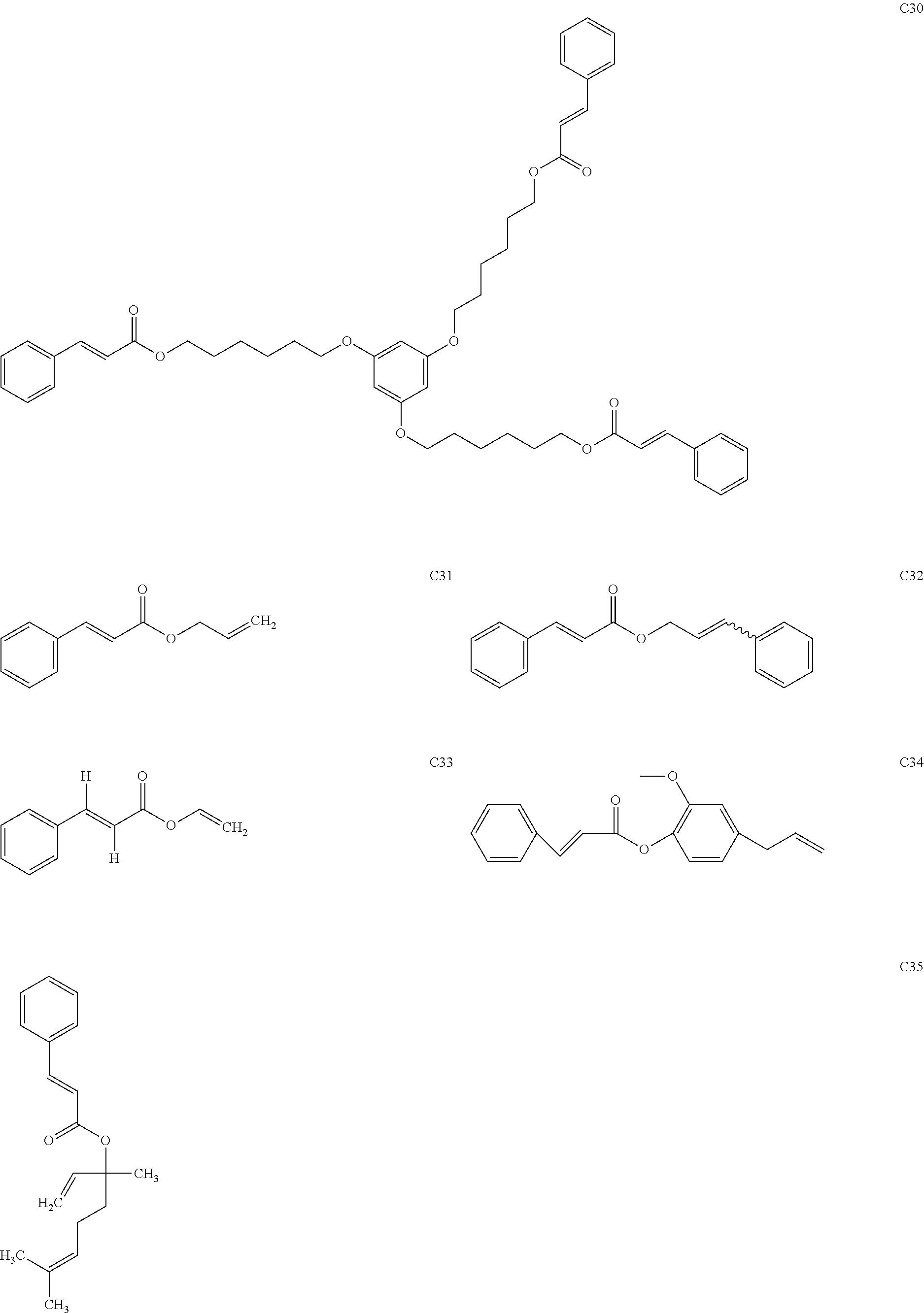 [SMILES: O=C(/C=C/c1ccccc1)OCCCCCCOc1cc(OCCCCCCOC(=O)/C=C/c2ccccc2)cc(OCCCCCCOC(=O)/C=C/c2ccccc2)c1 ; C=CCOC(=O)/C=C/c1ccccc1 ; O=C(/C=C/c1ccccc1)OCC=Cc1ccccc1 ; C=COC(=O)/C=C/c1ccccc1 ; C=CCc1ccc(OC(=O)/C=C/c2ccccc2)c(OC)c1 ; C=CC(C)(CCC=C(C)C)OC(=O)/C=C/c1ccccc1]

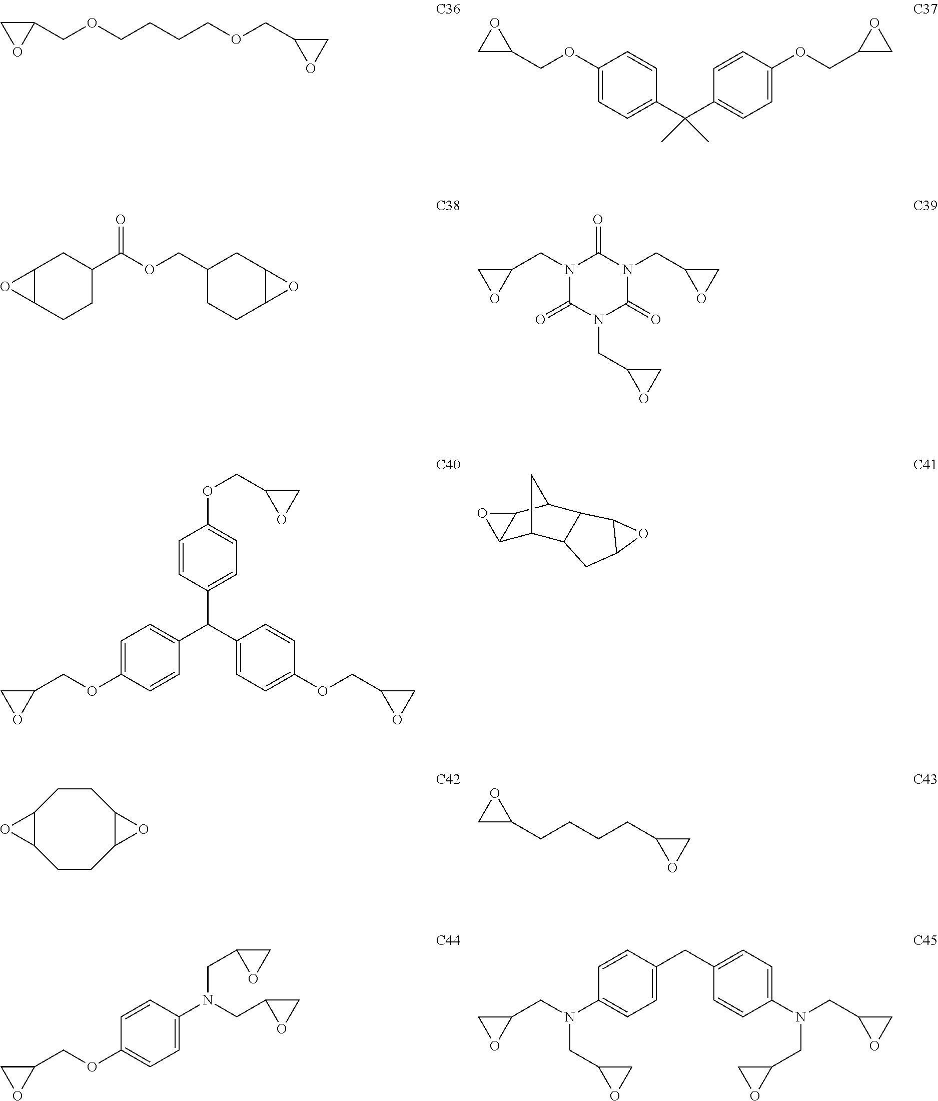

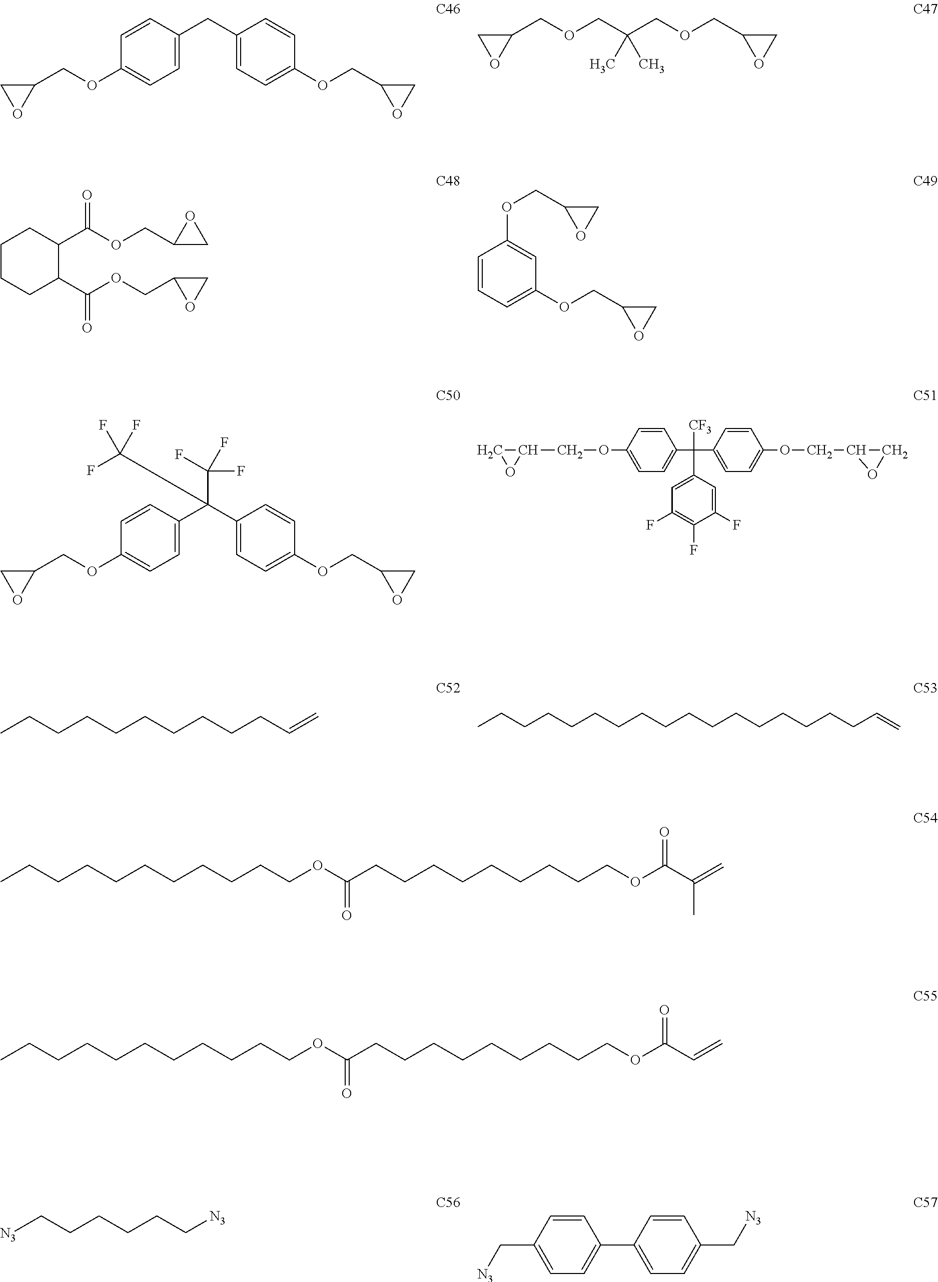

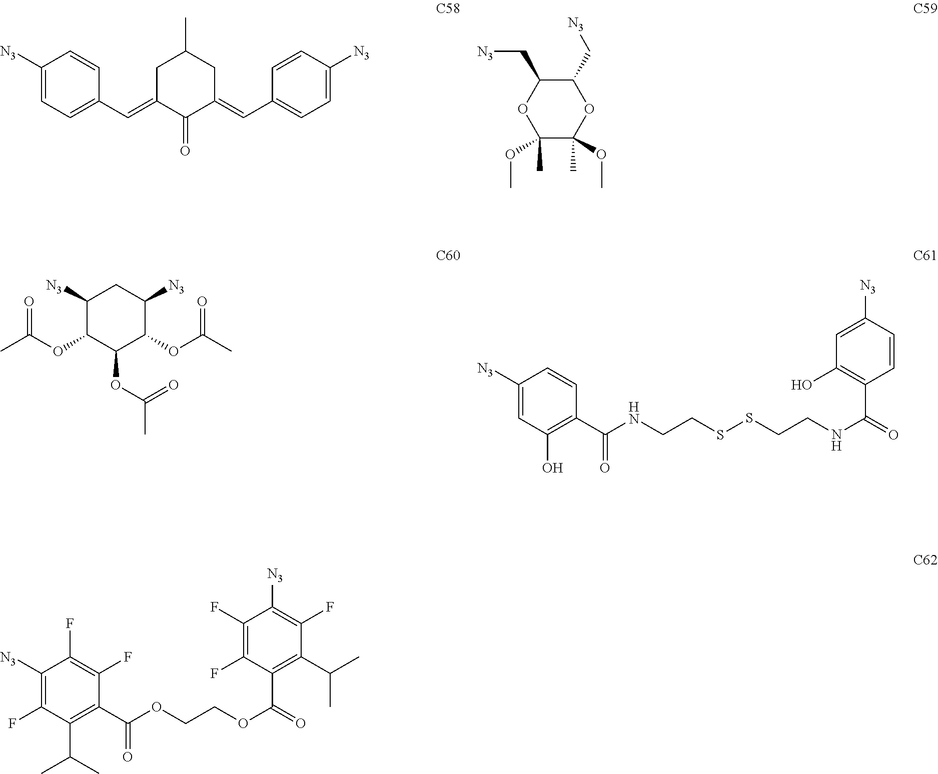 [SMILES: CC1C/C(=C\c2ccc(N=[N+]=[N-])cc2)C(=O)/C(=C/c2ccc(N=[N+]=[N-])cc2)C1 ; CO[C@]1(C)O[C@@H](CN=[N+]=[N-])[C@H](CN=[N+]=[N-])O[C@@]1(C)OC ; CC(=O)O[C@@H]1[C@@H](OC(C)=O)[C@H](N=[N+]=[N-])C[C@H](N=[N+]=[N-])[C@H]1OC(C)=O ; [N-]=[N+]=Nc1ccc(C(=O)NCCSSCCNC(=O)c2ccc(N=[N+]=[N-])cc2O)c(O)c1 ; CC(C)c1c(F)c(N=[N+]=[N-])c(F)c(F)c1C(=O)OCCOC(=O)c1c(F)c(F)c(N=[N+]=[N-])c(F)c1C(C)C]

or, (C) a combination thereof.

Photoinitiator

In some examples, a polymer blend comprises at least one OSC polymer, at least one crosslinker, and at least one photoinitiator.

The photoinitiator is a key component of photocuring products. In some examples, the photoinitiator comprises at least one free radical photoinitiator. Free-radical based photoinitiators include reactive free radicals that initiate photo-polymerization when exposed to UV light. In one example, the mechanism by which photoinitiator TPO initiates thiol-ene free-radical polymerization is shown below.

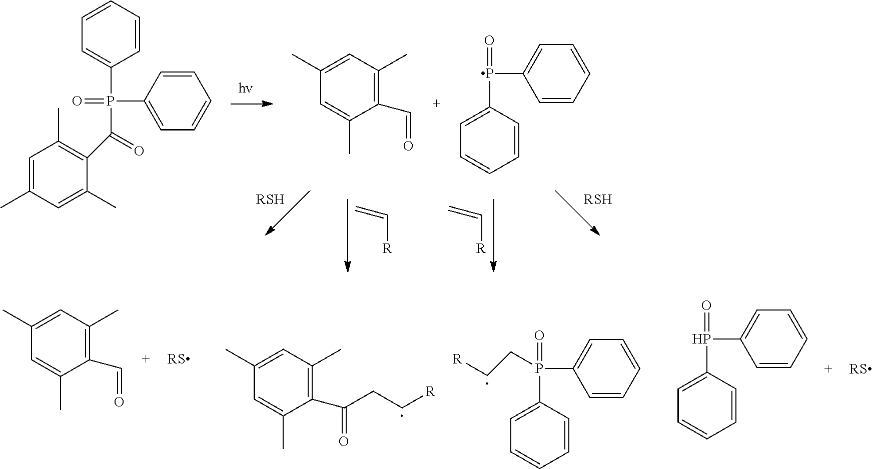

In some examples, the photoinitiator comprises at least one cationic photoinitiator. Cationic photoinitiators are also called photo-acid generators (PAGs). Once a cationic photoinitiator absorbs UV light, the initiator molecule is converted into a strong acid species, either a Lewis or Brönsted acid, that initiates polymerization. Typical photoacids/photoacid generators include aryl diazo salts, diaryliodonium salts, triaryl sulfonium salts, and aryl ferrocenium salts. In one example, the mechanism by which polymerization proceeds in using PAGs is shown below.

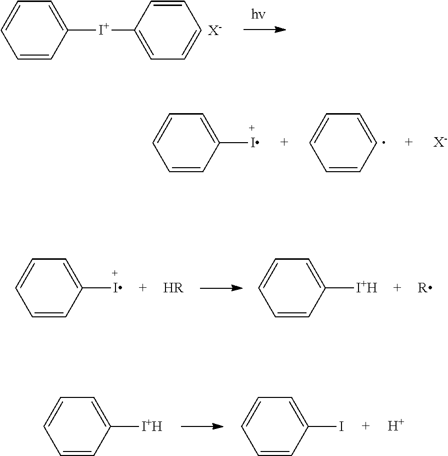

In some examples, the at least one photoinitiator includes: 1-hydroxy-cyclohexyl-phenyl-ketone (184); 2-benzyl-2-dimethylamino-1-(4-morpholinophenyl)-butanone-1 (369); diphenyl(2,4,6-trimethylbenzoyl)phosphine oxide (TPO); 2-isopropyl thioxanthone (ITX); 1-[4-(phenylthio) phenyl]-1,2-octanedione 2-(O-benzoyloxime) (HRCURE-OXE01); 2,2-dimethoxy-1,2-diphenylethan-1-one (BDK); benzoyl peroxide (BPO); hydroxyacetophenone (HAP); 2-hydroxy-2-methylprophenone (1173); 2-methyl-4′-(methylthio)-2-morpholinopropiophenone (907); 2-benzyl-2-(dimethylamino)-4′-morpholinobutyrophenone (IHT-PI 910); Ethyl-4-(dimethylamino)benzoate (EDB); methyl o-benzoyl benzoate (OMBB); bis-(2,6 dimethoxy-benzoyl)-phenyl phosphine oxide (BAPO); 4-benzoyl-4′ methyldiphenylsulfide (BMS); benzophenone (BP); 1-chloro-4-propoxy thiozanthone (CPTX); chlorothioxanthone (CTX); 2,2-diethoxyacetophenone (DEAP); diethyl thioxanthone (DETX); 2-dimethyl aminoethyl benzonate (DMB); 2,2-dimethoxy-2-phenyl acetophenone (DMPA); 2-ethyl anthraquinone (2-EA); ethyl-para-N,N-dimethyl-dimethylamino lenzoate (EDAB); 2-ethyl hexyl-dimethylaminolenzoate (EHA); 4,4-bis-(diethylamino)-benzophenone (EMK); methyl benzophenone (MBF); 4-methyl benzophenone (MBP); Michler's ketone (MK); 2-methyl-1-[4(methylthiol)phenyl]-2-morpholino propanone (1) (MMMMP); 4-phenylbenzophenone (PBZ); 2,4,6-trimethyl-benzoly-ethoxyl phenyl phosphine oxide (TEPO); bis(4-tert-butylphenyl) iodonium perfluoro-1-butanesulfonate; bis(4-tert-butylphenyl) iodonium p-toluenesulfonate; bis(4-tert-butylphenyl) iodonium triflate; boc-methoxyphenyldiphenylsulfonium triflate; (4-tert-Butylphenyl) diphenylsulfonium triflate; diphenyliodonium hexafluorophosphate; diphenyliodonium nitrate; diphenyliodonium p-toluenesulfonate; diphenyliodonium triflate; (4-fluorophenyl) diphenylsulfonium triflate; N-hydroxynaphthalimide triflate; N-hydroxy-5-norbornene-2,3-dicarboximide perfluoro-1-butanesulfonate; (4-iodophenyl) diphenylsulfonium triflate; (4-methoxyphenyl) diphenylsulfonium triflate; 2-(4-Methoxystyryl)-4,6-bis (trichloromethyl)-1,3,5-triazine; (4-methylthiophenyl) methyl phenyl sulfonium triflate; 1-naphthyl diphenylsulfonium triflate; (4-phenoxyphenyl) diphenylsulfonium triflate; (4-phenylthiophenyl) diphenylsulfonium triflate; triarylsulfonium hexafluoroantimonate salts, mixed 50 wt. % in propylene carbonate; triarylsulfonium hexafluorophosphate salts, mixed 50 wt. % in propylene carbonate; triphenylsulfonium perfluoro-1-butanesufonate; triphenylsulfonium triflate; tris(4-tert-butylphenyl) sulfonium perfluoro-1-butanesulfonate; tris(4-tert-butylphenyl)sulfonium triflate; aryl diazo salts; diaryliodonium salts; triaryl sulfonium salts; aryl ferrocenium salts; or combinations thereof.

Structures for representative photoinitiators are shown in Table 1 below.

TABLE 1

| | |
|---|---|
| 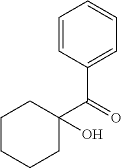 [SMILES: O=C(c1ccccc1)C1(O)CCCCC1] | P1 |
| 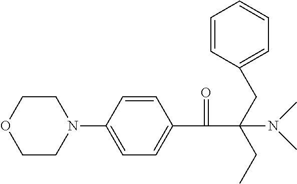 [SMILES: CCC(Cc1ccccc1)(C(=O)c1ccc(N2CCOCC2)cc1)N(C)C] | P2 |
| 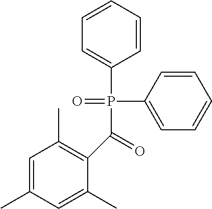 [SMILES: Cc1cc(C)c(C(=O)P(=O)(c2ccccc2)c2ccccc2)c(C)c1] | P3 |
| 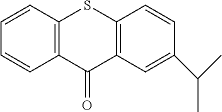 [SMILES: CC(C)c1ccc2sc3ccccc3c(=O)c2c1] | P4 |
| 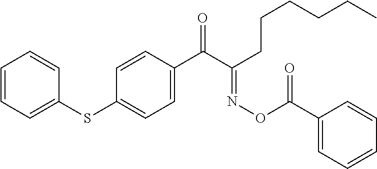 [SMILES: CCCCCC/C(=N\OC(=O)c1ccccc1)C(=O)c1ccc(Sc2ccccc2)cc1] | P5 |
| 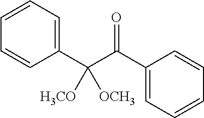 [SMILES: COC(OC)(C(=O)c1ccccc1)c1ccccc1] | P6 |
| 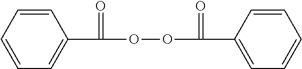 [SMILES: O=C(OOC(=O)c1ccccc1)c1ccccc1] | P7 |
| 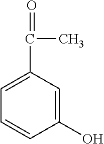 | P8 |
| 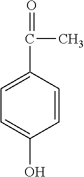 | P9 |
| 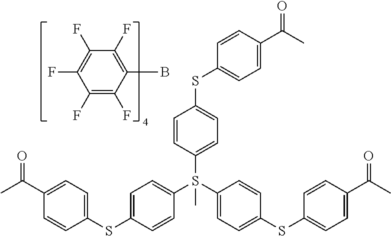 | P10 |

Structures for representative aryl diazo salt, diaryliodonium salt, triaryl sulfonium salt, and aryl ferrocenium salt photoinitiators are shown in Table 2 below.

TABLE 2

| | |
|---|---|
| Aryl diazo salts | |
| 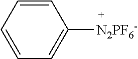 | P11 |
| 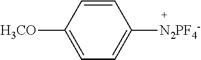 | P12 |
| Diaryliodonium salts | |
| 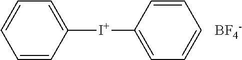 | P13 |
| 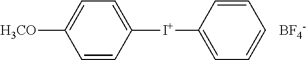 | P14 |
| 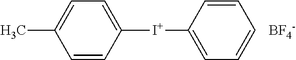 | P15 |
| 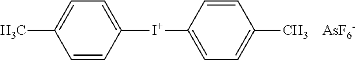 | P16 |
| 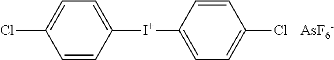 | P17 |
| 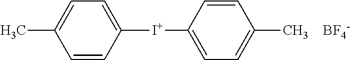 | P18 |
| 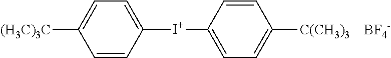 [SMILES: CC(C)(C)c1ccc([I+]c2ccc(C(C)(C)C)cc2)cc1 ; "BF4-"] | P19 |
| 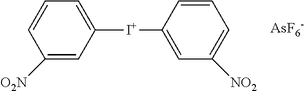 [SMILES: O=[N+]([O-])c1cccc([I+]c2cccc([N+](=O)[O-])c2)c1 ; "AsF6-"] | P20 |
| 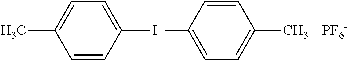 | P21 |
| 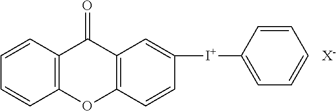 | P22 |
| 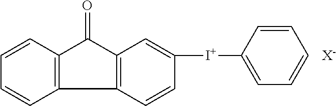 | P23 |
| 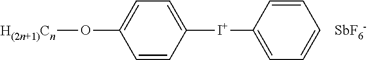 | P24 |
| 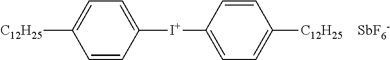 | P25 |
| 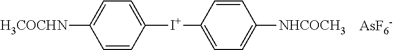 | P26 |
| Triaryl sulfonium salts | |
| 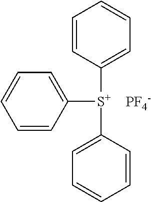 | P27 |
| 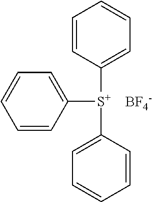 | P28 |
| 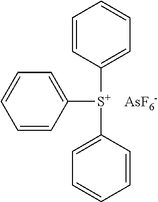 | P29 |
| 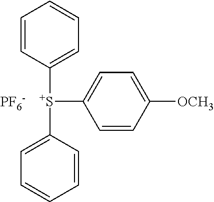 [SMILES: "PF6-" ; COc1ccc([S+](c2ccccc2)c2ccccc2)cc1] | P30 |
| 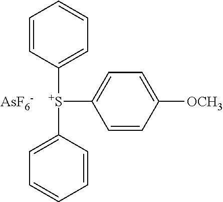 | P31 |
| 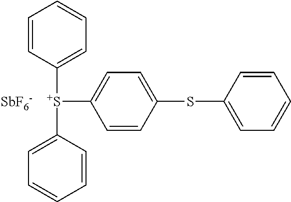 | P32 |
| 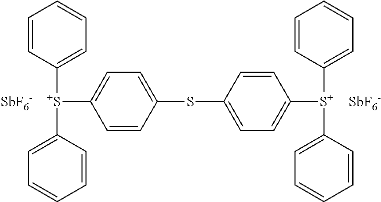 | P33 |
| 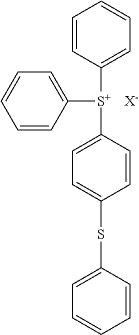 | P34 |
| 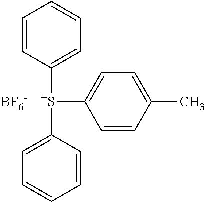 | P35 |
| 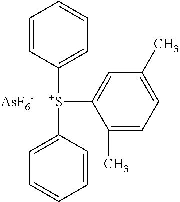 | P36 |
| 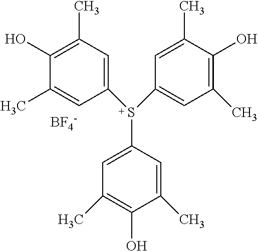 | P37 |
| Aryl ferrocenium salt | |
| 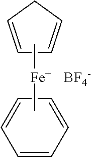 | P38 |
| 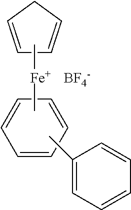 | P39 |
| 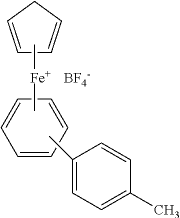 | P40 |
| 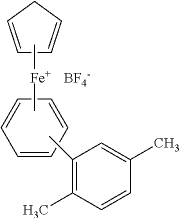 | P41 |
| 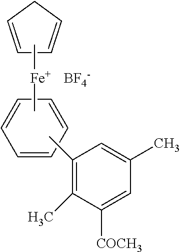 | P42 |
| 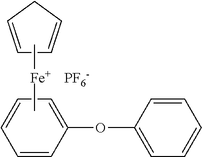 | P43 |
| 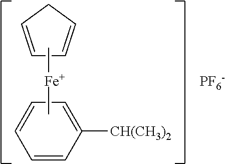 | P44 |

Additives

In some examples, a polymer blend comprises at least one OSC polymer, at least one crosslinker, at least one photoinitiator, and at least one additive, such as antioxidants (i.e., oxygen inhibitors), lubricants, compatibilizers, leveling agents, nucleating agents, or combinations thereof. In some examples, oxygen inhibitors include phenols, thiols, amines, ethers, phosphites, organic phosphines, hydroxylamines, or combinations thereof.

Polymer Blend

In some examples, the performance of a device comprising the OSC polymer may be improved by blending the OSC polymer with a crosslinker. In some examples, the OSC polymer is blended with a crosslinker in a solvent. In some examples, the solvent is chloroform, methylethylketone, toluene, xylenes, chlorobenzene, 1,2-dichlorobenzene, 1,2,4-trichlorobenzene, tetralin, naphthalene, chloronaphthalene, or combinations thereof. In some examples, a mixture of more than one solvent may be used.

In some examples, the at least one OSC polymer is present in a range of 1 wt. % to 99 wt. %, or in a range of 5 wt. % to 95 wt. %, or in a range of 10 wt. % to 90 wt. %, or in a range of 25 wt. % to 85 wt. %, or in a range of 50 wt. % to 80 wt. %. In some examples, the at least one OSC polymer is present at 1 wt. %, or 2 wt. %, or 3 wt. %, or 5 wt. %, or 10 wt. %, or 15 wt. %, or 20 wt. %, or 25 wt. %, or 30 wt. %, or 35 wt. %, or 40 wt. %, or 50 wt. %, or 60 wt. %, or 70 wt. %, or 80 wt. %, or 90 wt. %, or 95 wt. %, or 99 wt. %, or any range defined by any two of those endpoints.

In some examples, the at least one crosslinker is present in a range of 1 wt. % to 99 wt. %, or in a range of 5 wt. % to 95 wt. %, or in a range of 10 wt. % to 90 wt. %, or in a range of 15 wt. % to 85 wt. %, or in a range of 20 wt. % to 80 wt. %, or in a range of 25 wt. % to 75 wt. %, or in a range of 25 wt. % to 65 wt. %, or in a range of 25 wt. % to 55 wt. %. In some examples, the at least one crosslinker is present at 0.1 wt. %, or 0.2 wt. %, or 0.3 wt. %, or 0.5 wt. %, or 0.8 wt. %, or 1 wt. %, or 2 wt. %, or 3 wt. %, or 5 wt. %, or 10 wt. %, or 15 wt. %, or 20 wt. %, or 25 wt. %, or 30 wt. %, or 35 wt. %, or 40 wt. %, or 45 wt. %, or 50 wt. %, or 55 wt. %, or 60 wt. %, or 65 wt. %, or 70 wt. %, or 75 wt. %, or 80 wt. %, or 85 wt. %, or 90 wt. %, or 95 wt. %, or 99 wt. %, or any range defined by any two of those endpoints. In some examples, the at least one crosslinker comprises a first crosslinker and a second crosslinker, the first crosslinker being present in a range of 30 wt. % to 50 wt. % and the second crosslinker being present in a range of 0.5 wt. % to 25 wt. %.

In some examples, the at least one photoinitiator is present in a range of 0.1 wt. % to 10 wt. %; or in a range of 0.2 wt. % to 8 wt. %, or in a range of 0.3 wt. % to 6 wt. %, or in a range of 0.4 wt. % to 5 wt. %, or in a range of 0.5 wt. % to 4.5 wt. %, or in a range of 0.5 wt. % to 4 wt. %, or in a range of 0.6 wt. % to 3.5 wt. %, or in a range of 0.7 wt. % to 3 wt. %. In some examples, the at least one photoinitiator is present at 0.1 wt. %, or 0.2 wt. %, or 0.3 wt. %, or 0.4 wt. %, or 0.5 wt. %, or 0.6 wt. %, or 0.7 wt. %, or 0.8 wt. %, or 0.9 wt. %, or 1 wt. %, or 1.5 wt. %, or 2 wt. %, or 2.5 wt. %, or 3 wt. %, or 3.5 wt. %, or 4 wt. %, or 4.5 wt. %, or 5 wt. %, or 6 wt. %, or 7 wt. %, or 8 wt. %, or 9 wt. %, or 10 wt. %, or any range defined by any two of those endpoints.

In some examples, the at least one OSC polymer is present in a range of 1 wt. % to 99 wt. %; the at least one crosslinker is present in a range of 1 wt. % to 99 wt. %; and the at least one photoinitiator is present in a range of 0.1 wt. % to 10 wt. %. In some examples, the at least one OSC polymer is present in a range of 50 wt. % to 80 wt. %; and the at least one crosslinker is present in a range of 25 wt. % to 55 wt. %.

In some examples, the at least one antioxidant, lubricant, compatibilizer, leveling agent, or nucleating agent may each be present, independently, in a range of 0.05 wt. % to 5 wt. %, or in a range of 0.1 wt. % to 4.5 wt. %, or in a range of 0.2 wt. % to 4 wt. %, or in a range of 0.3 wt. % to 3.5 wt. %, or in a range of 0.4 wt. % to 3 wt. %, or in a range of 0.5 wt. % to 2.5 wt. %. In some examples, the at least one antioxidant, lubricant, compatibilizer, leveling agent, or nucleating agent may each be present, independently, at 0.05 wt. %, or 0.1 wt. %, or 0.2 wt. %, or 0.3 wt. %, or 0.4 wt. %, or 0.5 wt. %, or 0.6 wt. %, or 0.7 wt. %, or 0.8 wt. %, or 0.9 wt. %, or 1 wt. %, or 1.5 wt. %, or 2 wt. %, or 2.5 wt. %, or 3 wt. %, or 3.5 wt. %, or 4 wt. %, or 4.5 wt. %, or 5 wt. %, or any range defined by any two of those endpoints.

In some examples, the blend consists of OSC polymers as described herein. In some examples, the blend comprises at least two of: OSC polymers, crosslinkers, photoinitiators, and additives as described herein. In some examples, the blend comprises at least three of: OSC polymers, crosslinkers, photoinitiators, and additives as described herein. In some examples, the blend comprises at least four of: OSC polymers, crosslinkers, photoinitiators, and additives as described herein.

OTFT Device Fabrication

Applications using OTFT devices require patterning of organic semiconducting materials to prevent undesired high off-currents and crosstalk between adjacent devices. As explained above, photolithography is a common patterning technique in semiconductor device fabrication. However, photolithography usually involves harsh O₂ plasma during pattern transfer or photoresist removal and aggressive developing solvents which may severely damage the OSC layer and lead to significant deterioration of OTFT device performance. In other words, conjugated organic materials tend to degrade when exposed to light and the chemicals used in photolithography may have an adverse effect on organic thin film transistors. Therefore, patterning of organic semiconducting materials using photolithography is not practical.

FIGS. 1A to 1E illustrate traditional patterning techniques 100 of organic semiconductor blends utilizing photoresists. In a first step (FIG. 1A), a thin film 104 of the blended OSC polymer is deposited over a substrate 102 followed by deposition of a photoresist layer 106 thereon in FIG. 1B. Optionally, the thin film 104 may be thermally annealed. The photoresist deposition may be conducted using processes known in the art such as spin coating. For example, the photoresist, rendered into a liquid form by dissolving the solid components in a solvent, is poured onto the substrate, which is then spun on a turntable at a high speed producing the desired film. Thereafter, the resulting resist film may experience a post-apply bake process (i.e., soft-bake or prebake) to dry the photoresist in removing excess solvent.

In the step of FIG. 1C, the photoresist layer 106 is exposed to UV light 112 through a master pattern called a photomask 108 positioned some distance away from the photoresist layer 106 to form a higher crosslinked portion 110 of the photoresist layer 106. The exposure to UV light operates to change the solubility of the photoresist in a subsequent developer solvent solution for pattern formation atop the substrate. Prior to the developer, the resist layer may experience a post exposure bake. In the step of FIG. 1D, the pattern 116 of the photoresist layer is transferred into the thin film 104 via subtractive etching 114 (i.e., O₂ plasma dry etching). The patterned photoresist layer 116 “resists” the etching and protects the material covered by the photoresist. When the etching is complete, the photoresist is stripped (e.g., using organic or inorganic solutions, and dry (plasma) stripping) leaving the desired pattern 118 etched into the thin film layer.

However, as explained above, aspects of traditional photolithography processes such as harsh O₂ plasma during pattern transfer and aggressive photoresist developer solvents and/or stripping solvents may severely damage the OSC layer and lead to significant deterioration of device performance.

FIGS. 2A to 2C illustrate patterning techniques 200 of organic semiconductor blends, according to some embodiments. In a first step (FIG. 2A), a thin film 204 of the blended OSC polymer is deposited over a substrate 202. Optionally, the thin film 204 may be thermally annealed. In some examples, depositing comprises at least one of spin coating; dip coating; spray coating; electrodeposition; meniscus coating; plasma deposition; and roller, curtain and extrusion coating. The thin film 204 was prepared as a polymer blend described above comprising at least one organic semiconductor (OSC) polymer, and optionally, at least one crosslinker, at least one photoinitiator, and at least one additive.

In some examples, the blending includes dissolving the at least one OSC polymer in a first organic solvent to form a first solution, dissolving the at least one crosslinker in a second organic solvent to form a second solution, and dissolving at least one photoinitiator in a third organic solvent to form a third solution; and combining the first, second, and third solutions in any suitable order to create the polymer blend. In some examples, the first, second, and third solutions may be combined simultaneously. In some examples, the at least one OSC polymer, at least one crosslinker, and at least one photoinitiator may be prepared together in a single organic solvent. The weight compositions of each component of the polymer blend is as provided above.

In some examples, after the thin film of the blended OSC polymer is deposited over the substrate and before exposing the thin film to UV light, the thin film may be heated at a temperature in a range of 50° C. to 200° C. for a time in a range of 10 sec to 10 min to remove excess solvent.

In a second step (FIG. 2B), the thin film 204 was exposed to UV light 208 through a photomask 206 to form a higher crosslinked portion 210 of the thin film 204. In some examples, the exposing comprises exposing the thin film to UV light having an energy in a range of 10 mJ/cm² to 600 mJ/cm² (e.g., 400 mJ/cm²) for a time in a range of 1 sec to 60 sec (e.g., 10 sec).

In some examples, the UV light may have an energy in a range of 300 mJ/cm² to 500 mJ/cm² and be operable for a time in a range of 5 sec to 20 sec. Similar to photoresist functionality described in FIGS. 1A to 1E, the exposure to UV light operates to change the solubility of the thin film in a subsequent developer solvent solution for pattern formation atop the substrate.

In the step of FIG. 2C, when light exposure is complete, the portion of the thin film 204 not exposed to UV light 208 was stripped using a predetermined solvent 212, thereby leaving the desired pattern 214 into the thin film layer. In other words, the higher crosslinked portion 210 was developed in a solvent to remove an un-patterned region of the thin film 204. In some examples, the developing comprises exposing the un-patterned region of the thin film to a solvent comprising chlorobenzene, 1,2-dichlorobenzene, 1,3-dichlorobenzene, 1,2,4-trichlorobenzene, dioxane, p-xylene, m-xylene, toluene, cyclopentanone, cyclohexanone, methyl lactate, 2-butanone, 2-pentanone, 3-pentanone, 2-heptanone, 3-heptanone, anisole, mesitylene, decalin, butylbenzene, cyclooctane, tetralin, chloroform, or combinations thereof, for a time in a range of 10 sec to 10 min. In some examples, the developer solution comprises chlorobenzene, p-xylene, dioxane, or combinations thereof.

In some examples, after developing the patterned thin film in a solvent to remove the un-patterned region of the thin film, the thin film may be heated at a temperature in a range of 50° C. to 200° C. for a time in a range of 10 sec to 30 min.

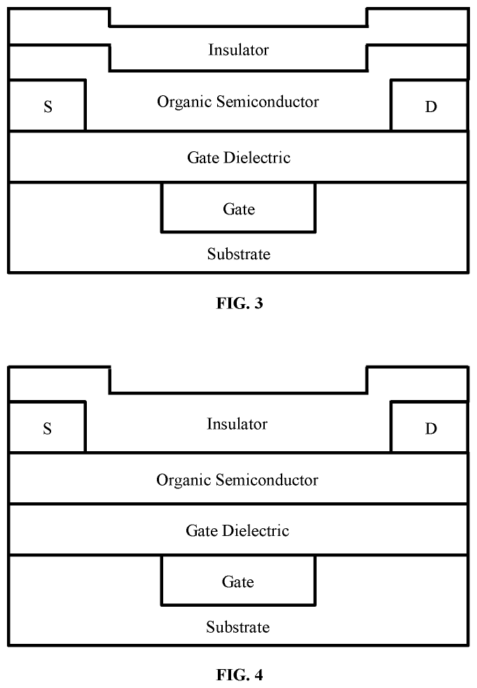

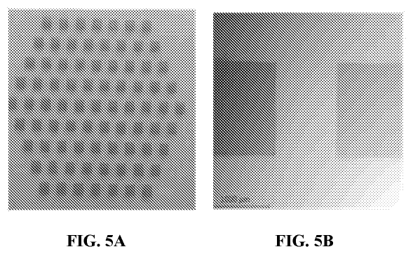

Thereafter, the OTFT devices may be completed by forming a gate electrode over the substrate; forming a gate dielectric layer over the substrate; forming patterned source and drain electrodes over the gate dielectric layer; forming an organic semiconductor active layer over the and gate dielectric layer, and forming an insulator layer over the patterned organic semiconductor active layer. (FIGS. 3 and 4).

### EXAMPLES

The embodiments described herein will be further clarified by the following examples.

All experimental operations are done in a fume hood unless otherwise stated.

Synthesis of DPP-Based Methyl Acrylate Alkyl Side Chain Monomer

In a first step, 0.895 mmol of bis-brominated DPP (3,6-Bis(5-bromothiophen-2-yl)pyrrolo[3,4-c]pyrrole-1,4(2H,5H)-dione), 4.0 equiv. of anhydrous K₂CO₃, and 1.36% mmol of BHT (di-tert-butylhydroxytoluene) are weighed into a 3-neck round bottom flask, which is then vacuumed and filled with N₂ with Schlenk line manifold for three times. Thereafter, after connecting the reaction flask with a condenser, anhydrous DMF (N,N-Dimethylformamide, 18 mL) is added to the flask. The reaction mixture is stirred in an oil bath heated to 120° C. for 1 hour after the oil bath temperature reaches 120° C. The oil bath is then cooled to 110° C.

Two-point-four (2.4) equiv. of brominated methyl acrylate alkyl side chain (10-bromodecyl 10-(methacryloyloxy) decanoate) is dissolved in 4.5 mL anhydrous DMF and then added dropwise to the reaction mixture. While keeping the oil bath at 110° C. for two hours, the reaction mixture is stirred. After about two hours, the reaction mixture is cooled to room temperature and thereafter poured directly into a stirred ice brine. A crude, dark solid product was obtained by filtration and then dissolved Dichloromethane (DCM). Quick-plug column chromatography was used using neutral aluminum oxide and DCM was conducted, with the solvent DCM in the filtered solution removed to yield a dark solid. The dark solid is then recrystallized from 100 mL hexanes after adding 1.3 mg BHT in a round bottle flask. The product is finally dried under vacuum.

Synthesis of Cross-bred OSC Polymer

In a first step, (x+y) mol linear alkyl side chain FT4, x mol linear alkyl side chain DPP monomer, y mol methyl acrylate alkyl side chain DPP monomer, 2% (x+y) Pd₂(DBA)₃ and 8% (x+y) o-tolyl phosphine are weighed into a 3-neck round bottom flask. The round bottom flask is then vacuumed and filled with N₂ with Schlenk line manifold three times. The reaction flask is connected with a condenser and chlorobenzene (20 mL) was added to the flask. A thermocouple is inserted into the reaction mixture through the septum in the third neck of the flask. The reaction mixture inner temperature was heated from room temperature to 120° C. and stirred in an oil bath for 1 hour after the inner temperature reaches 120° C.

While the reaction mixture is still hot, it is poured directly into stirred 300 mL methanol. Thereafter, about 50 mL methanol is used to wash the flask and concentrated HCl(aq) (4 mL) is then added. The mixture is stirred overnight. The polymer is then filtered from the solution using a Buchner funnel and side arm conical flask with reduced pressure. The filtrate solution is discarded. The polymer is transferred into a Soxhlet thimble (polymer not to exceed half height of thimble) and loaded into a Soxhlet extraction apparatus. Polymer Soxhlet extraction is conducted with Acetone (300 mL) for 24 h. The acetone solution/suspension is then discarded. Soxhlet extraction is then conducted with hexane (300 mL) for about 24 h. The hexane solution/suspension is then discarded. The polymer is then extracted into chloroform (300 mL) until no more material will dissolve. The polymer precipitates by pouring the chloroform solution into a stirring beaker of acetone (400 mL), stirring till room temperature. The polymer is filtered from the solution using a Buchner funnel and side arm conical flask with reduced pressure. The filtrate solution is then discarded. The polymer is finally dried under vacuum.

Photo Patterning and Results Comparison

A solution of cross-bred OSC polymer is prepared in chlorobenzene and stirred at 60-90° C. in an oil bath for 1 hr to overnight and then cooled to room temperature. A crosslinker (1-3 wt. % relative to OSC polymer) such as TRIS (trimethylolpropane tris(3-mercaptopropionae)) and a photoinitiator (1-3 wt. % relative to OSC polymer) such as diphenyl(2,4,6-trimethylbenzoyl) phosphine oxide (TPO) were added into the solution and the solution was stirred at room temperature for about 5 minutes. The mixture was then filtered using a 0.45 μm PTFE filter.

The filtered OSC polymer solution was spun coated as a thin film coating onto a glass, glass-ceramic, or ceramic substrate at a coating speed of, for example, 500 rpm for 30 seconds, followed by, for example, 1000 rpm for 30 seconds. Then the OSC polymer solution-coated glass slide was pre-baked at 90° C. for one minute. Under a photo mask, the OSC polymer solution-coated substrate was cured at 365 nm using an Oriel lamp under a suitable curing dose in air (e.g., about 300 mJ/cm²). The OSC polymer solution-coated substrate was washed sequentially in two glass cylinder dishes containing chlorobenzene for two times. The photo-patterned OSC polymer thin film is then dried with nitrogen gas.

FIGS. 5A and 5B illustrate a photo patterning of the cross-bred OSC polymer using chlorobenzene for dissolving and rinsing, according to some embodiments. Specifically, the film in FIG. 5A was exposed under UV light with a photo mask. The unexposed areas are dissolved in chlorobenzene during a rinse cycle. The exposed areas are crosslinked to form network structures, which are not dissolved in chlorobenzene, thereby showing excellent solvent resistance. FIG. 5B is a partially enlarged portion of FIG. 5A and illustrates clear patterning edges with resolutions of 2 μm. The clear patterning edges exemplify good photo patterning reproducibility, which is a prerequisite for maintaining the uniformity of devices performance.

General Manufacturing Procedure for OTFT Device

In some examples, a bottom gate, bottom contact OTFT device can be formed as following: patterning a gold (Au) or silver (Ag) gate electrode onto a substrate, followed by spin-coating a dielectric onto the substrate and treating to obtain a gate dielectric layer. After patterning Au or Ag source and drain electrodes, an OSC layer may be formed by the materials and methods of patterning as described herein to a thickness in a range of 10 nm to 200 nm. Finally, an insulator layer was positioned. One example of the formed OTFT device is shown in FIG. 3.

OFET Device Performance

A bottom gate, top contact OTFT device may be formed as following: some substrates were treated with octadecyltrichlorosilane (OTS) on an SiO₂ surface. An OSC polymer [x+y mol linear alkyl side chain FT4, 80% (x+y) mol linear alkyl side chain DPP monomer, 20% (x+y) mol methyl acrylate alkyl side chain DPP monomer] solution containing photo initiator and crosslinker were spun coated at 1000 rpm. Gold electrodes were fabricated on the spun-coated OSC layer. The OFET device performance is based on the OFET structure of FIG. 4.

Both bare SiO₂ and OTS-treated surfaces were tested, with the OTS-treated surface showing higher mobility (ph) (Table 3). Both low solution concentration and high solution concentration were tested, with low solution concentration showing higher mobility, but high solution concentration demonstrating a better Iₒₙ/I_{off} ratio. Charge mobility is one parameter to determine OTFT device performance and represents how fast an electron or hole can move per unit voltage; the higher mobility, the better the performance. The Iₒₙ/I_{off} ratio is another parameter to determine OTFT device performance and represents the on/off current ratio. A higher on/off ratio means a lower off-current (lower power consumption) when an on-current is fixed; thus, the higher Iₒₙ/I_{off} ratio, the better the performance.

TABLE 3

| | | Solution | | μₕ [cm² V⁻¹ s⁻¹] | | Vₜₕ |
|---|---|---|---|---|---|---|
| Entry | Solvent | Concentration | Substrate | (in air) | I_{ON}/I_{OFF} | [V] |
| 1 | chlorobenzene | 5 mg/mL | Bare | 0.238 | 3 × 10⁴ | 2 |
| 2 | chlorobenzene | 5 mg/mL | OTS | 0.472 | 4 × 10³ | 7 |
| 3 | chlorobenzene | 10 mg/mL | OTS | 0.236 | 2 × 10⁵ | 8 |

Thus, as presented herein, improved photo-patternable cross-bred organic semiconductor polymers and use thereof for OSC layers of organic thin-film transistors are disclosed. Advantages of the photo-patternable cross-bred organic semiconductor polymers are disclosed herein.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

As utilized herein, “optional,” “optionally,” or the like are intended to mean that the subsequently described event or circumstance can or cannot occur, and that the description includes instances where the event or circumstance occurs and instances where it does not occur. The indefinite article “a” or “an” and its corresponding definite article “the” as used herein means at least one, or one or more, unless specified otherwise.

References herein to the positions of elements (e.g., “top,” “bottom,” “above,” “below,” etc.) are merely used to describe the orientation of various elements in the FIGURES. It should be noted that the orientation of various elements may differ according to other exemplary embodiments, and that such variations are intended to be encompassed by the present disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be apparent to those skilled in the art that various modifications and variations can be made without departing from the spirit or scope of the claimed subject matter.

Accordingly, the claimed subject matter is not to be restricted except in light of the attached claims and their equivalents.

1. A polymer blend, comprising:
at least one organic semiconductor (OSC) polymer,
wherein the at least one OSC polymer is a diketopyrrolopyrrole-fused thiophene polymeric material, wherein the fused thiophene is beta-substituted, and
wherein the at least one OSC polymer comprises a first portion and a second portion, wherein at least one of the first portion or the second portion comprises at least one UV-curable side chain.

2. The polymer blend of claim 1, wherein the at least one UV-curable side chain comprises at least one of acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

3. The polymer blend of claim 1, wherein only the first portion comprises at least one UV-curable side chain.

4. The polymer blend of claim 1, wherein both the first portion and the second portion comprise the at least one UV-curable side chain.

5. The polymer blend of claim 1, further comprising: at least one crosslinker, wherein the at least one crosslinker comprises at least one of acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

6. The polymer blend of claim 1, further comprising: at least one photoinitiator, wherein the at least one photoinitiator is present in a range of 0.1 wt. % to 10 wt. %.

7. (canceled)

8. (canceled)

9. The polymer blend of claim 1, wherein the at least one OSC polymer comprises the repeat unit of Formula 1 or Formula 2, or a salt, isomer, or analog thereof: 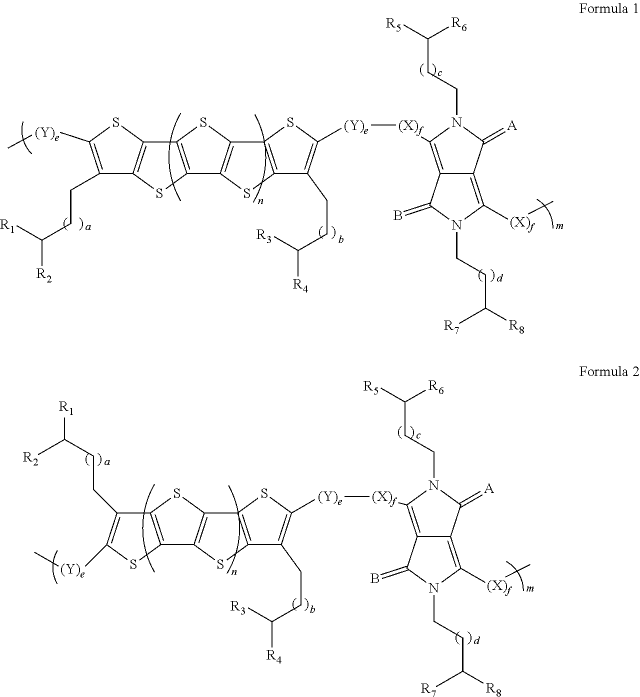
wherein in Formula 1 and Formula 2:
m is an integer greater than or equal to one;
n is 0, 1, or 2;
R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl;
a, b, c, and d are independently, integers greater than or equal to 3;
e and f are integers greater than or equal to zero;
X and Y are, independently a covalent bond, an optionally substituted aryl group, an optionally substituted heteroaryl, an optionally substituted fused aryl or fused heteroaryl group, an alkyne or an alkene; and
A and B may be, independently, either S or O, with the provisos that:
i. at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl;
ii. if any of R₁, R₂, R₃, or R₄ is hydrogen, then none of R₅, R₆, R₇, or R₈ are hydrogen;
iii. if any of R₅, R₆, R₇, or R₈ is hydrogen, then none of R₁, R₂, R₃, or R₄ are hydrogen;
iv. e and f cannot both be 0;
v. if either e or f is 0, then c and d, independently, are integers greater than or equal to 5; and
vi. the polymer having a molecular weight, wherein the molecular weight of the polymer is greater than 10,000.

10. The polymer blend of claim 9, wherein for the first portion, R₅ and R₇ are hydrogen and R₆ and R₈ are substituted or unsubstituted C₄ or greater alkenyl.

11. The polymer blend of claim 9, wherein for the first portion and the second portion, R₅ and R₇ are hydrogen and R₆ and R₈ are substituted or unsubstituted C₄ or greater alkenyl.

12. The polymer blend of claim 9, wherein at least one of R₅, R₆, R₇, and R₈ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

13. The polymer blend of claim 9, wherein at least one of R₁, R₂, R₃, and R₄ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

14. The polymer blend of claim 1, wherein the at least one UV-curable side chain comprises at least one of:
(A) a polymer selected from: 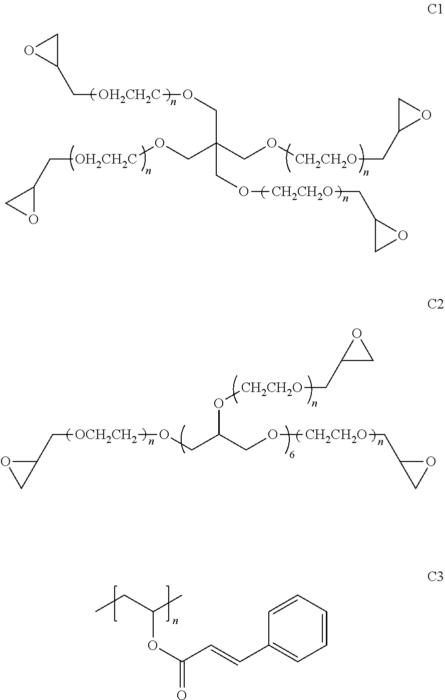
wherein n is an integer greater than or equal to two, or
(B) a small-molecule selected from: 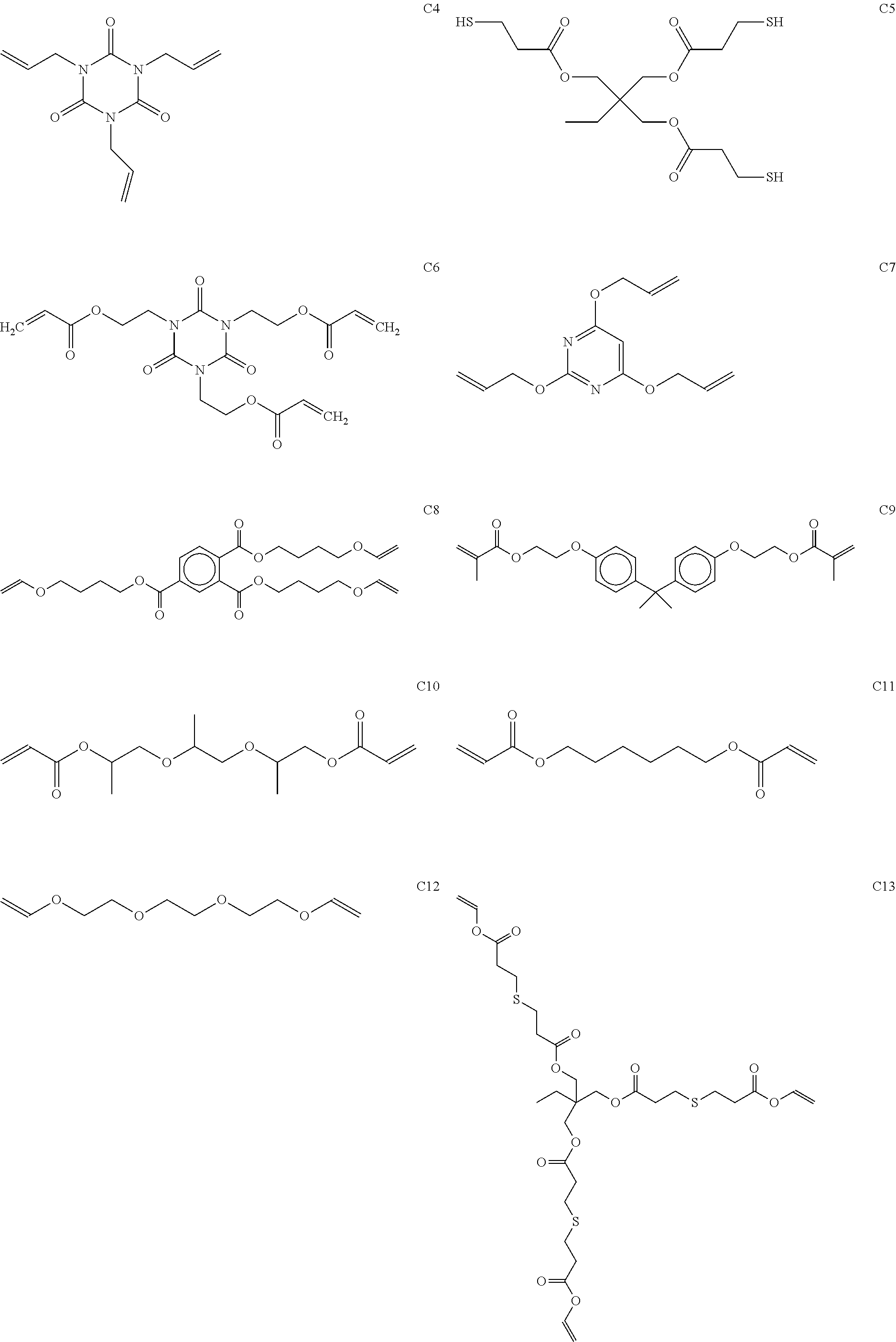 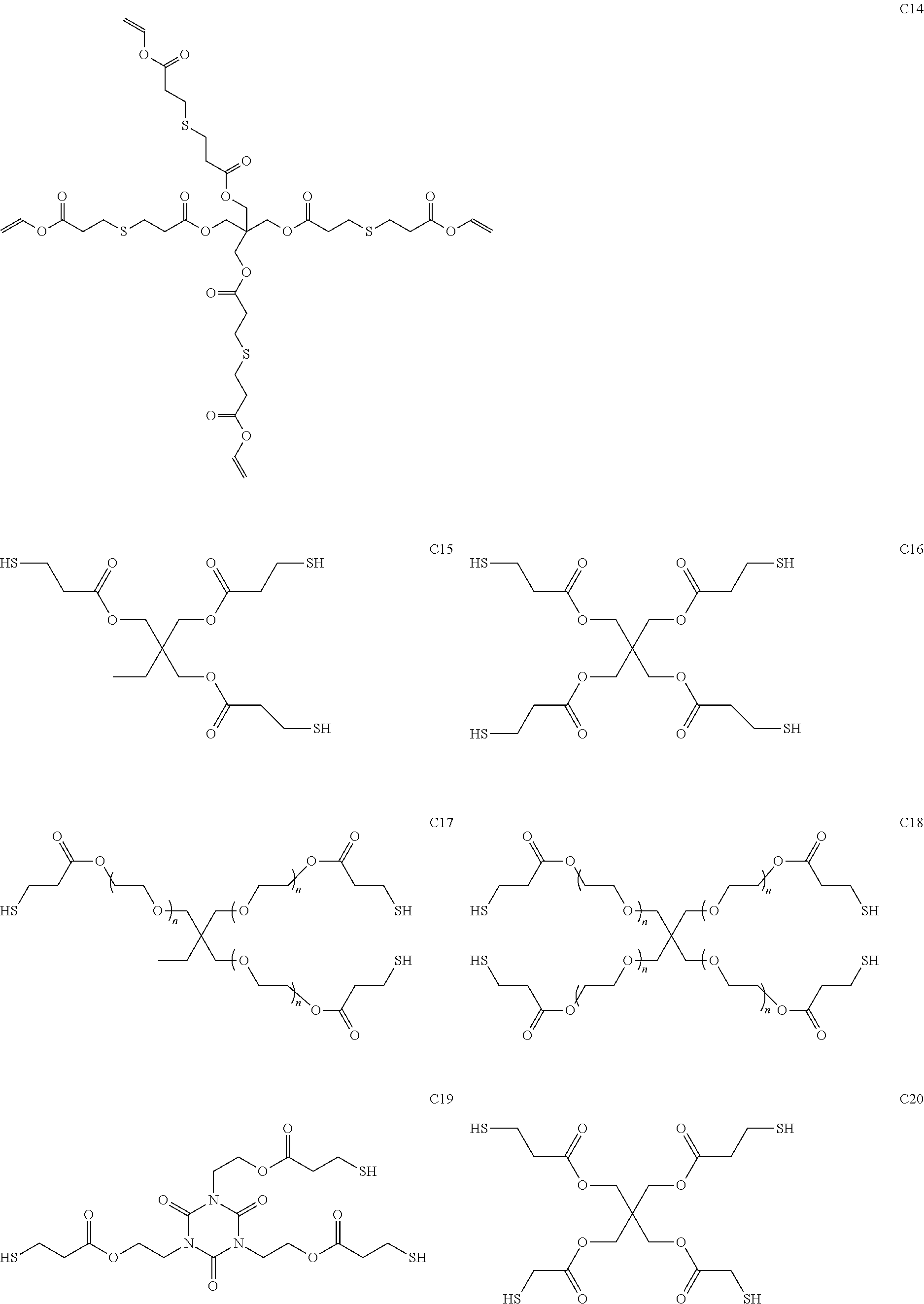 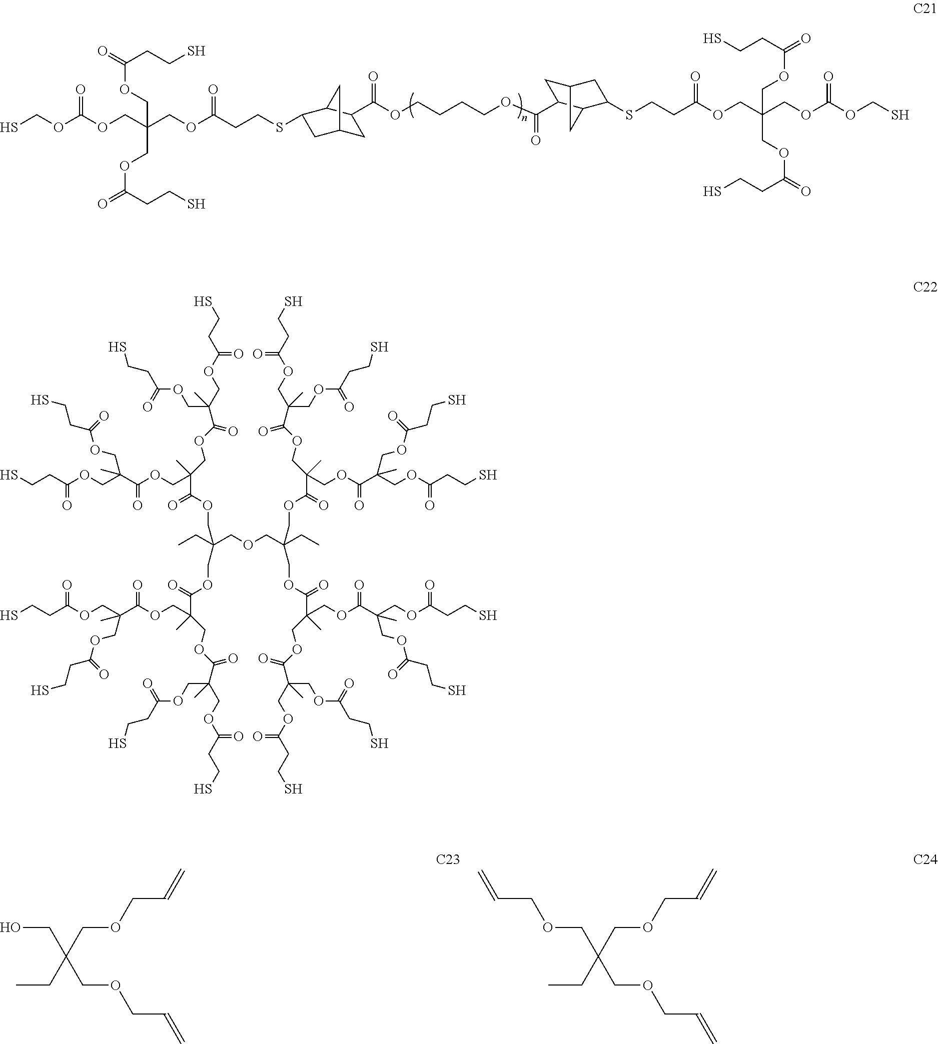 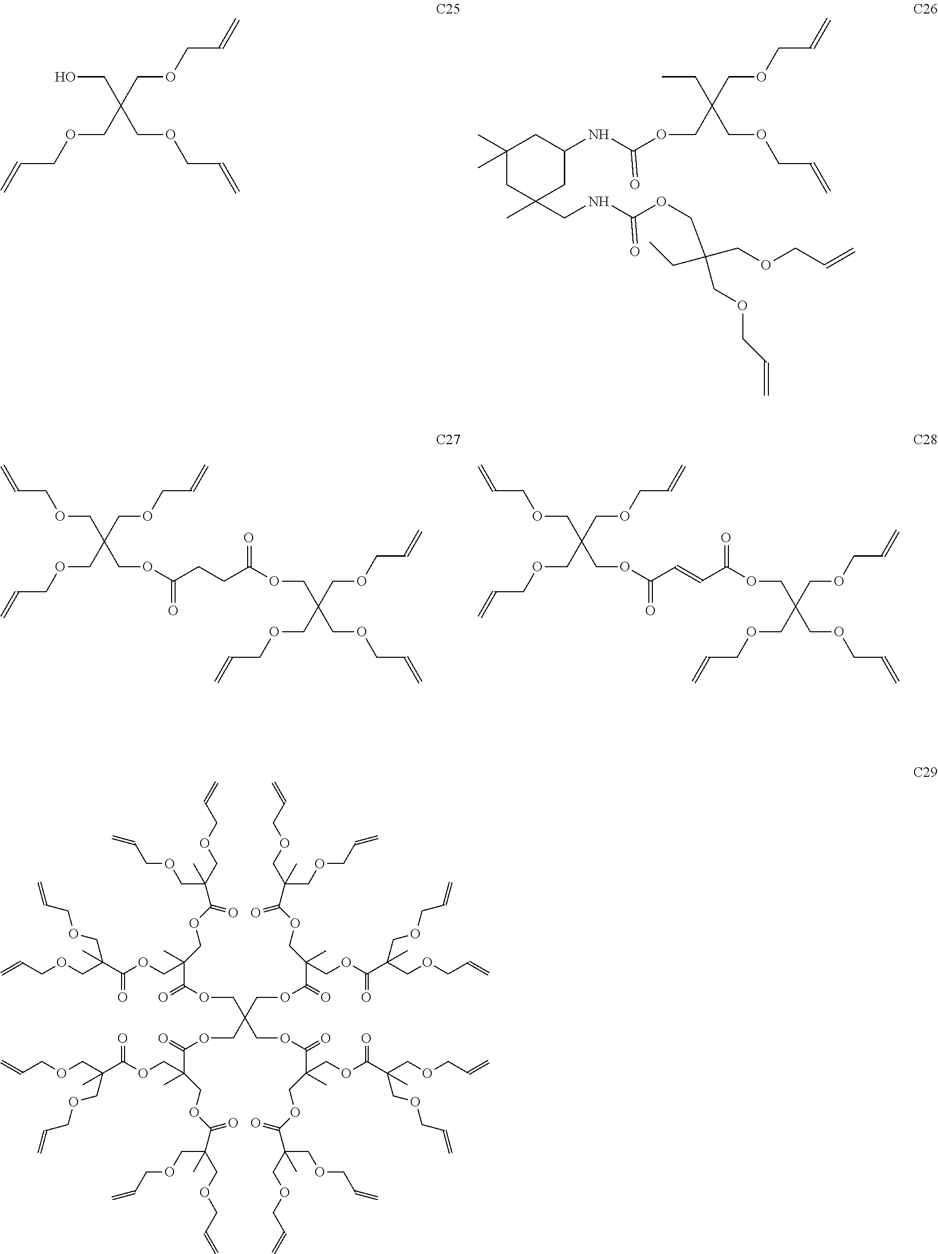 [SMILES: C=CCOCC(CO)(COCC=C)COCC=C ; C=CCOCC(CC)(COCC=C)COC(=O)NCC1(C)CC(NC(=O)OCC(CC)(COCC=C)COCC=C)CC(C)(C)C1 ; C=CCOCC(COCC=C)(COCC=C)COC(=O)CCC(=O)OCC(COCC=C)(COCC=C)COCC=C ; C=CCOCC(COCC=C)(COCC=C)COC(=O)/C=C/C(=O)OCC(COCC=C)(COCC=C)COCC=C ; C=CCOCC(C)(COCC=C)C(=O)OCC(C)(COC(=O)C(C)(COCC=C)COCC=C)C(=O)OCC(COC(=O)C(C)(COC(=O)C(C)(COCC=C)COCC=C)COC(=O)C(C)(COCC=C)COCC=C)(COC(=O)C(C)(COC(=O)C(C)(COCC=C)COCC=C)COC(=O)C(C)(COCC=C)COCC=C)COC(=O)C(C)(COC(=O)C(C)(COCC=C)COCC=C)COC(=O)C(C)(COCC=C)COCC=C] 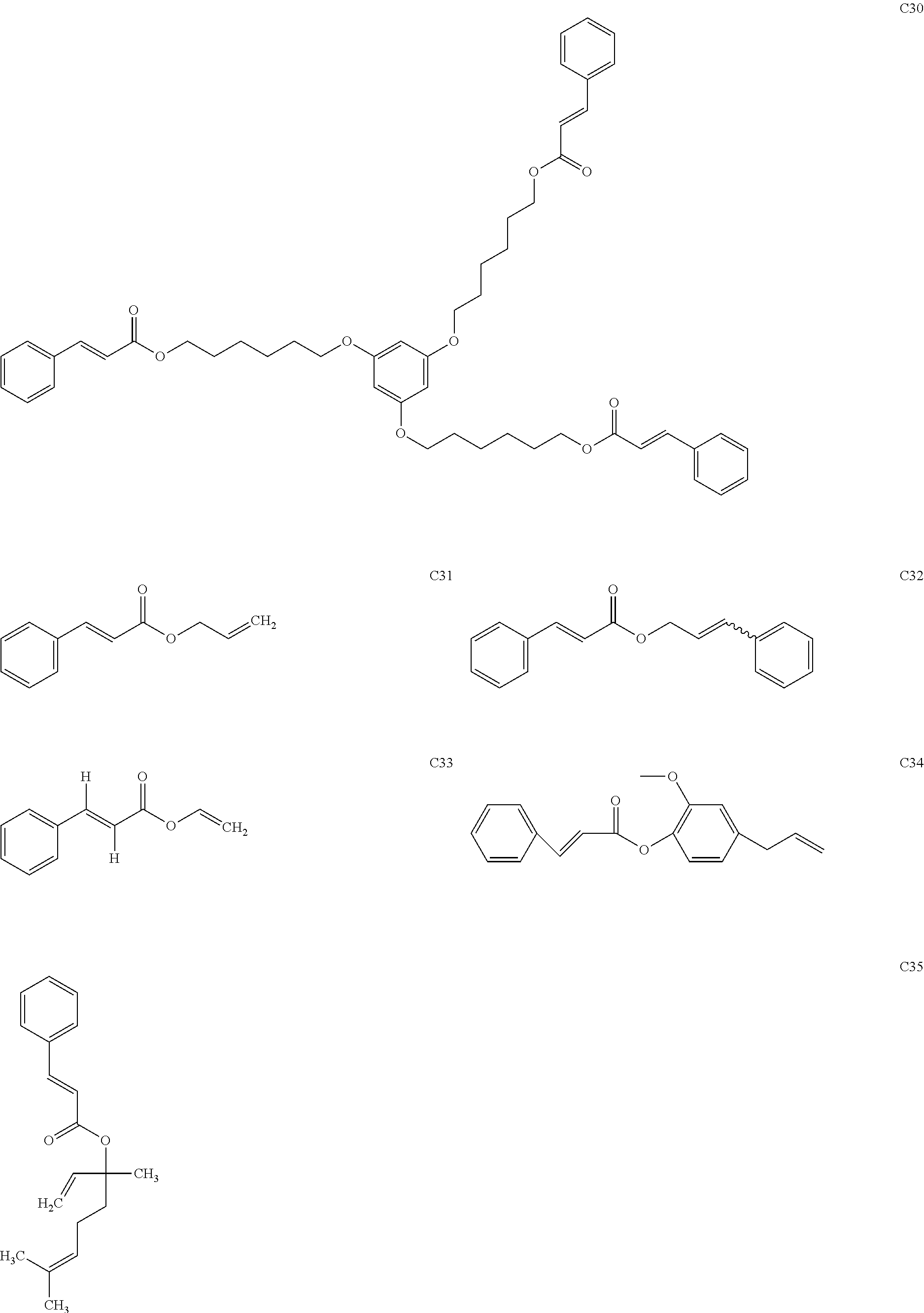 [SMILES: O=C(/C=C/c1ccccc1)OCCCCCCOc1cc(OCCCCCCOC(=O)/C=C/c2ccccc2)cc(OCCCCCCOC(=O)/C=C/c2ccccc2)c1 ; C=CCOC(=O)/C=C/c1ccccc1 ; O=C(/C=C/c1ccccc1)OCC=Cc1ccccc1 ; C=COC(=O)/C=C/c1ccccc1 ; C=CCc1ccc(OC(=O)/C=C/c2ccccc2)c(OC)c1 ; C=CC(C)(CCC=C(C)C)OC(=O)/C=C/c1ccccc1] 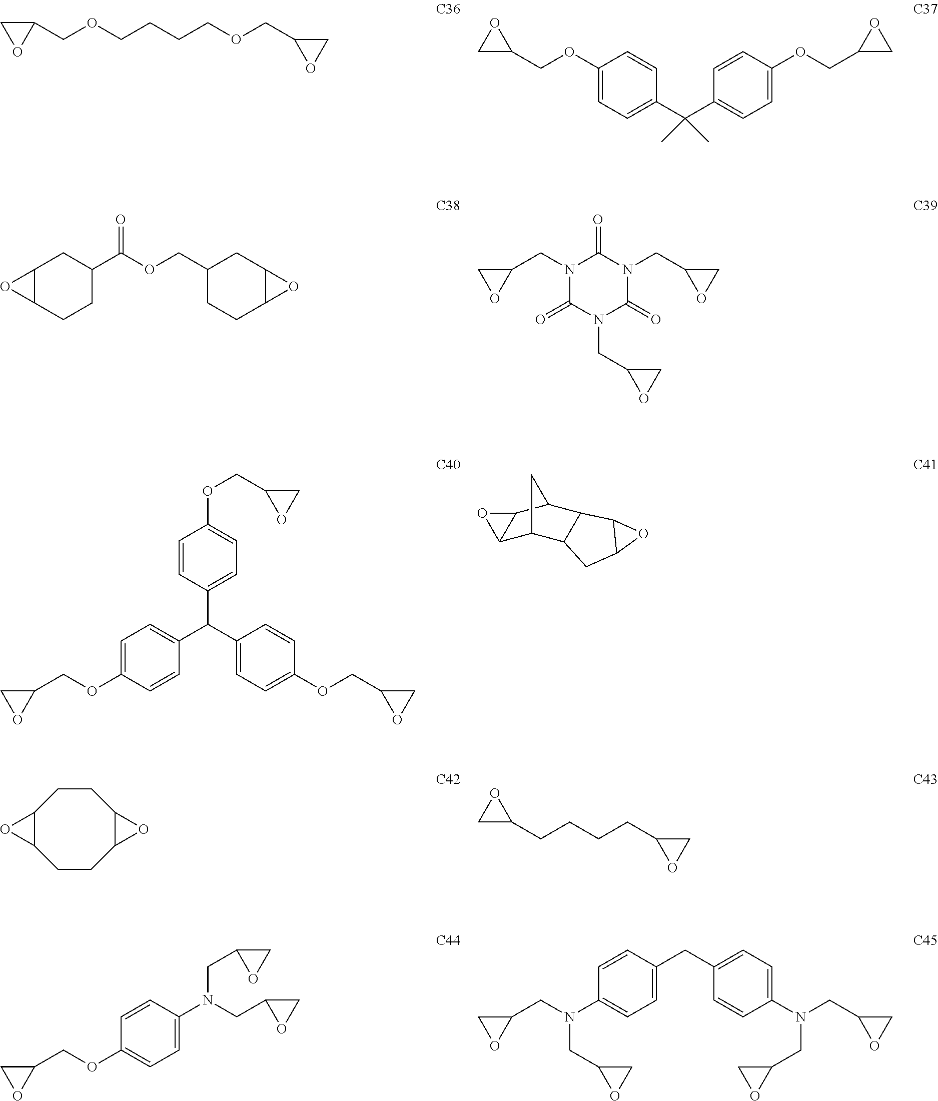 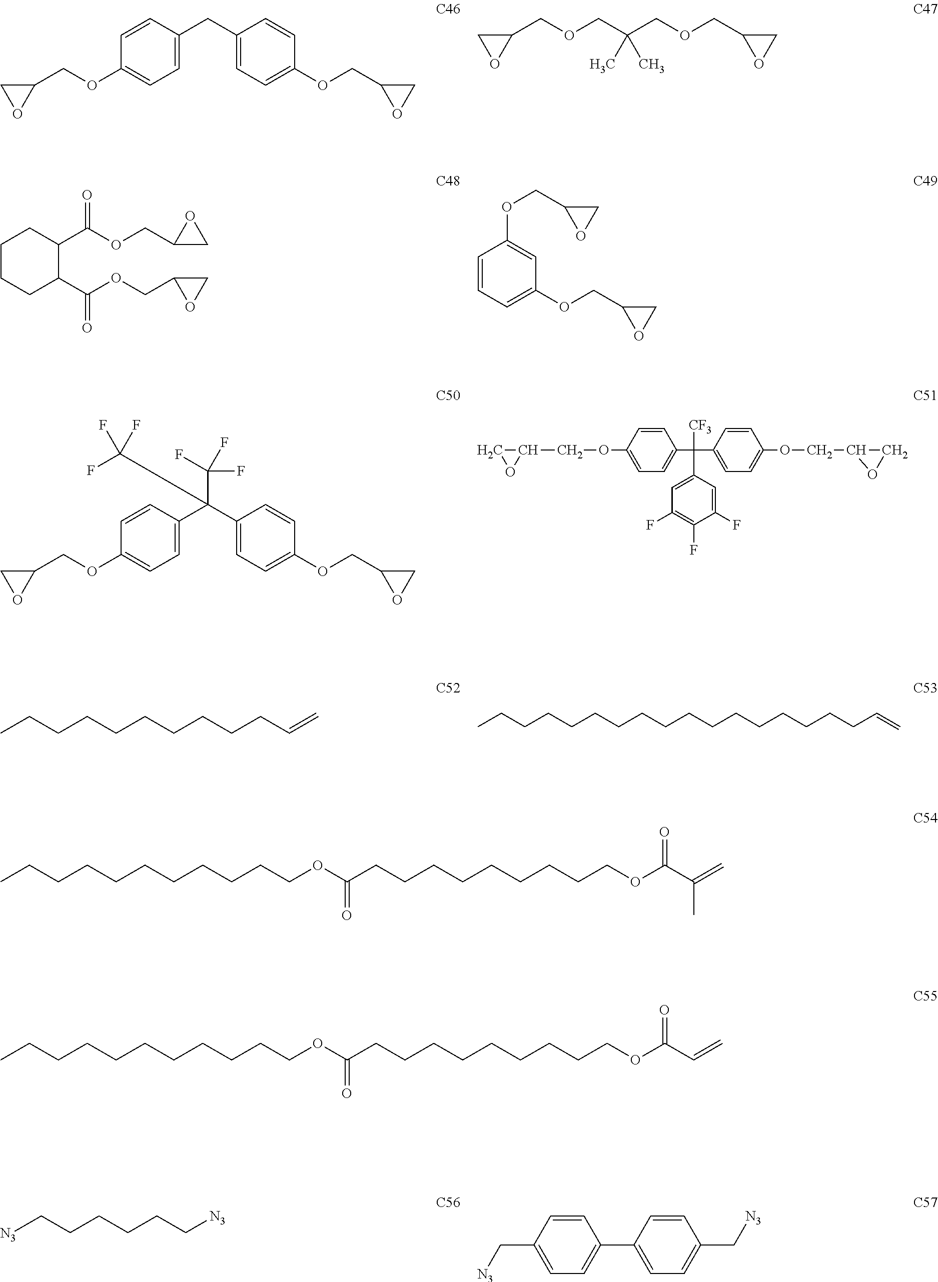 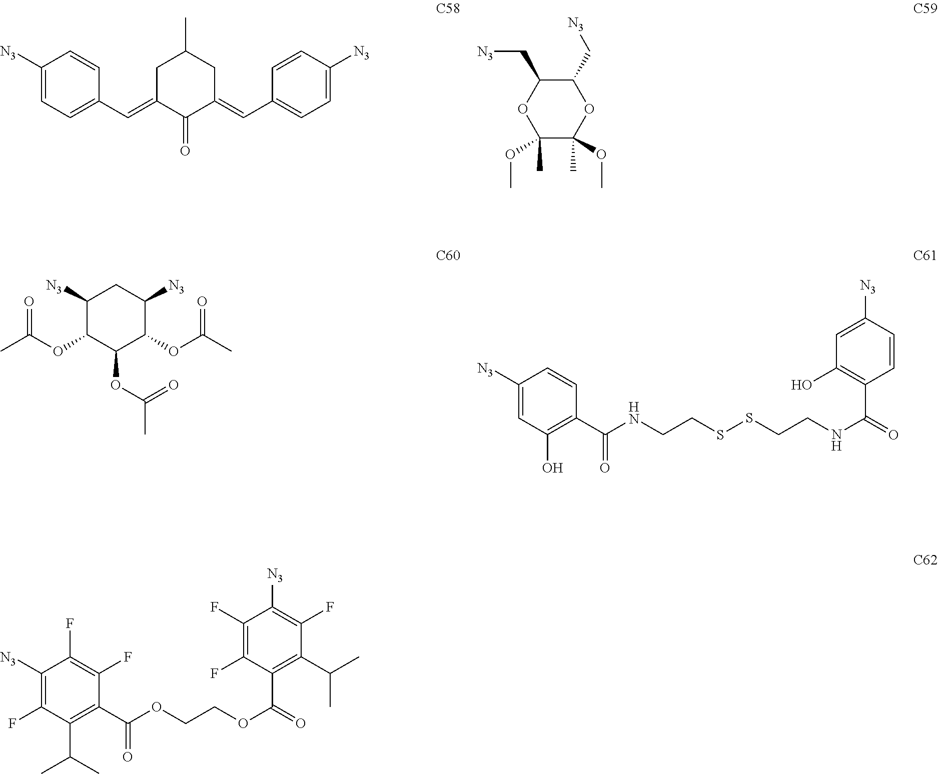 [SMILES: CC1C/C(=C\c2ccc(N=[N+]=[N-])cc2)C(=O)/C(=C/c2ccc(N=[N+]=[N-])cc2)C1 ; CO[C@]1(C)O[C@@H](CN=[N+]=[N-])[C@H](CN=[N+]=[N-])O[C@@]1(C)OC ; CC(=O)O[C@@H]1[C@@H](OC(C)=O)[C@H](N=[N+]=[N-])C[C@H](N=[N+]=[N-])[C@H]1OC(C)=O ; [N-]=[N+]=Nc1ccc(C(=O)NCCSSCCNC(=O)c2ccc(N=[N+]=[N-])cc2O)c(O)c1 ; CC(C)c1c(F)c(N=[N+]=[N-])c(F)c(F)c1C(=O)OCCOC(=O)c1c(F)c(F)c(N=[N+]=[N-])c(F)c1C(C)C]
or,
(C) a combination thereof.

15-17. (canceled)

18. A polymer blend, comprising:
at least one organic semiconductor (OSC) polymer,
wherein the at least one OSC polymer comprises a structure of Formula 7: 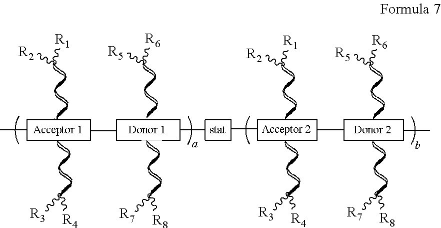
wherein in Formula 7:
Acceptor 1 and Acceptor 2 are each electron withdrawing groups;
Donor 1 and Donor 2 are electron-donating groups;
a and b are, independently, integers greater than or equal to one;
R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl,
wherein:
(i) at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl;
(ii) if any of R₁, R₂, R₃, or R₄ is hydrogen, then none of R₅, R₆, R₇, or R₈ are hydrogen;
(iii) if any of R₅, R₆, R₇, or R₈ is hydrogen, then none of R₁, R₂, R₃, or R₄ are hydrogen;
(iv) one of R₁ or R₂ and one of R₃ or R₄ are, independently, connected with Acceptor 1 and Acceptor 2;
(v) one of R₅ or R₆ and one of R₇ or R₅ are, independently, connected with Donor 1 and Donor 2; and
(vi) the at least one OSC polymer has a molecular weight of greater than 10,000.

19. The polymer blend of claim 18, wherein Acceptor 1 and Acceptor 2 are independently selected from the group comprising: 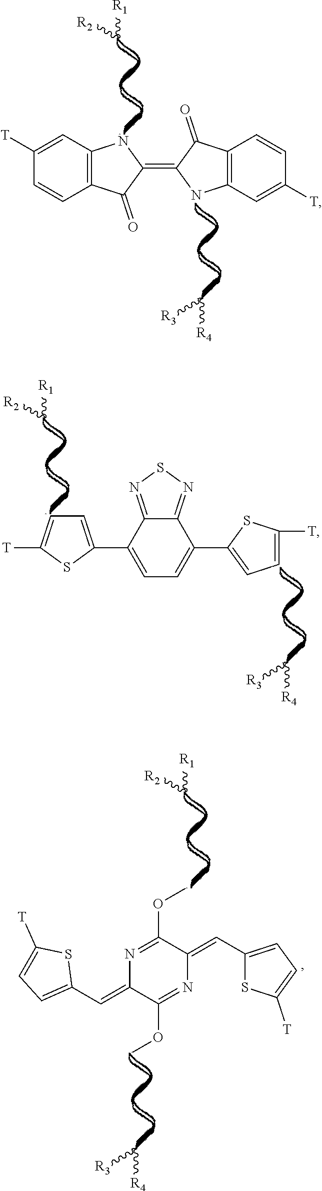 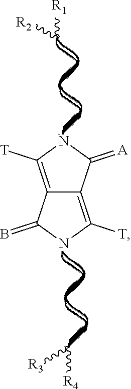
wherein A and B may be, independently, either S or O, and T is a connection terminus to at least one of Donor 1 or Donor 2.

20. The polymer blend of claim 18, wherein Donor 1 and Donor 2 are independently selected from the group comprising: thiophene, benzene, fused thiophene, or combinations thereof.

21. The polymer blend of claim 18, wherein at least one of Acceptor 1, Acceptor 2, Donor 1, or Donor 2 comprises at least one UV-curable side chain.

22. The polymer blend of claim 21, wherein the at least one UV-curable side chain comprises at least one of acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

23. The polymer blend of claim 18, wherein at least one of R₅, R₆, R₇, and R₈ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

24. The polymer blend of claim 18, wherein at least one of R₁, R₂, R₃, and R₄ comprise acrylates, epoxides, oxetanes, alkenes, alkynes, azides, thiols, allyloxysilanes, phenols, anhydrides, amines, cyanate esters, isocyanate esters, silyl hydrides, chalones, cinnamates, coumarins, fluorosulfates, silyl ethers, or combinations thereof.

25. The polymer blend of claim 21, wherein the at least one UV-curable side chain comprises at least one of:
(A) a polymer selected from: 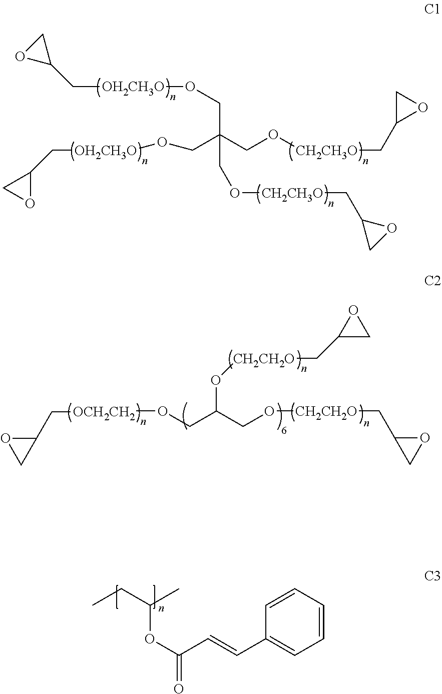
wherein n is an integer greater than or equal to two, or
(B) a small-molecule selected from: 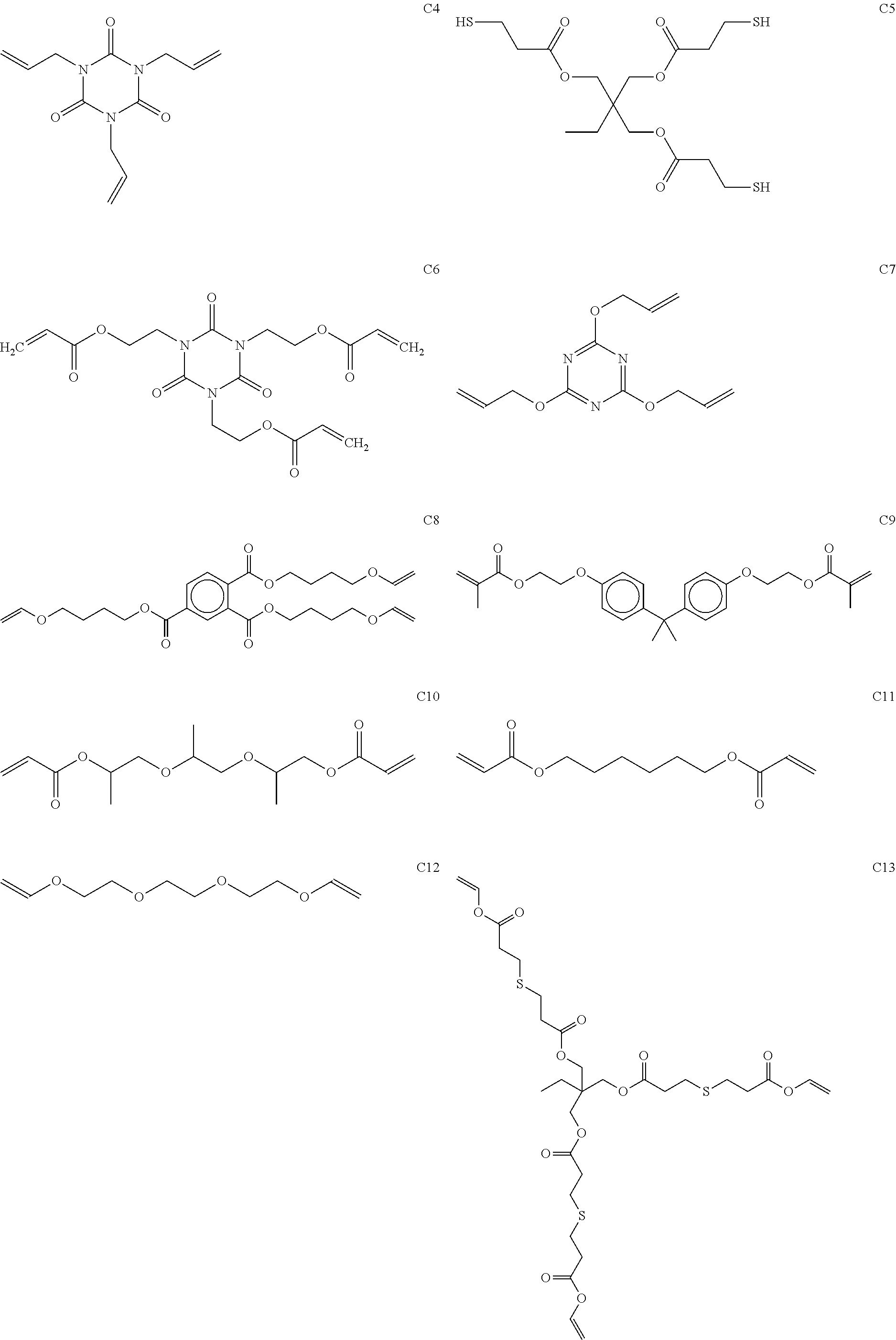 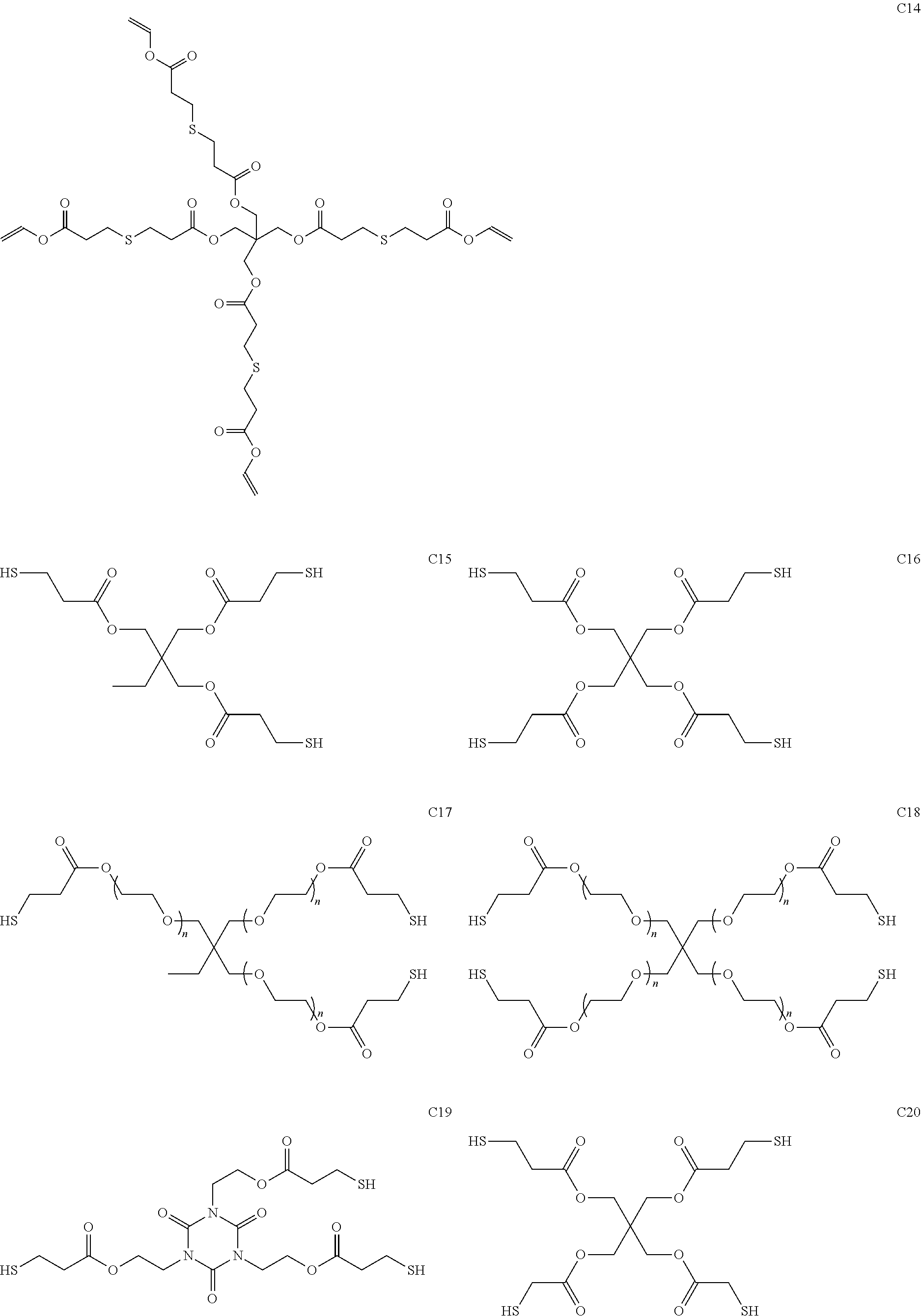 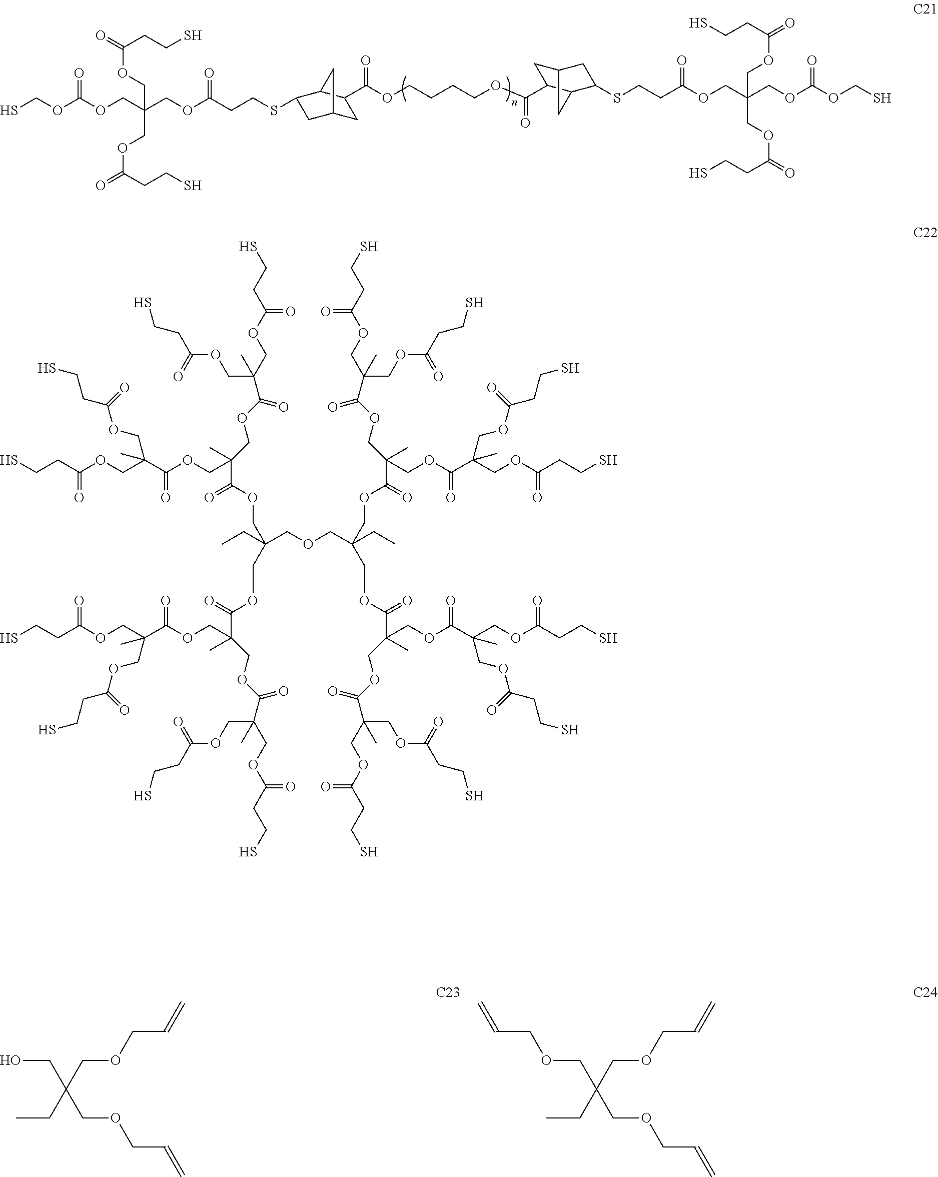 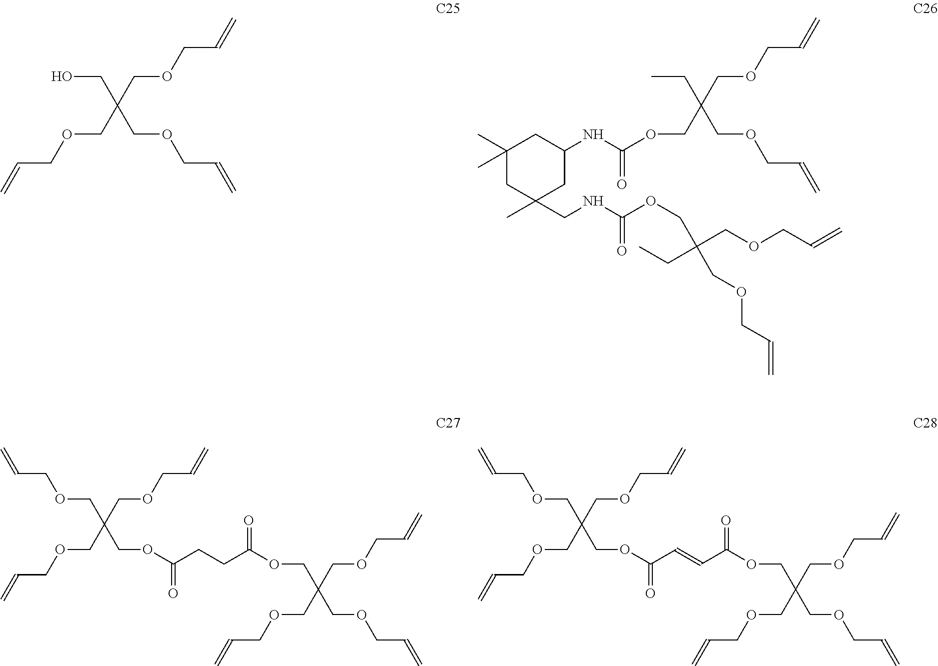 [SMILES: C=CCOCC(CO)(COCC=C)COCC=C ; C=CCOCC(CC)(COCC=C)COC(=O)NCC1(C)CC(NC(=O)OCC(CC)(COCC=C)COCC=C)CC(C)(C)C1 ; C=CCOCC(COCC=C)(COCC=C)COC(=O)CCC(=O)OCC(COCC=C)(COCC=C)COCC=C ; C=CCOCC(COCC=C)(COCC=C)COC(=O)/C=C/C(=O)OCC(COCC=C)(COCC=C)COCC=C] 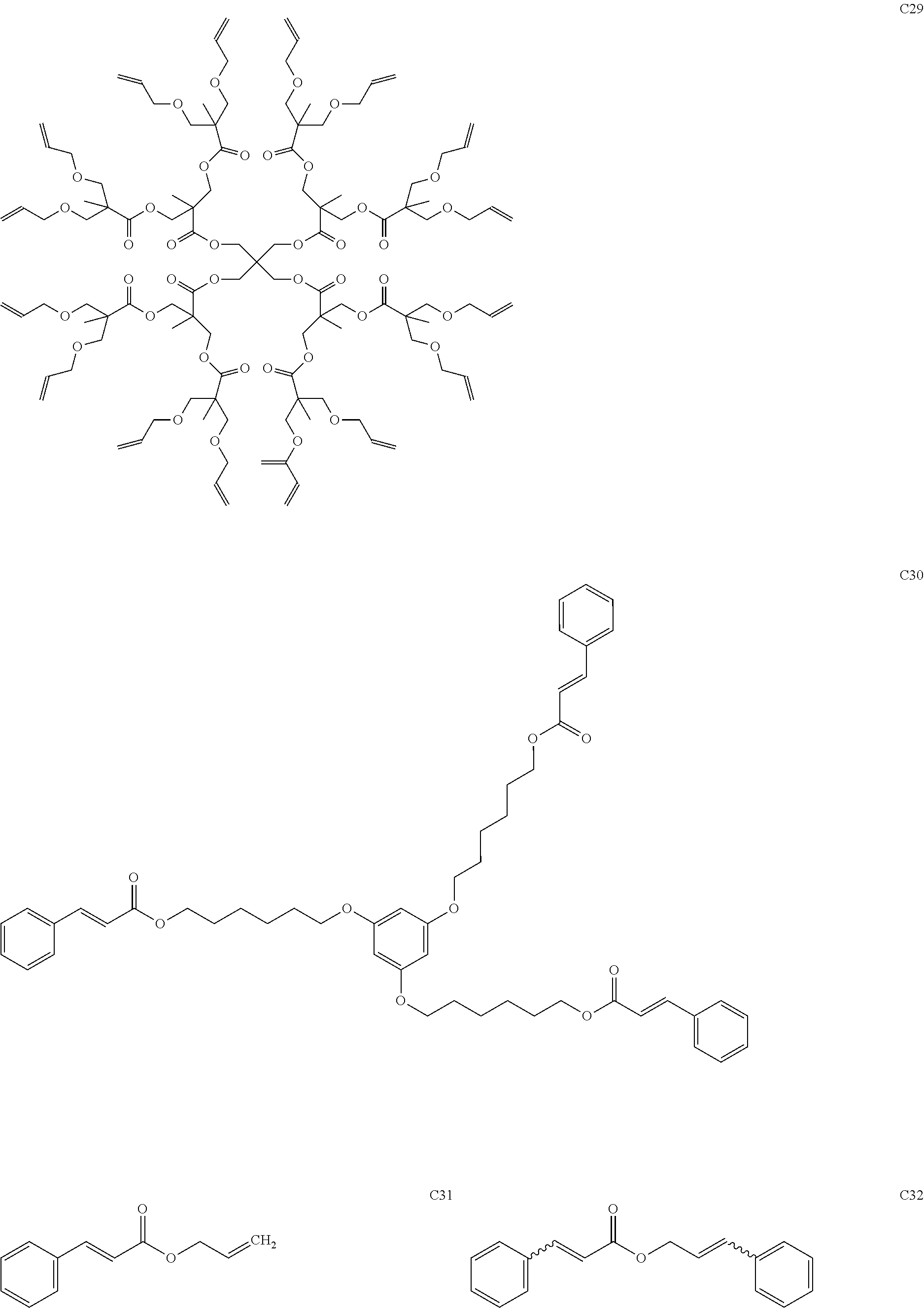 [SMILES: C=CCOCC(C)(COCC=C)C(=O)OCC(C)(COC(=O)C(C)(COCC=C)COCC=C)C(=O)OCC(COC(=O)C(C)(COC(=O)C(C)(COCC=C)COCC=C)COC(=O)C(C)(COCC=C)COCC=C)(COC(=O)C(C)(COC(=O)C(C)(COCC=C)COCC=C)COC(=O)C(C)(COCC=C)COCC=C)COC(=O)C(C)(COC(=O)C(C)(COCC=C)COCC=C)COC(=O)C(C)(COCC=C)COC(=C)C=C ; O=C(/C=C/c1ccccc1)OCCCCCCOc1cc(OCCCCCCOC(=O)/C=C/c2ccccc2)cc(OCCCCCCOC(=O)/C=C/c2ccccc2)c1 ; C=CCOC(=O)/C=C/c1ccccc1 ; O=C(C=Cc1ccccc1)OCC=Cc1ccccc1] 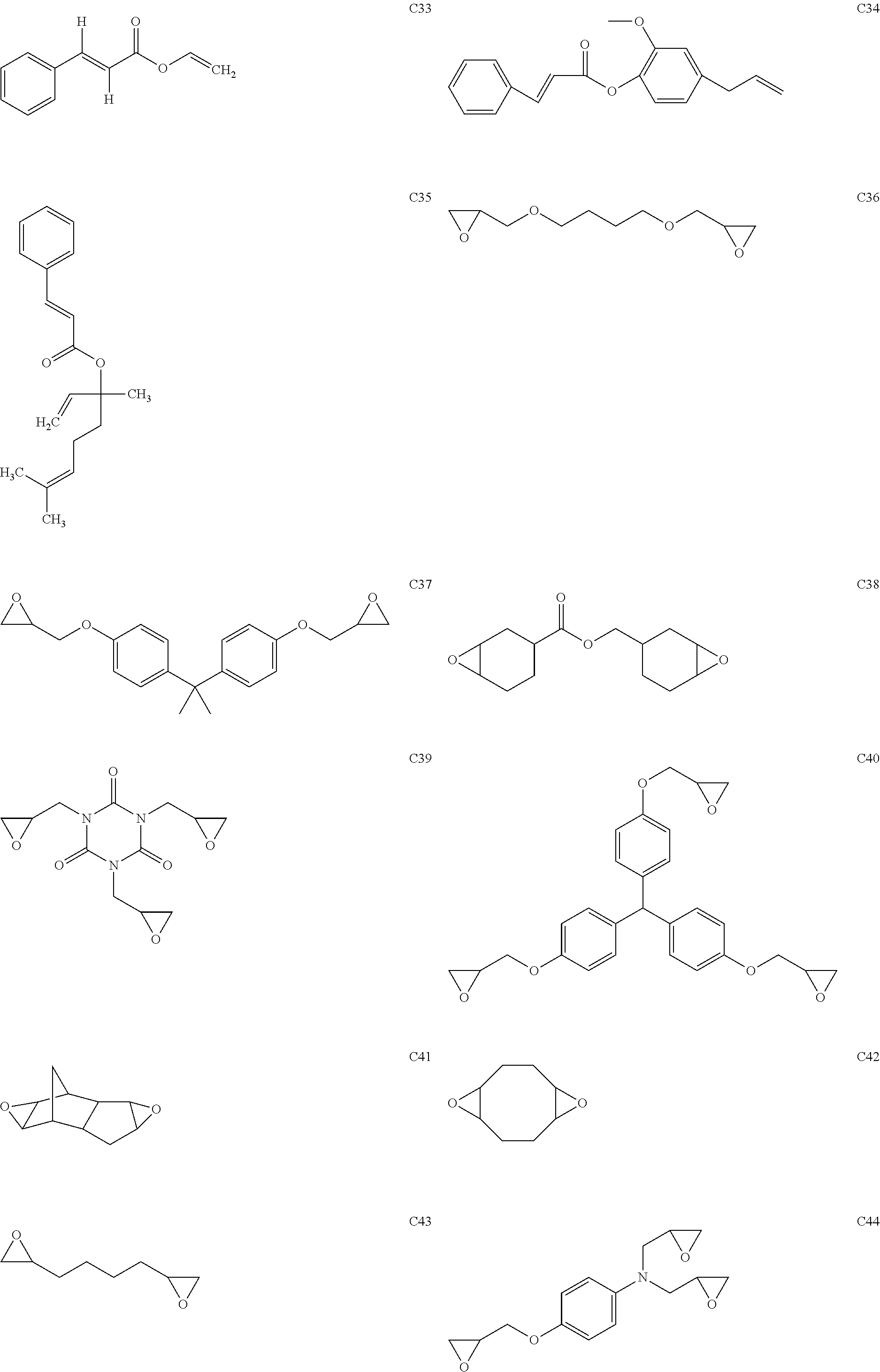 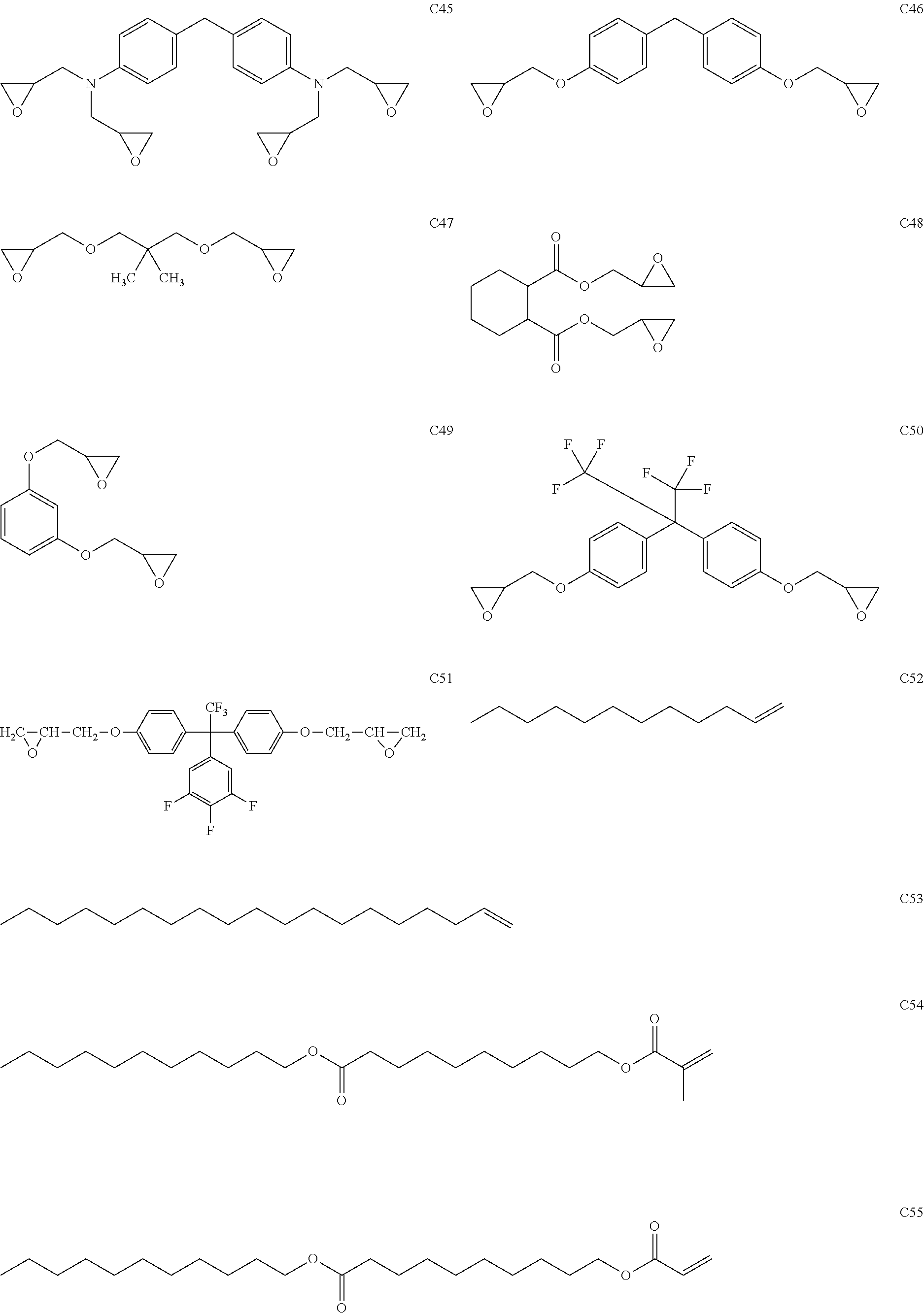 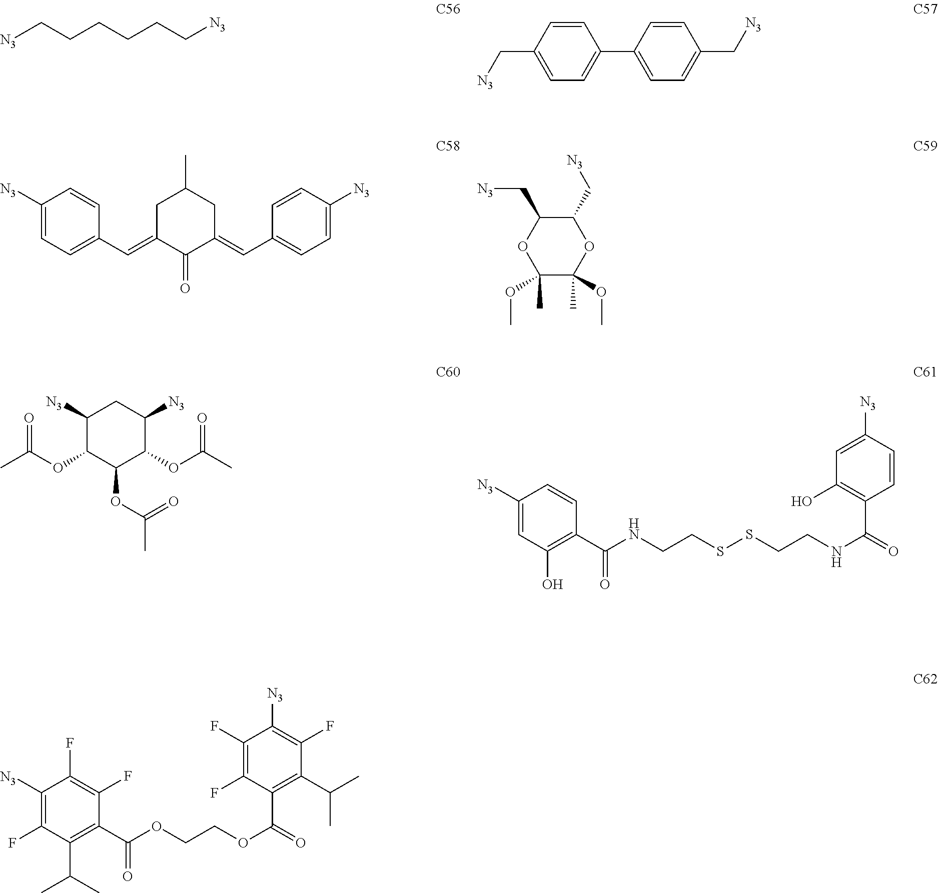
or,
(C) a combination thereof.
